(19) United States
(12) Patent Application Publication
(10) Pub. No.: US 2025/0017050 A1
(43) Pub. Date: Jan. 9, 2025

(54) DISPLAY DEVICE

(71) Applicant: SEMICONDUCTOR ENERGY LABORATORY CO., LTD., Atsugi-shi, Kanagawa-ken (JP)

(72) Inventors: Masahiro KATAYAMA, Isehara, Kanagawa (JP); Naoto GOTO, Tochigi, Tochigi (JP); Kenichi OKAZAKI, Atsugi, Kanagawa (JP)

(21) Appl. No.: 18/709,968

(22) PCT Filed: Nov. 8, 2022
(86) PCT No.: PCT/IB2022/060709

§ 371 Date: May 14, 2024

(30) Foreign Application Priority Data
Nov. 19, 2021 (JP) 2021-188533

(51) Int. Cl. H10K 59/122; H10K 50/13; H10K 59/80

(52) U.S. Cl. CPC H10K 59/122; H10K 50/13; H10K 59/80515; H10K 59/80523

(57) ABSTRACT

A display device in which crosstalk is inhibited is provided. The display device includes a first insulating layer including a first region and a second region having a lower top surface level than the first region, a second insulating layer including a region overlapping with the first region, a light-emitting device including a region overlapping with the first region with the second insulating layer therebetween, a stack including a region overlapping with the second region, and a third insulating layer including a region overlapping with the stack; the second insulating layer includes a protruding portion overlapping with the second region; the light-emitting device includes at least a light-emitting layer, a first upper electrode over the light-emitting layer, and a second upper electrode over the first upper electrode; the second upper electrode includes a region overlapping with the third insulating layer; and the stack contains the same material as the light-emitting layer.

### TECHNICAL FIELD

One embodiment of the present invention relates to a display device.

Note that one embodiment of the present invention is not limited to the above technical field. Examples of the technical field of one embodiment of the present invention disclosed in this specification and the like include a semiconductor device, a light-emitting apparatus, a power storage device, a memory device, an electronic device, a lighting device, an input device, and an input/output device in addition to a display device.

### BACKGROUND ART

In recent years, electronic devices such as smartphones, tablet terminals, and laptop computers have higher definition, and display devices mounted on the electronic devices are required to have higher resolution. As an electronic device required to have the highest definition, an electronic device for virtual reality (VR) or augmented reality (AR) is given.

As a display device capable of higher resolution, a light-emitting apparatus using an EL (ELectro Luminescence) element is given. When current flows through the EL element including a light-emitting layer, light is emitted from the light-emitting layer. As the resolution increases, crosstalk occurs between adjacent EL elements in some cases. Crosstalk means that current leaks to an adjacent EL element, and light is emitted from an EL element other than a desired one. In order to inhibit crosstalk, a structure in which a partition is provided between EL elements and a light-emitting layer in a region overlapping with the partition is made thick has been considered (see Patent Document 1).

### REFERENCE

### Patent Document

[Patent Document 1] Japanese Published Patent Application No. 2013-30476

### SUMMARY OF THE INVENTION

### Problems to be Solved by the Invention

In view of the difficulty in thickness control of light-emitting layer in the above Patent Document 1, crosstalk is inhibited using a new structure in one embodiment of the present invention. That is, an object of one embodiment of the present invention is to provide a display device in which crosstalk is inhibited.

Note that the description of these objects does not preclude the existence of other objects. These objects should be construed as being independent of one another. One embodiment of the present invention only needs to achieve at least one of these objects and does not necessarily achieve all the objects. Other objects can be derived from the description of the specification, the drawings, and the claims, which are this specification and the like.

### Means for Solving the Problems

One embodiment of the present invention is a display device including a first insulating layer including a first region and a second region having a lower top surface level than the first region, a second insulating layer including a region overlapping with the first region, a light-emitting device including a region overlapping with the first region with the second insulating layer therebetween, a stack including a region overlapping with the second region, and a third insulating layer including a region overlapping with the stack; the second insulating layer includes a protruding portion overlapping with the second region; the light-emitting device includes at least a light-emitting layer, a first upper electrode over the light-emitting layer, and a second upper electrode over the first upper electrode; the second upper electrode includes a region overlapping with the third insulating layer; and the stack includes the same material as the light-emitting layer.

Another embodiment of the present invention is a display device including a substrate, a first insulating layer that is positioned over the substrate and includes a first region and a second region at a lower level from the substrate than the first region, a second insulating layer that is positioned over the first insulating layer and includes a region overlapping with the first region, a light-emitting device that is positioned over the second insulating layer and includes a region overlapping with the first region, a stack that is positioned over the first insulating layer and includes a region overlapping with the second region, and a third insulating layer that is positioned over the first insulating layer and includes a region overlapping with the stack; the second insulating layer includes a protruding portion in a position overlapping with the second region; the light-emitting device includes at least a light-emitting layer, a first upper electrode over the light-emitting layer, and a second upper electrode over the first upper electrode; the second upper electrode includes a region positioned over the third insulating layer; and the stack includes the same material as the light-emitting layer.

In the present invention, the same material as the light-emitting layer is preferably a light-emitting material.

Another embodiment of the present invention is a display device including a first insulating layer including a first region and a second region having a lower top surface level than the first region, a second insulating layer including a region overlapping with the first region, a light-emitting device including a region overlapping with the first region with the second insulating layer therebetween, a stack including a region overlapping with the second region, and a third insulating layer including a region overlapping with the stack; the second insulating layer includes a protruding portion overlapping with the second region; the light-emitting device includes at least a first light-emitting layer, a charge-generation layer over the first light-emitting layer, a second light-emitting layer over the charge-generation layer, a first upper electrode over the second light-emitting layer, and a second upper electrode over the first upper electrode; the second upper electrode includes a region overlapping with the third insulating layer; and the stack includes the same material as the charge-generation layer.

Another embodiment of the present invention is a display device including a substrate, a first insulating layer that is positioned over the substrate and includes a first region and a second region at a lower level from the substrate than the first region, a second insulating layer that is positioned over the first insulating layer and includes a region overlapping with the first region, a light-emitting device that is positioned over the second insulating layer and includes a region overlapping with the first region, a stack that is positioned over the first insulating layer and includes a region overlapping with the second region, and a third insulating layer that is positioned over the first insulating layer and includes a region overlapping with the stack; the second insulating layer includes a protruding portion in a position overlapping with the second region; the light-emitting device includes at least a first light-emitting layer, a charge-generation layer over the first light-emitting layer, a second light-emitting layer over the charge-generation layer, a first upper electrode over the second light-emitting layer, and a second upper electrode over the first upper electrode; the second upper electrode includes a region positioned over the third insulating layer; and the stack includes the same material as the charge-generation layer.

In another embodiment of the present invention, the charge-generation layer is preferably a layer containing lithium.

In another embodiment of the present invention, the second upper electrode preferably functions as a common electrode.

In another embodiment of the present invention, a color filter is preferably included in a position overlapping with the light-emitting device.

In another embodiment of the present invention, a region positioned between the light-emitting device and the third insulating layer is preferably included.

In another embodiment of the present invention, the fourth insulating layer preferably includes a region in contact with a bottom surface of the second insulating layer.

In another embodiment of the present invention, it is preferable that the first insulating layer contain an organic material and the second insulating layer contain an inorganic material.

In another embodiment of the present invention, an end portion of a lower electrode in the light-emitting device preferably has a tapered shape.

### Effect of the Invention

With one embodiment of the present invention, a display device in which crosstalk is inhibited can be provided.

Note that the description of these effects does not preclude the existence of other effects. These effects should be construed as being independent of one another, and one embodiment of the present invention only needs to have at least one of these effects and does not need to achieve all the effects. Other effects can be derived from the description of the specification, the drawings, and the claims, which are this specification and the like.

### BRIEF DESCRIPTION OF THE DRAWINGS

FIG. 1 is a cross-sectional view illustrating an example of a display device of one embodiment of the present invention.

FIG. 2A to FIG. 2I are cross-sectional views illustrating examples of a display device of one embodiment of the present invention.

FIG. 3 is a cross-sectional view illustrating an example of a display device of one embodiment of the present invention.

FIG. 4A to FIG. 4I are cross-sectional views illustrating examples of a display device of one embodiment of the present invention.

FIG. 5 is a cross-sectional view illustrating an example of a display device of one embodiment of the present invention.

FIG. 6 is a cross-sectional view illustrating an example of a display device of one embodiment of the present invention.

FIG. 7 is a cross-sectional view illustrating an example of a display device of one embodiment of the present invention.

FIG. 8 is a cross-sectional view illustrating an example of a display device of one embodiment of the present invention.

FIG. 9 is a top view illustrating an example of a display device of one embodiment of the present invention.

FIG. 10 is a cross-sectional view illustrating an example of a display device of one embodiment of the present invention.

FIG. 11 is a cross-sectional view illustrating an example of a display device of one embodiment of the present invention.

FIG. 12 is a cross-sectional view illustrating an example of a display device of one embodiment of the present invention.

FIG. 13 is a cross-sectional view illustrating an example of a display device of one embodiment of the present invention.

FIG. 14A to FIG. 14C are cross-sectional views illustrating an example of a method for fabricating a display device of one embodiment of the present invention.

FIG. 15A to FIG. 15C are cross-sectional views illustrating an example of a method for fabricating a display device of one embodiment of the present invention.

FIG. 16A to FIG. 16D are cross-sectional views illustrating an example of a method for fabricating a display device of one embodiment of the present invention.

FIG. 17A to FIG. 17G are top views of a display device of one embodiment of the present invention.

FIG. 18A to FIG. 18I are top views of a display device of one embodiment of the present invention.

FIG. 19A to FIG. 19K are top views of a display device of one embodiment of the present invention.

FIG. 20A to FIG. 20F are cross-sectional views illustrating a light-emitting device and the like of one embodiment of the present invention.

FIG. 21A to FIG. 21D are cross-sectional views illustrating a light-emitting device and the like of one embodiment of the present invention.

FIG. 22A is a block diagram illustrating an example of a display device. FIG. 22B to FIG. 22E are diagrams illustrating examples of a pixel circuit.

FIG. 23A to FIG. 23D are diagrams illustrating examples of transistors.

FIG. 24A to FIG. 24C are diagrams illustrating a display device of one embodiment of the present invention.

FIG. 25A and FIG. 25B are diagrams illustrating a display device of one embodiment of the present invention.

FIG. 26A and FIG. 26B are diagrams illustrating a display device of one embodiment of the present invention.

FIG. 27A and FIG. 27B are diagrams illustrating a display device of one embodiment of the present invention.

FIG. 28A to FIG. 28D are diagrams illustrating examples of electronic devices.

FIG. 29A and FIG. 29B are diagrams illustrating an example of an electronic device.

FIG. 30A is a cross-sectional STEM image of the example and FIG. 30B is a drawing in which the STEM image is indicated with lines.

### MODE FOR CARRYING OUT THE INVENTION

In this specification and the like, components are classified based on their functions and the components are described using independent blocks in a diagram in some cases; however, it is difficult to classify actual components based on their functions, and one component may have a plurality of functions.

In this specification and the like, the terms “source” and “drain” of a transistor interchange with each other depending on the polarity of the transistor or the levels of potentials applied to the terminals. In general, in an n-channel transistor, a terminal to which a lower potential is supplied is called a source, and a terminal to which a higher potential is supplied is called a drain. In a p-channel transistor, a terminal to which a lower potential is supplied is called a drain, and a terminal to which a higher potential is supplied is called a source. Although the names of the source and the drain sometimes interchange with each other in reality depending on the above-described relation of potentials, a source and a drain are fixed for convenience in the description of the connection relation of a transistor in this specification and the like.

In this specification and the like, a source of a transistor means a source region that is part of a semiconductor layer functioning as an active layer or means a source electrode connected to the source region. Similarly, a drain of a transistor means a drain region that is part of the semiconductor film or a drain electrode connected to the drain region. Moreover, a gate of a transistor means a gate electrode.

In this specification and the like, a state where transistors are connected in series means, for example, a state where only one of a source and a drain of a first transistor is connected to only one of a source and a drain of a second transistor. In addition, a state where transistors are connected in parallel means a state where one of a source and a drain of a first transistor is connected to one of a source and a drain of a second transistor and the other of the source and the drain of the first transistor is connected to the other of the source and the drain of the second transistor.

In this specification and the like, connection is sometimes referred to as electrical connection and includes a state where current, voltage, or a potential can be supplied or transmitted. Accordingly, connection includes connection via an element such as a wiring, a resistor, a diode, or a transistor. Electrical connection includes direct connection without via an element such as a wiring, a resistor, a diode, or a transistor.

In this specification and the like, a first electrode and a second electrode are used for description of a source and a drain of a transistor in some cases: when one of the first electrode and the second electrode refers to a source, the other thereof refers to a drain. Note that one and the other are just examples and thus can be interchanged with each other.

In this specification and the like, a conductive layer sometimes has a plurality of functions such as those of a wiring and an electrode.

In this specification and the like, a tapered shape indicates a shape in which at least part of a side surface of a structure inclined to a formation surface or a substrate surface. For example, an angle formed by an inclined side surface and a substrate surface is referred to as a taper angle, and a tapered shape indicates a region whose taper angle is less than 90°. Note that a side surface of the structure may be a substantially planar surface having a fine curvature or a substantially planar surface having a fine unevenness. The taper angle can be measured by providing a line from a top end to a bottom end of the side surface of the structure. Similarly, the formation surface or the substrate surface may be a substantially planar surface having a fine curvature or a substantially planar surface having a fine unevenness.

In this specification and the like, a light-emitting device is referred to as a light-emitting element or an EL element in some cases. The light-emitting device includes a pair of electrodes and functional layers that are stacked between the pair of electrodes. The stacked functional layers are simply referred to as a stack in some cases.

As the functional layers, a light-emitting layer, carrier-injection layers (typically, a hole-injection layer and an electron-injection layer), carrier-transport layers (typically, a hole-transport layer and an electron-transport layer), carrier-blocking layers (typically, a hole-blocking layer and an electron-blocking layer), and the like are given. The light-emitting layer refers to a layer containing a light-emitting material (sometimes referred to as a light-emitting substance). The hole-injection layer refers to a layer containing a substance having a high hole-injection property. The electron-injection layer refers to a layer containing a substance having a high electron-injection property. The hole-transport layer refers to a layer containing a substance having a high hole-transport property. The electron-transport layer refers to a layer containing a substance having a high electron-transport property. The hole-blocking layer refers to a layer containing a substance with a high hole-blocking property. The electron-blocking layer refers to a layer containing a substance with a high electron-blocking property.

A layer containing an inorganic compound (also referred to as an inorganic compound layer) can be used as the carrier-injection layer, the carrier-blocking layer, or the like among the functional layers described above. Note that a layer containing an organic compound (referred to as an organic compound layer) is used as the light-emitting layer among the functional layers. The light-emitting layer is important as the functional layer of the light-emitting device; thus, the stack is simply referred to as an organic compound layer or an EL layer in some cases.

In this specification and the like, many terms can be used to refer to one and the other of a pair of electrodes included in the light-emitting device. For example, one of the pair of electrodes is referred to as an anode and the other is referred to as a cathode in some cases. In the case of representation according to the electrode arrangement in the light-emitting device, one of the pair of electrodes placed below the light-emitting layer is referred to as a lower electrode and the other of the pair of electrodes placed above the light-emitting layer is referred to as an upper electrode in some cases. Furthermore, in the case of representation based on a light extraction direction of the light-emitting device, one of the pair of electrodes positioned on the side where light is extracted is referred to as an extraction electrode and the other is referred to as a counter electrode in some cases. Note that one and the other are just examples and can be interchanged with each other.

In this specification and the like, a light-emitting device formed using a metal mask or an FMM (a fine metal mask or a high-resolution metal mask) is sometimes referred to as a device having an MM (metal mask) structure. In this specification and the like, a light-emitting device formed using neither a metal mask nor an FMM is sometimes referred to as a device having an MML (metal maskless) structure.

In this specification and the like, a light-emitting device emitting white light is sometimes referred to as a white-light-emitting device. The white-light-emitting device can be formed in the entire pixel region without using a fine metal mask or the like and thus is a device having an MML structure. A light-emitting region capable of emitting red light, green light, and blue light can be obtained by using a color filter (sometimes referred to as a coloring layer), a color conversion layer, or the like in the white-light-emitting device. The light-emitting region capable of emitting red light, green light, or blue light is sometimes referred to as a subpixel. In other words, the white-light-emitting device can perform full-color display using a color filter or a color conversion layer. The minimum unit capable of full-color display is sometimes referred to as a pixel. Although the pixel often means a combination of three subpixels with different emission wavelengths, four subpixels may be combined.

In this specification and the like, a red-light-emitting device, a green-light-emitting device, or a blue-light-emitting device may be used instead of a white-light-emitting device. Note that in the case where full-color display is performed using a blue-light-emitting device formed in the entire pixel region without using a fine metal mask or the like, a blue color filter or a blue color conversion layer can be but is not necessarily used in a subpixel capable of emitting blue light. The same applies to a red-light-emitting device and a green-light-emitting device. A color filter or a color conversion layer is not necessary, whereby the manufacturing cost of a display device can be reduced.

In this specification and the like, a light-emitting device can include two or more light-emitting layers that are stacked. The light-emitting device can have a tandem structure or a single structure depending on the stacking way of the light-emitting layers. In the tandem structure, two or more light-emitting layers are stacked between a pair of electrodes with a charge-generation layer therebetween. A stack including the light-emitting layers is sometimes referred to as a light-emitting unit: in the tandem structure, two or more light-emitting units are stacked with a charge-generation layer therebetween, and two or more charge-generation layers may be included in accordance with the number of stacked light-emitting units. In the case where two light-emitting units are included, a first light-emitting unit, a charge-generation layer, and a second light-emitting unit are positioned between a pair of electrodes in the tandem structure. Furthermore, one light-emitting unit may include two or more light-emitting layers in the tandem structure. In the case where a white-light-emitting device is obtained using the tandem structure, the two or more light-emitting layers included in the tandem structure emit light of complementary colors.

The charge-generation layer has a function of injecting holes into one of the light-emitting units and a function of injecting electrons into the other light-emitting unit, when voltage is applied between the pair of electrodes. When the charge-generation layer is provided between the stacked light-emitting units, the driving voltage increase in the tandem structure can be inhibited. The charge-generation layer is positioned between the light-emitting units and thus sometimes referred to as an intermediate layer. A thin charge-generation layer cannot be observed as a layer in some cases and thus is sometimes referred to as a charge-generation region or an intermediate region.

In a single structure used to obtain a white-light-emitting device, two or more light-emitting layers are included with no charge-generation layer therebetween. The light-emitting layers may be positioned in contact with each other or are not necessarily positioned in contact with each other. A given layer can be provided between the light-emitting layers. In the case where a white-light-emitting device is obtained using the single structure, the two or more light-emitting layers included in the single structure emit light of complementary colors.

In this specification and the like, a structure in which light-emitting layers are separately formed is sometimes referred to as an SBS (Side By Side) structure. The SBS structure can optimize a material of a functional layer in each light-emitting device. The SBS structure can optimize a stack in each light-emitting device.

In this specification and the like, a structure in which a connector such as an FPC (Flexible Printed Circuit) or a TCP (Tape Carrier Package) is attached to a substrate of a display device, or a structure in which an IC is mounted on the substrate by a COG (Chip On Glass) method or the like is referred to as a display module in some cases. Thus, the display module is one embodiment of a display device.

Next, embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

A display device of one embodiment of the present invention includes an insulating layer with a depression and a projection and a light-emitting device positioned over the insulating layer. Since top surface positions of the depression and the projection of the insulating layer are different from each other, in the case where a region having the projection is referred to as a first region, a region having the depression can be referred to as a second region having a lower top surface level than the first region. Since the depression and the projection of the insulating layer are different in height from a reference surface, in the case where the region having the projection is referred to as the first region, the region having the depression can be referred to as the second region at lower level from the reference surface than the first region. The reference surface can be, for example, a top surface of a substrate. The depression of the insulating layer can be referred to as a groove, a trench, or a concave. The depression and the projection of the insulating layer can be referred to as a projected portion and a depressed portion. In this specification and the like, a projected portion and a depressed portion are used for description.

When the light-emitting device of one embodiment of the present invention is formed over the projected portion in the entire pixel region, layers of the light-emitting device are divided by the depressed portion, and the light-emitting device is formed over the projected portion. The divided layers of the light-emitting device include functional layers, and a stack of the same materials as the functional layers is also formed in the depressed portion. Furthermore, the divided layers of the light-emitting device preferably include an upper electrode, and a conductive layer of the same material as the upper electrode is formed in the depressed portion. The conductive layer formed in the depressed portion is formed over the stack.

The light-emitting device of one embodiment of the present invention is divided without using a fine metal mask or the like and thus can be regarded as a light-emitting device having an MML structure. Note that the division refers to isolation of adjacent light-emitting devices. The isolation of the light-emitting devices includes a structure in which at least the upper electrodes are isolated from each other. In addition, the isolation of the light-emitting devices includes a structure in which at least the functional layers are isolated from each other. When the upper electrodes or the functional layers such as light-emitting layers are isolated from each other, unnecessary current (referred to as leakage current) does not flow between the adjacent light-emitting devices, so that crosstalk can be inhibited.

In the display device of one embodiment of the present invention, an insulating layer including a protruding portion is preferably included over the insulating layer including the depressed portion, and the protruding portion is provided to overlap with the depressed portion. The protruding portion can surely divide the layers of the light-emitting device.

In this embodiment, the display device of one embodiment of the present invention will be described.

### Structure Example of Display Device

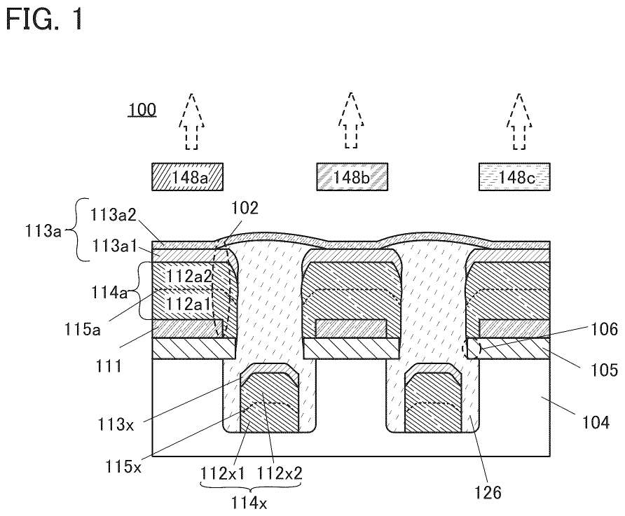

FIG. 1 illustrates a display device 100 of one embodiment of the present invention. In the display device 100 of one embodiment of the present invention, a white-light-emitting device 102 that might be formed in the entire pixel region is preferably used. In the display device 100 including the white-light-emitting device 102, a functional layer need not be formed separately for each of subpixels of different colors, and a simple manufacturing process or a reduced manufacturing cost can be achieved. Instead of the white-light-emitting device 102, a monochromatic-light-emitting device such as a red-light-emitting device, a green-light-emitting device, or a blue-light-emitting device may be used.

The light-emitting device 102 includes a stack 114a positioned between a lower electrode 111 and an upper electrode 113a. In the case of the white-light-emitting device 102, a tandem structure or a single structure can be used, and two or more light-emitting layers included in the stack 114a emit light of complementary colors.

The light-emitting device 102 has a tandem structure in this embodiment; thus, as illustrated in FIG. 1, the light-emitting device 102 includes a charge-generation layer 115a, and further includes a first light-emitting unit 112a1 positioned on the lower electrode 111 side and a second light-emitting unit 112a2 positioned on the upper electrode 113 side with the charge-generation layer 115a therebetween. Note that the stack 114a includes the first light-emitting unit 112a1, the charge-generation layer 115a, and the second light-emitting unit 112a2. When a light-emitting layer of the first light-emitting unit 112a1 and a light-emitting layer of the second light-emitting unit 112a2 emit light of complementary colors, the light-emitting device 102 is a white-light-emitting device. The first light-emitting unit 112a1 can include one or more light-emitting layers, and the second light-emitting unit 112a2 can include one or more light-emitting lavers.

In this embodiment, as illustrated in FIG. 1, color filters 148a, 148b, and 148c are provided at positions overlapping with the light-emitting devices 102 for full-color display. Note that the color filters 148a, 148b, and 148c are distinguished from each other in FIG. 1; however, when the color filters need not be distinguished from each other, they are sometimes collectively referred to as a color filter 148.

The color filter 148 has a function of transmitting light in a specific wavelength range (typically, red, green, blue, or the like). Transmitting light in a specific wavelength range refers to a state where light transmitted through a color filter has a peak at the wavelength corresponding to the specific color. For example, a red color filter that transmits light in a red wavelength range can be used as the color filter 148a, a green color filter that transmits light in a green wavelength range can be used as the color filter 148b, and a blue color filter that transmits light in a blue wavelength range can be used as the color filter 148c.

The color filter 148 can be formed in desired positions using any of various materials such as a chromatic light-transmitting resin by a printing method, an ink-jet method, an etching method using a photolithography method, or the like. As the chromatic light-transmitting resin, a photosensitive or non-photosensitive organic resin can be used, and a photosensitive organic resin is preferably used because the number of resist masks used in the etching can be reduced and the process can be accordingly simplified.

Chromatic colors are colors except achromatic colors such as black, gray, and white; specifically, red, green, blue, and the like can be used. The color of the color filter 148 may be cyan, magenta, yellow, and the like.

The thickness of the color filter 148 is preferably greater than or equal to 500 nm and less than or equal to 5 μm.

The use of the color filter 148 can eliminate the need for an optical element such as a circularly polarizing plate or a polarizing plate provided in the display device 100. Eliminating the need for the optical element is preferable, in which case the display device 100 can be lightweight or thin.

In this embodiment, light from the light-emitting device 102 is emitted toward the color filter 148 side. In FIG. 1, the arrow shows a direction in which the light is emitted. The display device 100 that emits light as illustrated in FIG. 1 is sometimes referred to as a top-emission display device. In the top-emission display device, a microcavity structure described later can be employed.

The lower electrode 111 included in the light-emitting device 102 is described. Note that the lower electrode 111 is positioned to be electrically connected to a driving element such as a transistor and is sometimes referred to as a pixel electrode. On the basis of the light extraction direction in FIG. 1, the lower electrode 111 is referred to as a counter electrode in some cases. The lower electrode 111 is referred to as an anode or a cathode in some cases.

For the lower electrode 111, a metal, an alloy, an electrically conductive compound, a mixture of these, and the like can be appropriately used. Specifically, for the lower electrode 111, it is possible to use an In—Sn oxide (sometimes referred to as an oxide containing indium and tin, an indium tin oxide, or ITO), an In—Si—Sn oxide (sometimes referred to as an oxide containing indium, silicon, and tin or ITSO), an In—Zn oxide (sometimes referred to as an oxide containing indium and zinc or an indium zinc oxide), an In—W—Zn oxide (sometimes referred to as an oxide containing indium, tungsten, and zinc), a Ga—Zn oxide (sometimes referred to as an oxide containing gallium and zinc), an Al—Zn oxide (sometimes referred to as an oxide containing aluminum and zinc), an In—Ga—Zn oxide (sometimes referred to as an oxide containing indium, gallium, and zinc, an indium gallium zinc oxide, or IGZO), or the like. These materials have a light-transmitting property and the light-transmitting materials have a visible light (light with a wavelength greater than or equal to 400 nm and less than 750 nm) transmittance higher than or equal to 40%. An electrode containing the light-transmitting material is referred to as a transparent electrode in some cases. For the lower electrode 111, an alloy containing aluminum (an aluminum alloy) such as an alloy of aluminum, nickel, and lanthanum (sometimes referred to as Al—Ni—La) or the like can be used. For the lower electrode 111, an alloy of silver, palladium, and copper (sometimes referred to as Ag—Pd—Cu or APC) or the like can be used. In addition, for the lower electrode 111, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing any of these metals in appropriate combination. These materials have a reflective property. For example, the reflective materials preferably have a visible light (light with a wavelength greater than or equal to 400 nm and less than 750 nm) reflectance higher than or equal to 40% and lower than or equal to 100%, further preferably higher than or equal to 70%, preferably 100%. An electrode containing the reflective material is referred to as a reflective electrode in some cases. When the reflective electrode is made thin enough to transmit visible light, the electrode can be used as a transparent electrode. In addition, for the lower electrode 111, it is possible to use an element belonging to Group 1 or Group 2 in the periodic table (e.g., lithium (Li), cesium (Cs), magnesium (Mg), calcium (Ca), or strontium (Sr)), an element belonging to rare earth metal in the periodic table (e.g., europium (Eu) or ytterbium (Yb)), and an alloy containing any of these elements belonging to Group 1, Group 2, and the rare earth metal in appropriate combination, for example. Graphene or the like can also be used for the lower electrode 111.

The lower electrode 111 is preferably an anode. As a material for forming the anode, it is preferable to use a metal, an alloy, and a conductive compound with a high work function (specifically, higher than or equal to 4.0 eV), a mixture thereof, or the like. For the anode, for example, ITO, ITSO, or the like is preferably used.

The lower electrode 111 can have a single-layer structure or a stacked-layer structure. For example, the lower electrode 111 can have a single-layer structure of any of the materials selected from the above specific examples. Alternatively, the lower electrode 111 can have a stacked-layer structure of two or more materials selected from the above specific examples, e.g., a structure in which ITSO, APC, and ITSO are stacked in this order or a structure in which ITO, APC, and ITO are stacked in this order.

In the case where the display device 100 has a microcavity structure described later, the lower electrode 111 preferably has reflectivity. In the case of a single-layer structure, the reflective material is selected from the above specific examples. In the case of a stacked-layer structure, the reflective material is used for at least one layer. In the above structure in which ITSO, APC, and ITSO are stacked in this order or the above structure in which ITO. APC, and ITO are stacked in this order. APC is the reflective material.

Next, the upper electrode 113a included in the light-emitting device 102 is described. On the basis of the light extraction direction in FIG. 1, the upper electrode 113a is referred to as an extraction electrode in some cases. The upper electrode 113a is referred to as an anode or a cathode in some cases.

For the upper electrode 113a, a metal, an alloy, an electrically conductive compound, a mixture of these, and the like can be appropriately used. Specifically, for the upper electrode 113a, it is possible to use an In—Sn oxide (sometimes referred to as an oxide containing indium and tin, an indium tin oxide, or ITO), an In—Si—Sn oxide (sometimes referred to as an oxide containing indium, silicon, and tin or ITSO), an In—Zn oxide (sometimes referred to as an oxide containing indium and zinc or an indium zinc oxide), an In—W—Zn oxide (sometimes referred to as an oxide containing indium, tungsten, and zinc), a Ga—Zn oxide (sometimes referred to as an oxide containing gallium and zinc), an Al—Zn oxide (sometimes referred to as an oxide containing aluminum and zinc), an In—Ga—Zn oxide (sometimes referred to as an oxide containing indium, gallium, and zinc, an indium gallium zinc oxide, or IGZO), or the like. These materials have a light-transmitting property and the light-transmitting materials have a visible light (light with a wavelength greater than or equal to 400 nm and less than 750 nm) transmittance higher than or equal to 40%. An electrode containing the light-transmitting material is referred to as a transparent electrode in some cases. For the upper electrode 113a, an alloy containing aluminum (an aluminum alloy) such as an alloy of aluminum, nickel, and lanthanum (sometimes referred to as Al—Ni—La) or the like can be used. For the upper electrode 113a, an alloy of silver, palladium, and copper (sometimes referred to as Ag—Pd—Cu or APC) or the like can be used. In addition, for the upper electrode 113a, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing any of these metals in appropriate combination. These materials have a reflective property. For example, the reflective materials preferably have a visible light (light with a wavelength greater than or equal to 400 nm and less than 750 nm) reflectance higher than or equal to 40% and lower than or equal to 100%, further preferably higher than or equal to 70%, preferably 100%. An electrode containing the reflective material is referred to as a reflective electrode in some cases. When the reflective electrode is made thin enough to transmit visible light, the electrode can be used as a transparent electrode. In addition, for the upper electrode 113a, it is possible to use an element belonging to Group 1 or Group 2 in the periodic table (e.g., lithium (Li), cesium (Cs), magnesium (Mg), calcium (Ca), or strontium (Sr)), an element belonging to rare earth metal in the periodic table (e.g., europium (Eu) or ytterbium (Yb)), and an alloy containing any of these elements belonging to Group 1, Group 2, and the rare earth metal in appropriate combination, for example. Graphene or the like can also be used for the upper electrode 113a.

The upper electrode 113a is preferably a cathode. As a material for forming the cathode, it is preferable to use a metal, an alloy, and a conductive compound with a low work function (specifically, lower than or equal to 3.8 eV), a mixture thereof, or the like. Specifically, for example, an element belonging to Group 1 or Group 2 in the periodic table, such as lithium (Li), cesium (Cs), magnesium (Mg), calcium (Ca), or strontium (Sr), can be used as the cathode, and an alloy containing any of these elements is preferably used. For example, an alloy of silver and magnesium (sometimes referred to as MgAg) or an alloy of lithium and aluminum (sometimes referred to as AlLi) can be used.

The upper electrode 113a can have a single-layer structure or a stacked-layer structure. In this embodiment, as illustrated in FIG. 1, a stacked-layer structure including at least a first upper electrode 113a1 and a second upper electrode 113a2 is employed. Furthermore, the first upper electrode 113a1 can have a single-layer structure or a stacked-layer structure. The second upper electrode 113a2 can also have a single-layer structure or a stacked-layer structure.

As illustrated in FIG. 1, the second upper electrode 113a2, unlike the first upper electrode 113a1, can be positioned to be shared by the light-emitting devices 102. In some cases, a layer positioned to be shared by a plurality of light-emitting devices is referred to as a common layer, and a common layer functioning as an electrode is referred to as a common electrode. That is, in FIG. 1, the second upper electrode 113a2 has a function of a common electrode, and the structure of the display device 100 can be understood with the second upper electrode 113a2 rephrased as a common electrode 113a2.

For the first upper electrode 113a1 having a single-layer structure or a stacked-layer structure, two or more materials can be selected from the above specific examples. For example, the materials are preferably selected for the first upper electrode 113a1 in consideration of a work function for efficient light emission from the light-emitting device 102, and a material containing Ag is sometimes used. When a material containing Ag is used, the first upper electrode 113a1 becomes a reflective electrode; however, an extraction electrode is required to have a light-transmitting property in a top-emission display device. Thus, the reflective electrode using the material containing Ag is preferably thinned to be provided in a state of a transparent electrode. Another electrode may be stacked to protect the thinned electrode. A light-transmitting material is preferably selected for another electrode. As the light-transmitting material, IGZO, ITO, or ITSO described above is preferably selected.

For the second upper electrode 113a2 having a single-layer structure or a stacked-layer structure, two or more materials can be selected from the above specific examples. For example, a light-transmitting material is preferably selected for the second upper electrode 113a2. As the light-transmitting material, IGZO, ITO, or ITSO described above is preferably selected.

The light-emitting device 102 of one embodiment of the present invention preferably employs a microcavity structure. The microcavity structure is a structure in which light with a specific wavelength λ is resonated between an extraction electrode corresponding to the upper electrode 113a and a counter electrode corresponding to the lower electrode 111.

For resonance of light with the specific wavelength A, a reflective electrode is preferably used as the counter electrode corresponding to the lower electrode 111. The counter electrode may have a structure in which a reflective electrode and a transparent electrode are stacked. For example, when at least one reflective electrode is included as in the structure in which ITSO, APC, and ITSO are stacked in this order or the structure in which ITO, APC, and ITO are stacked in this order, each of which is described as the lower electrode 111, a function of the counter electrode in the microcavity structure can be achieved.

For resonance of light with the specific wavelength 2, an extraction electrode corresponding to the upper electrode 113a preferably has a structure in which a reflective electrode and a transparent electrode are stacked, for example. An electrode having the structure in which a reflective electrode and a transparent electrode are stacked is sometimes referred to as a transflective electrode. For example, the first upper electrode 113a1 can be the reflective electrode and the second upper electrode 113a2 can be the transparent electrode.

The transparent electrode preferably has a light transmittance higher than or equal to 40%. That is, the transparent electrode used in the light-emitting device 102 preferably has a visible light (light with a wavelength greater than or equal to 400 nm and less than 750 nm) transmittance higher than or equal to 40%.

The transflective electrode preferably has a light reflectance higher than or equal to 10% and lower than or equal to 95%, further preferably higher than or equal to 30% and lower than or equal to 80%. That is, the transflective electrode used in the light-emitting device 102 preferably has a visible light (light with a wavelength greater than or equal to 400 nm and less than 750 nm) reflectance higher than or equal to 10% and lower than or equal to 95%, further preferably higher than or equal to 30% and lower than or equal to 80%.

The reflective electrode preferably has a light reflectance higher than or equal to 40% and lower than or equal to 100%, further preferably higher than or equal to 70% and lower than or equal to 100%. That is, the reflective electrode used in the light-emitting device 102 preferably has a visible light (light with a wavelength greater than or equal to 400 nm and less than 750 nm) reflectance higher than or equal to 40% and lower than or equal to 100%, further preferably higher than or equal to 70%, preferably 100%.

The specific wavelength λ corresponds to the wavelength λ of light extracted from the light-emitting device 102. Although the light-emitting device 102 emits white light, a microcavity structure in which light with the specific wavelength λ, e.g., blue light, in white light is resonated can be used for the light-emitting device 102.

For resonance of light with the specific wavelength λ, in the light-emitting device 102, the distance between a reflective surface of the lower electrode 111 and a reflective surface of the upper electrode 113a, i.e., the optical distance is set such that nλ/2 (note that n is an integer greater than or equal to 1 and λ is a wavelength of a color to be resonated, e.g., a blue wavelength) is satisfied.

It is preferable that the display device 100 of one embodiment of the present invention include an insulating layer 104 having a depressed portion and a projected portion and the light-emitting device 102 positioned over the projected portion, and the stack 114a of the light-emitting device 102 be divided by the depressed portion of the insulating layer 104. Note that the depressed portion is formed in the insulating layer 104, whereby the projected portion is formed.

Next, a material and the like that can be used for the insulating layer 104 is described. As the insulating layer 104, an insulating layer containing an inorganic material or an insulating layer containing an organic material can be used, and an organic material is preferably used. As the organic material, a photosensitive organic resin is preferably used: for example, a photosensitive resin composition containing an acrylic resin is used. Note that an acrylic resin refers to not only a polymethacrylic acid ester or a methacrylic resin, but also all the acrylic polymer in a broad sense in some cases.

The organic material that can be used for the insulating layer 104 is not limited to the above. For the insulating layer 104, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used, for example. Alternatively, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin can be used for the insulating layer 104 in some cases. As the photosensitive resin, a photoresist can be used. As the photosensitive resin, a positive material or a negative material can be used.

For example, the insulating layer 104 is preferably formed by a wet film formation method such as spin coating, dipping, spray coating, ink-jetting, dispensing, screen printing, offset printing, doctor blade coating, slit coating, roll coating, curtain coating, or knife coating. Specifically, the insulating layer 104 is preferably formed by spin coating.

Next, the effect of dividing the stack 114a for each subpixel is considered. In a light-emitting device formed in the entire pixel region, a layer having high conductivity is sometimes used as a functional layer. As a functional layer having relatively high conductivity, a charge-generation layer can be given. When the layer having high conductivity is not divided and exists as a common layer between subpixels, leakage current flows between the subpixels. The leakage current generates crosstalk in the display device.

The leakage current or crosstalk might decrease the luminance of the light-emitting device. When a large amount of current is made to flow through the light-emitting device 102 to compensate for a decrease in luminance, deterioration of the light-emitting device 102 might be promoted. Furthermore, the leakage current or crosstalk might decrease the contrast of the display device. Moreover, the leakage current might increase power consumed by the display device.

To dispel the concern, the display device 100 of one embodiment of the present invention has a structure in which the stack 114a is divided for each subpixel, typically, a structure in which the charge-generation layer 115a is divided for each subpixel using the depressed portion of the insulating layer 104 as illustrated in FIG. 1. With this structure, leakage current can be inhibited, and crosstalk can be inhibited.

That is, the display device 100 of one embodiment of the present invention can have both the effect of forming the stack 114a in the entire pixel region and the effect of dividing the stack 114a including the charge-generation layer 115a for each subpixel.

In the display device 100 of one embodiment of the present invention, the light-emitting device 102 including the first upper electrode 113a1 may be divided as long as the above effects are obtained, and specifically, the display device 100 has a structure in which the light-emitting device 102 including the first light-emitting unit 112a1, the charge-generation layer 115a, the second light-emitting unit 112a2, and the first upper electrode 113a1 is divided using the depressed portion of the insulating layer 104 as illustrated in FIG. 1. With this structure, the display device 100 of one embodiment of the present invention can have both the effect of forming the light-emitting device 102 in the entire pixel region and the effect of dividing the light-emitting device 102 including the charge-generation layer 115a for each subpixel.

As described above, since the second upper electrode 113a2 functions as a common electrode, a structure in which the second upper electrode 113a2 is not divided between the light-emitting devices is desirable. The light-emitting device including the first upper electrode 113a1 is divided in the depressed portion of the insulating layer 104; therefore, the second upper electrode 113a2 is preferably formed after the depressed portion is filled with an insulator or the like. Specifically, in FIG. 1, an insulating layer 126 is formed to fill the depressed portion, and the insulating layer 126 is a formation surface of the second upper electrode 113a2. For the insulating layer 126, an insulating material that can fill the depressed portion of the insulating layer 104 is preferably used. Owing to the insulating layer 126 that fills the depression portion, the second upper electrode 113a2 functioning as a common electrode is less likely to be disconnected.

Furthermore, for the insulating layer 126, an insulating material making a top surface of the insulating layer 126 be flat or have a projected portion or a convex surface is preferably used. A shape of the top surface having a projected portion or a convex surface is sometimes referred to as a shape in which the center portion rises. Owing to the insulating layer 126 that has such a shape, the second upper electrode 113a2 functioning as a common electrode is much less likely to be disconnected.

Next, a material and the like of the insulating layer 126 is described. An insulating layer containing an organic material can be suitably used as the insulating layer 126. As the organic material, a photosensitive organic resin is preferably used: for example, a photosensitive resin composition containing an acrylic resin is used. The viscosity of the material for the insulating layer 126 is greater than or equal to 1 cP and less than or equal to 1500 cP, and is preferably greater than or equal to 1 cP and less than or equal to 12 cP. By setting the viscosity of the material for the insulating layer 126 in the above range, the insulating layer 126 having a tapered shape, which is to be described later, can be formed relatively easily.

The organic material that can be used for the insulating layer 126 is not limited to the above. For example, the insulating layer 126 can be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like in some cases. Alternatively, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin can be used for the insulating layer 126 in some cases. As the photosensitive resin, a photoresist can be used in some cases. As the photosensitive resin, a positive material or a negative material can be used in some cases.

The insulating layer 126 may be formed using a material absorbing visible light. When the insulating layer 126 absorbs light emitted from the light-emitting device, leakage of light (stray light) from the light-emitting device to an adjacent light-emitting device through the insulating layer 126 can be inhibited. Thus, the display quality of the display device can be improved. Since no polarizing plate is required to improve the display quality, the weight and thickness of the display device can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two colors or three or more colors is particularly preferred, in which case the effect of blocking visible light can be enhanced. In particular, mixing color filter materials of three or more colors enables the formation of a black or nearly black resin layer.

The insulating layer 126 can be formed by, for example, a wet film formation method such as spin coating, dipping, spray coating, ink-jetting, dispensing, screen printing, offset printing, a doctor knife method, slit coating, roll coating, curtain coating, or knife coating. In particular, the organic insulating film to be the insulating layer 126 is preferably formed by spin coating. The insulating layer 126 is formed at a temperature lower than the upper temperature limit of an organic compound layer. The typical substrate temperature in formation of the insulating layer 126 is lower than or equal to 200° C., preferably lower than or equal to 180° C., further preferably lower than or equal to 160° C., still further preferably lower than or equal to 150° C., yet still further preferably lower than or equal to 140° C.

The insulating layer 126 containing the material absorbing visible light preferably also has a tapered side surface.

As illustrated in FIG. 1, the insulating layer 126 is preferably provided to fill the depressed portion. Providing the insulating layer 126 in this manner can reduce an extreme depression and projection of a formation surface of a common electrode (corresponding to the second upper electrode 113a2 illustrated in FIG. 1) and make the formation surface flat. Thus, the common electrode can be prevented from being divided.

The top surface of the insulating layer 126 preferably has high planarity but may have a projected portion or a convex surface. Specifically, as illustrated in FIG. 1 and the like, the top surface of the insulating layer 126 preferably has a convex shape. Furthermore, the top surface of the insulating layer 126 may have a depressed portion or a concave surface as long as the common electrode is prevented from being divided.

Since the second upper electrode 113a2 is electrically connected to the first upper electrode 113a1, the insulating layer 126 preferably includes a contact hole. A contact hole refers to an opening portion formed in an insulating layer and enables a conductive layer positioned below the insulating layer (referred to as a lower conductive layer) to be electrically connected to a conductive layer positioned above the insulating layer (referred to as an upper conductive layer). For electrical connection, the lower conductive layer includes a region exposed in the opening portion.

In the display device 100 of one embodiment of the present invention, division of the light-emitting device 102 inhibits leakage current, crosstalk, or the like; thus, a decrease in the luminance of the light-emitting device 102 can be inhibited. Furthermore, in the display device 100 of one embodiment of the present invention, deterioration of the light-emitting device 102 can be inhibited. Moreover, one embodiment of the present invention can provide a display device with high contrast. In addition, one embodiment of the present invention can provide a display device with reduced power consumption.

When the light-emitting device 102 is divided as illustrated in FIG. 1, a stack 114x and an upper electrode 113x are positioned in the depressed portion of the insulating layer 104. The stack 114x includes a light-emitting unit 112x1, a charge-generation layer 115x, and a light-emitting unit 112x2.

The stack 114x and the upper electrode 113x contain the same material as the light-emitting device 102. Specifically, the light-emitting unit 112x1 included in the stack 114x contains the same material as the first light-emitting unit 112a1, typically, the same light-emitting material. The light-emitting unit 112x2 included in the stack 114x contains the same material as the second light-emitting unit 112a2, typically, the same light-emitting material. The charge-generation layer 115x included in the stack 114x includes the same layer as the charge-generation layer 115a included in the light-emitting device 102. The upper electrode 113x included in the stack 114x contains the same material as the first upper electrode 113a1. The “same” can be rephrased as “formation is performed through the same process as the light-emitting device 102”. Note that the stack 114x does not emit light; however, to explain that the stack 114x contains the same material or the like as the light-emitting device 102, description is made assuming that the stack 114x includes the light-emitting units 112x1 and 112x2, the charge-generation layer 115x, and the upper electrode 113x.

When the light-emitting device 102 is divided as illustrated in FIG. 1, the light-emitting unit 112x1 included in the stack 114x is positioned in the depressed portion but is not electrically connected to the first light-emitting unit 112a1. When the light-emitting device 102 is divided, the charge-generation layer 115x included in the stack 114x is also positioned in the depressed portion but is not electrically connected to the charge-generation layer 115a. When the light-emitting device 102 is divided, the light-emitting unit 112x2 included in the stack 114x is positioned in the depressed portion but is not electrically connected to the second light-emitting unit 112a2. Note that being positioned in the depressed portion means that the stack 114x or the upper electrode 113x is positioned without extending beyond an outer edge of the depressed portion in a plan view.

In order to divide the light-emitting device 102 as illustrated in FIG. 1, the depth of the depressed portion of the insulating layer 104 is considered. In order to divide the light-emitting device 102 including the upper electrode 113 (the first upper electrode 113a1 in FIG. 1) in the depressed portion, the depth of the depressed portion is preferably larger than the thickness of the light-emitting device 102. The depth of the depressed portion for dividing the light-emitting device 102 can be typically greater than or equal to 500 nm and less than or equal to 2 μm, preferably greater than or equal to 600 nm and less than or equal to 1.2 μm. The depth of the depressed portion can be calculated from a cross-sectional view. The depth of the depressed portion in the cross-sectional view refers to the distance between the deepest position of a bottom portion of the depressed portion and a top end of the insulating layer 104 that defines the depressed portion. In the case where the deepest position of the bottom portion and the top end of the insulating layer 104 do not overlap with each other, the distance can be calculated using a point where a line that is parallel to a substrate and passes through the top end of the insulating layer 104 intersects with a perpendicular line starting from the deepest position.

The depressed portion of the insulating layer 104 can be miniaturized. Since the width of the depressed portion of the insulating layer 104 becomes small, the structure in which the light-emitting device 102 is divided using the depressed portion as illustrated in FIG. 1 is suitable for a high-resolution display device. For example, the distance between adjacent light-emitting devices 102 in the display device 100 in FIG. 1 can be determined in accordance with the size of the depressed portion of the insulating layer 104, specifically, the width of the depressed portion in the cross-sectional view. The depressed portion of the insulating layer 104 can be miniaturized by an etching process or the like, and the width of the depressed portion in the cross-sectional view can be, for example, less than 10 μm, less than or equal to 8 μm, less than or equal to 5 μm, less than or equal to 3 μm, less than or equal to 2 μm, less than or equal to 1.5 μm, less than or equal to 1 μm, or less than or equal to 0.5 μm. When a light-emitting device or the like is fabricated using a fine metal mask, it is difficult to set the distance between adjacent light-emitting devices less than 10 μm; however, as described above, the display device 100 of one embodiment of the present invention can be formed such that the distance between the adjacent light-emitting devices 102 is less than 10 μm, less than or equal to 8 μm, less than or equal to 5 μm, less than or equal to 3 μm, less than or equal to 2 μm, less than or equal to 1.5 μm, less than or equal to 1 μm, or less than or equal to 0.5 μm. Accordingly, one embodiment of the present invention can provide a high-resolution display device.

The insulating layer 104 has a tapered shape in the depressed portion in some cases. In the case where the insulating layer 104 has a tapered shape, the width of the depressed portion in the cross-sectional view is the width between the top ends of the insulating layer 104 defining the depressed portion. The depressed portion of the insulating layer 104 may have a shape in which the lower portion of the insulating layer 104 has a tapered shape and a tapered shape cannot be observed in the upper portion of the insulating layer 104. That is, the insulating layer 104 defining the side surface of the depressed portion or the like may have a tapered shape, or the insulating layer 104 may have a tapered shape in the lower side surface and no tapered shape in the upper side surface.

The distance between the adjacent light-emitting devices 102 can be regarded as the distance between adjacent stacks 114a or the distance between adjacent lower electrodes 111, for example.

Although there is a non-light-emitting region between adjacent light-emitting devices 102, the distance between the adjacent light-emitting devices can be less than 10 μm in the display device 100 of one embodiment of the present invention, as described above; thus, the area of the non-light-emitting region can be reduced and the aperture ratio can be increased. For example, the display device 100 of one embodiment of the present invention can have an aperture ratio higher than or equal to 40%, higher than or equal to 50%, higher than or equal to 60%, higher than or equal to 70%, higher than or equal to 80%, or higher than or equal to 90%, and lower than 100%. Accordingly, one embodiment of the present invention can provide a display device with a high aperture ratio.

When the aperture ratio of the display device 100 is increased, the density of current flowing through the light-emitting device 102 can be reduced; thus, one embodiment of the present invention can improve the lifetime of the light-emitting device 102 and significantly improve the reliability (particularly, lifetime) of the display device. Accordingly, one embodiment of the present invention can provide a display device with a long lifetime and high reliability.

A preferable structure of an insulating layer for dividing the light-emitting device 102 is considered. As described above, the light-emitting device 102 can be divided by the insulating layer 104 including the depressed portion. Furthermore, in the display device 100 of this embodiment, the light-emitting device 102 is easily divided due to a structure in which an insulating layer 105 including a protruding portion 106 is stacked in addition to the insulating layer 104 including the depressed portion. Specifically, the display device 100 in FIG. 1 includes the insulating layer 104 and the insulating layer 105. The insulating layer 104 including the depressed portion and the insulating layer 105 including the protruding region are respectively referred to as a first insulating layer and a second insulating layer to be distinguished from each other in some cases. Next, the first insulating layer 105 is described.

As the insulating layer 105, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, the insulating layer 105 preferably includes a nitride insulating film or a nitride oxide insulating film, and further preferably includes a nitride insulating film. For the insulating layer 105, the above-described material may be used as a single layer or a stacked layer.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

The insulating layer 105 is positioned over the insulating layer 104, and the protruding portion 106 of the insulating layer 105 is a portion protruding from the top end of the insulating layer 104 defining the depressed portion. That is, the protruding portion 106 is positioned to overlap with the depressed portion. The length of the protruding portion 106 from the top end of the insulating layer 104 defining the depressed portion is preferably greater than or equal to 50 nm and less than or equal to 500 nm, further preferably greater than or equal to 80 nm and less than or equal to 300 nm in the cross-sectional view.

The protruding portion 106 having the above length can extend straight from the insulating layer 105 positioned over the projected portion of the insulating layer 104 but may extend gradually downward to the depressed portion from the insulating layer 105 positioned over the projected portion of the insulating layer 104. In order to extend the protruding portion 106 straight from the insulating layer 105 positioned over the projected portion of the insulating layer 104, it is preferable that the thickness of the insulating layer 105 be equal to or substantially equal to the length of the protruding portion 106. Being substantially equal means that a difference within ±10% of the length is included.

The insulating layer 105 including the protruding portion 106 can be observed as the insulating layer 105 including an opening portion in a plan view. It is preferable that the opening portion overlap with the depressed portion of the insulating layer 104 and an outer edge of the opening portion be positioned inside the depressed portion in the plan view. The insulating layer 104 is preferably combined with the insulating layer 105 as described above, in which case the stack 114a is easily divided.

In FIG. 1, an end of the lower electrode 111 recedes from an end of the insulating layer 105. Thus, the stack 114a can be in contact with a top surface of the insulating layer 105 that extends beyond the end of the lower electrode 111.

The end of the lower electrode 111 may be aligned with the end of the insulating layer 105. In this case, the width of the opening portion of the insulating layer 105 in the cross-sectional view can be used as the distance between the adjacent light-emitting devices 102. The opening portion of the insulating layer 105 can be miniaturized by an etching process or the like, and can be smaller than the width of the depressed portion of the insulating layer 104 in the cross-sectional view.

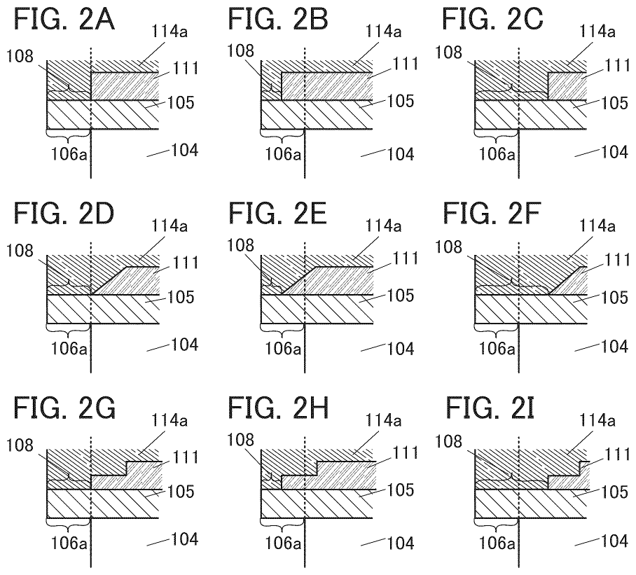

Examples of the positional relation among the insulating layer 104, the insulating layer 105, the protruding portion 106, the lower electrode 111, and the stack 114a in the above display device 100 are described with reference to FIG. 2A to FIG. 2I. Even in any positional relation, the stack 114a can be divided using the depressed portion.

FIG. 2A illustrates a protruding region 106a where the insulating layer 105 protrudes from the insulating layer 104 as the protruding portion 106 and illustrates the case where the length of the protruding region 106a is equal to the length of a region 108 where the insulating layer 105 protrudes from the lower electrode 111. The length can be regarded as the width that can be observed in a cross-sectional view. An end surface of the lower electrode 111 is positioned perpendicular or substantially perpendicular to the insulating layer 105. The stack 114a is formed at a position overlapping with the region 108; the stack 114a extending beyond the region 108 becomes the stack 114x positioned in the depressed portion, which is not illustrated in FIG. 2A, resulting in division of the stack 114a. Part of the stack 114a may be attached to an end surface of the insulating layer 105.

FIG. 2B illustrates the protruding region 106a where the insulating layer 105 protrudes from the insulating layer 104 as the protruding portion 106 and illustrates the case where the length of the protruding region 106a is greater than the length of the region 108 where the insulating layer 105 protrudes from the lower electrode 111. The length can be regarded as the width that can be observed in a cross-sectional view. The end surface of the lower electrode 111 is positioned perpendicular or substantially perpendicular to the insulating layer 105. The stack 114a is formed at a position overlapping with the region 108; the stack 114a extending beyond the region 108 becomes the stack 114x positioned in the depressed portion, which is not illustrated in FIG. 2B, resulting in division of the stack 114a. Part of the stack 114a may be attached to the end surface of the insulating layer 105.

FIG. 2C illustrates the protruding region 106a where the insulating layer 105 protrudes from the insulating layer 104 as the protruding portion 106 and illustrates the case where the length of the protruding region 106a is less than the length of the region 108 where the insulating layer 105 protrudes from the lower electrode 111. The length can be regarded as the width that can be observed in a cross-sectional view. The end surface of the lower electrode 111 is positioned perpendicular or substantially perpendicular to the insulating layer 105. The stack 114a is formed at a position overlapping with the region 108; the stack 114a extending beyond the region 108 becomes the stack 114x positioned in the depressed portion, which is not illustrated in FIG. 2C, resulting in division of the stack 114a. Part of the stack 114a may be attached to the end surface of the insulating layer 105.

FIG. 2D illustrates the protruding region 106a where the insulating layer 105 protrudes from the insulating layer 104 as the protruding portion 106 and illustrates the case where the length of the protruding region 106a is equal to the length of the region 108 where the insulating layer 105 protrudes from a lower end of the lower electrode 111. The length can be regarded as the width that can be observed in a cross-sectional view. The end of the lower electrode 111 has a tapered shape. The taper angle of the lower electrode 111 is greater than or equal to 20° and less than or equal to 85°, preferably greater than or equal to 30° and less than or equal to 60°. The stack 114a is formed at a position overlapping with the region 108; the stack 114a extending beyond the region 108 becomes the stack 114x positioned in the depressed portion, which is not illustrated in FIG. 2D, resulting in division of the stack 114a. Part of the stack 114a may be attached to the end surface of the insulating layer 105.

FIG. 2E illustrates the protruding region 106a where the insulating layer 105 protrudes from the insulating layer 104 as the protruding portion 106 and illustrates the case where the length of the protruding region 106a is greater than the length of the region 108 where the insulating layer 105 protrudes from the lower end of the lower electrode 111. The length can be regarded as the width that can be observed in a cross-sectional view. The end of the lower electrode 111 has a tapered shape. The taper angle of the lower electrode 111 is greater than or equal to 20° and less than or equal to 85°, preferably greater than or equal to 30° and less than or equal to 60°. The stack 114a is formed at a position overlapping with the region 108; the stack 114a extending beyond the region 108 becomes the stack 114x positioned in the depressed portion, which is not illustrated in FIG. 2E, resulting in division of the stack 114a. Part of the stack 114a may be attached to the end surface of the insulating layer 105.

FIG. 2F illustrates the protruding region 106a where the insulating layer 105 protrudes from the insulating layer 104 as the protruding portion 106 and illustrates the case where the length of the protruding region 106a is less than the length of the region 108 where the insulating layer 105 protrudes from the lower end of the lower electrode 111. The length can be regarded as the width that can be observed in a cross-sectional view. The end of the lower electrode 111 has a tapered shape. The taper angle of the lower electrode 111 is greater than or equal to 20° and less than or equal to 85°, preferably greater than or equal to 30° and less than or equal to 60°. The stack 114a is formed at a position overlapping with the region 108; the stack 114a extending beyond the region 108 becomes the stack 114x positioned in the depressed portion, which is not illustrated in FIG. 2F, resulting in division of the stack 114a. Part of the stack 114a may be attached to the end surface of the insulating layer 105.

FIG. 2G illustrates the protruding region 106a where the insulating layer 105 protrudes from the insulating layer 104 as the protruding portion 106 and illustrates the case where the length of the protruding region 106a is equal to the length of the region 108 where the insulating layer 105 protrudes from the lower end of the lower electrode 111. The length can be regarded as the width that can be observed in a cross-sectional view. The end of the lower electrode 111 has a multistep shape, and for example, can have a shape in which the lower side of the lower electrode protrudes more than the upper side of the lower electrode. The end of the lower electrode 111 having a multistep shape may have a tapered shape, and the taper angle is greater than or equal to 20° and less than or equal to 85°, preferably greater than or equal to 30° and less than or equal to 60°. The stack 114a is formed at a position overlapping with the region 108; the stack 114a extending beyond the region 108 becomes the stack 114x positioned in the depressed portion, which is not illustrated in FIG. 2G, resulting in division of the stack 114a. Part of the stack 114a may be attached to the end surface of the insulating layer 105.

FIG. 2H illustrates the protruding region 106a where the insulating layer 105 protrudes from the insulating layer 104 as the protruding portion 106 and illustrates the case where the length of the protruding region 106a is greater than the length of the region 108 where the insulating layer 105 protrudes from the lower end of the lower electrode 111. The length can be regarded as the width that can be observed in a cross-sectional view. The end of the lower electrode 111 has a multistep shape, and for example, can have a shape in which the lower side of the lower electrode protrudes more than the upper side of the lower electrode. The end of the lower electrode 111 having a multistep shape may have a tapered shape, and the taper angle is greater than or equal to 20° and less than or equal to 85°, preferably greater than or equal to 30° and less than or equal to 60°. The stack 114a is formed at a position overlapping with the region 108; the stack 114a extending beyond the region 108 becomes the stack 114x positioned in the depressed portion, which is not illustrated in FIG. 2H, resulting in division of the stack 114a. Part of the stack 114a may be attached to the end surface of the insulating layer 105.

FIG. 2I illustrates the protruding region 106a where the insulating layer 105 protrudes from the insulating layer 104 as the protruding portion 106 and illustrates the case where the length of the protruding region 106a is less than the length of the region 108 where the insulating layer 105 protrudes from the lower end of the lower electrode 111. The length can be regarded as the width that can be observed in a cross-sectional view. The end of the lower electrode 111 has a multistep shape, and for example, can have a shape in which the lower side of the lower electrode protrudes more than the upper side of the lower electrode. The end of the lower electrode 111 having a multistep shape may have a tapered shape, and the taper angle is greater than or equal to 20° and less than or equal to 85°, preferably greater than or equal to 30° and less than or equal to 60°. The stack 114a is formed at a position overlapping with the region 108; the stack 114a extending beyond the region 108 becomes the stack 114x positioned in the depressed portion, which is not illustrated in FIG. 2I, resulting in division of the stack 114a. Part of the stack 114a may be attached to the end surface of the insulating layer 105.

### Modification Example 1 of Display Device

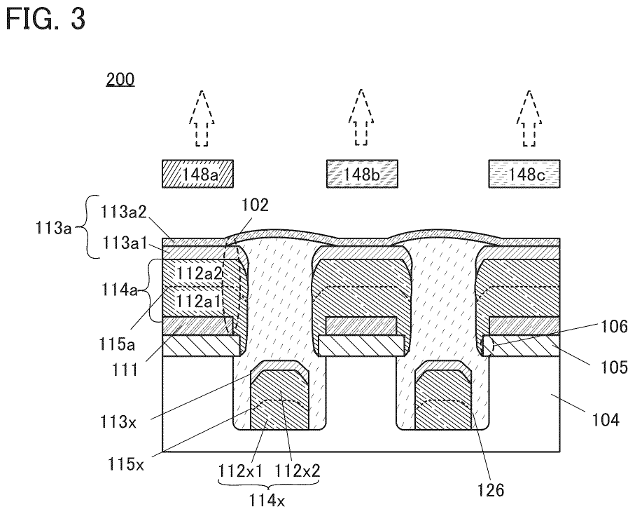

FIG. 3 illustrates a display device 200 which is different from the display device 100 in FIG. 1 in that the stack 114a is attached to the end surface of the insulating layer 105. Since the other components of the display device 200 are similar to those of the display device 100 in FIG. 1, the description thereof is omitted.

When the light-emitting device 102 is divided using the depressed portion of the insulating layer 104, part of the stack 114a is formed on the end surface of the insulating layer 105, i.e., the stack 114a is attached to the end surface in some cases. Also in the display device 200 of one embodiment of the present invention, leakage current or crosstalk can be inhibited.

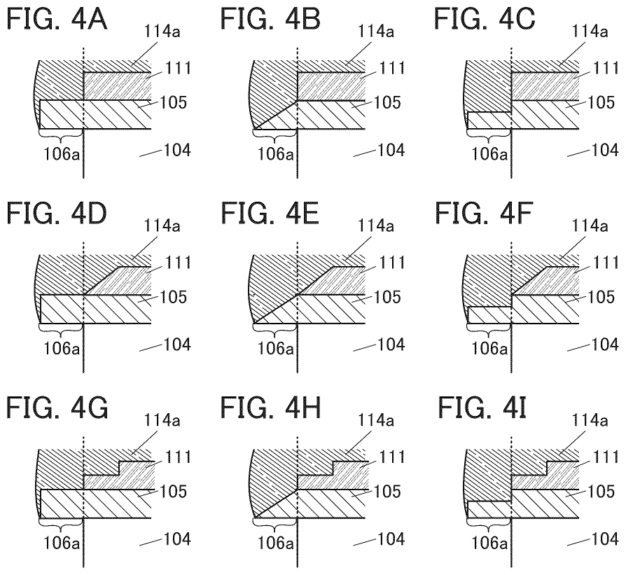

Examples of the positional relation among the insulating layer 104, the insulating layer 105, the protruding portion 106, the lower electrode 111, and the stack 114a in the above display device 200 are described with reference to FIG. 4A to FIG. 4I. Even in any positional relation, part of the stack 114a is formed on the end surface of the insulating layer 105 in addition to the top surface thereof. The end surface of the insulating layer 105 includes a side surface of the insulating layer 105, a tapered top surface of the insulating layer 105, a multistep top surface of the insulating layer 105, and the like.

FIG. 4A illustrates the protruding region 106a where the insulating layer 105 protrudes from the insulating layer 104 as the protruding portion 106. Although the region 108 is not illustrated in FIG. 4A, the width of the region 108 can be changed with reference to FIG. 2A to FIG. 2I. The end surface of the insulating layer 105 is positioned perpendicular or substantially perpendicular to the insulating layer 104. Furthermore, the end surface of the lower electrode 111 is positioned perpendicular or substantially perpendicular to the insulating layer 105. The stack 114a is formed at a position overlapping with the protruding region 106a and at a position overlapping with the side surface of the insulating layer 105. Although not illustrated in FIG. 4A, the stack 114a extending beyond the protruding portion 106 becomes the stack 114x positioned in the depressed portion, resulting in division of the stack 114a. Part of the stack 114a is not necessarily attached to the end surface of the insulating layer 105.

FIG. 4B illustrates the protruding region 106a where the insulating layer 105 protrudes from the insulating layer 104 as the protruding portion 106. Although the region 108 is not illustrated in FIG. 4B, the width of the region 108 can be changed with reference to FIG. 2A to FIG. 2I. The end surface of the insulating layer 105 has a tapered shape. Furthermore, the end surface of the lower electrode 111 is positioned perpendicular or substantially perpendicular to the insulating layer 105. The stack 114a is formed at a position overlapping with the protruding region 106a and at a position overlapping with the tapered top surface of the insulating layer 105. Although not illustrated in FIG. 4B, the stack 114a extending beyond the protruding portion 106 becomes the stack 114x positioned in the depressed portion, resulting in division of the stack 114a. Part of the stack 114a is not necessarily attached to the tapered top surface of the insulating layer 105.

FIG. 4C illustrates the protruding region 106a where the insulating layer 105 protrudes from the insulating layer 104 as the protruding portion 106. Although the region 108 is not illustrated in FIG. 4C, the width of the region 108 can be changed with reference to FIG. 2A to FIG. 2I. The end surface of the insulating layer 105 has a multistep shape. Furthermore, the end surface of the lower electrode 111 is positioned perpendicular or substantially perpendicular to the insulating layer 105. The stack 114a is formed at a position overlapping with the protruding region 106a and at a position overlapping with the multistep top surface of the insulating layer 105. Although not illustrated in FIG. 4C, the stack 114a extending beyond the protruding portion 106 becomes the stack 114x positioned in the depressed portion, resulting in division of the stack 114a. Part of the stack 114a is not necessarily attached to the multistep top surface of the insulating layer 105.

FIG. 4D illustrates the protruding region 106a where the insulating layer 105 protrudes from the insulating layer 104 as the protruding portion 106. Although the region 108 is not illustrated in FIG. 4D, the width of the region 108 can be changed with reference to FIG. 2A to FIG. 2I. The end surface of the insulating layer 105 is positioned perpendicular or substantially perpendicular to the insulating layer 104. An end portion of the lower electrode 111 has a tapered shape. The stack 114a is formed at a position overlapping with the protruding region 106a and at a position overlapping with the side surface of the insulating layer 105. Although not illustrated in FIG. 4D, the stack 114a extending beyond the protruding portion 106 becomes the stack 114x positioned in the depressed portion, resulting in division of the stack 114a. Part of the stack 114a is not necessarily attached to the end surface of the insulating layer 105.

FIG. 4E illustrates the protruding region 106a where the insulating layer 105 protrudes from the insulating layer 104 as the protruding portion 106. Although the region 108 is not illustrated in FIG. 4E, the width of the region 108 can be changed with reference to FIG. 2A to FIG. 2I. The end surface of the insulating layer 105 preferably has a tapered shape. The end portion of the lower electrode 111 has a tapered shape. The stack 114a is formed at a position overlapping with the protruding region 106a and at a position overlapping with the tapered top surface of the insulating layer 105. Although not illustrated in FIG. 4E, the stack 114a extending beyond the protruding portion 106 becomes the stack 114x positioned in the depressed portion, resulting in division of the stack 114a. Part of the stack 114a is not necessarily attached to the tapered top surface of the insulating layer 105.

FIG. 4F illustrates the protruding region 106a where the insulating layer 105 protrudes from the insulating layer 104 as the protruding portion 106. Although the region 108 is not illustrated in FIG. 4F, the width of the region 108 can be changed with reference to FIG. 2A to FIG. 2I. The end surface of the insulating layer 105 has a multistep shape. The end portion of the lower electrode 111 has a tapered shape. The stack 114a is formed at a position overlapping with the protruding region 106a and at a position overlapping with the multistep top surface of the insulating layer 105. Although not illustrated in FIG. 4F, the stack 114a extending beyond the protruding portion 106 becomes the stack 114x positioned in the depressed portion, resulting in division of the stack 114a. Part of the stack 114a is not necessarily attached to the multistep top surface of the insulating layer 105.

FIG. 4G illustrates the protruding region 106a where the insulating layer 105 protrudes from the insulating layer 104 as the protruding portion 106. Although the region 108 is not illustrated in FIG. 4G, the width of the region 108 can be changed with reference to FIG. 2A to FIG. 2I. The end surface of the insulating layer 105 is positioned perpendicular or substantially perpendicular to the insulating layer 104. Furthermore, the end portion of the lower electrode 111 has a multistep shape. The stack 114a is formed at a position overlapping with the protruding region 106a and at a position overlapping with the side surface of the insulating layer 105. Although not illustrated in FIG. 4G, the stack 114a extending beyond the protruding portion 106 becomes the stack 114x positioned in the depressed portion, resulting in division of the stack 114a. Part of the stack 114a is not necessarily attached to the end surface of the insulating layer 105.

FIG. 4H illustrates the protruding region 106a where the insulating layer 105 protrudes from the insulating layer 104 as the protruding portion 106. Although the region 108 is not illustrated in FIG. 4H, the width of the region 108 can be changed with reference to FIG. 2A to FIG. 2I. The end surface of the insulating layer 105 preferably has a tapered shape. Furthermore, the end portion of the lower electrode 111 has a multistep shape. The stack 114a is formed at a position overlapping with the protruding region 106a and at a position overlapping with the tapered top surface of the insulating layer 105. Although not illustrated in FIG. 4H, the stack 114a extending beyond the protruding portion 106 becomes the stack 114x positioned in the depressed portion, resulting in division of the stack 114a. Part of the stack 114a is not necessarily attached to the tapered top surface of the insulating layer 105.

FIG. 4I illustrates the protruding region 106a where the insulating layer 105 protrudes from the insulating layer 104 as the protruding portion 106. Although the region 108 is not illustrated in FIG. 4I, the width of the region 108 can be changed with reference to FIG. 2A to FIG. 2I. The end surface of the insulating layer 105 has a multistep shape. Furthermore, the end portion of the lower electrode 111 has a multistep shape. The stack 114a is formed at a position overlapping with the protruding region 106a and at a position overlapping with the multistep top surface of the insulating layer 105. Although not illustrated in FIG. 4I, the stack 114a extending beyond the protruding portion 106 becomes the stack 114x positioned in the depressed portion, resulting in division of the stack 114a. Part of the stack 114a is not necessarily attached to the tapered multistep top surface of the insulating layer 105.

### Modification Example 2 of Display Device

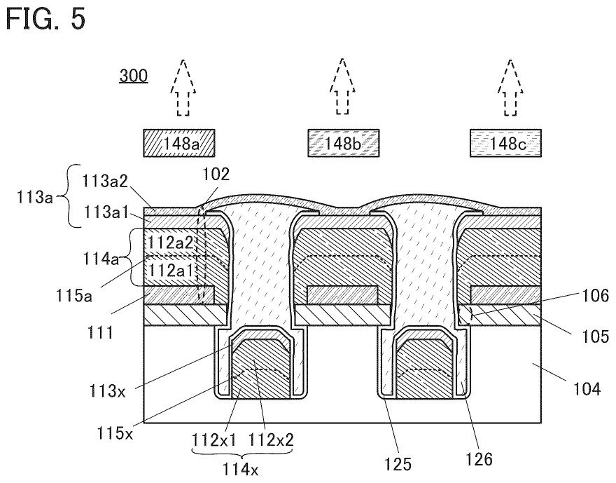

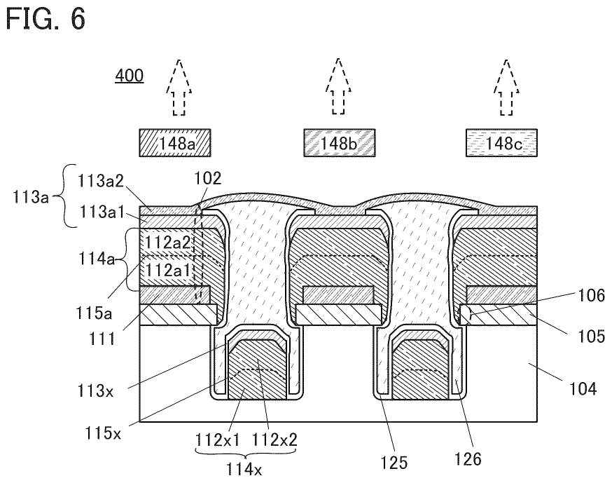

FIG. 5 illustrates a display device 300 in which an insulating layer 125 is added to the display device 100 in FIG. 1. FIG. 6 illustrates a display device 400 in which the insulating layer 125 is added to the display device 200 in FIG. 3. In FIG. 5 and FIG. 6, the insulating layer 125 is preferably provided to cover part of a top surface of the first upper electrode 113a1 and to be positioned between the insulating layer 126 and the stack 114a. Furthermore, it is preferable that the insulating layer 125 cover the end surface of the insulating layer 105 and adhesion between the layers covered by the insulating layer 125 and the insulating layer 105 be increased. Furthermore, the insulating layer 125 can be provided to cover a surface and the like of the depressed portion of the insulating layer 104 and to cover the stack 114x, the upper electrode 113x, and the like in the depressed portion.

Furthermore, in the insulating layer 125, a first opening portion is provided so as to overlap with the top surface of the first upper electrode 113a1. A second opening portion of the insulating layer 126 is provided at a position overlapping with the first opening portion. For example, in the top surface of the first upper electrode 113a1, an end portion of the insulating layer 125 defining the first opening portion is preferably positioned to overlap with an end portion of the insulating layer 126 defining the second opening portion. Alternatively, when the end portion of the insulating layer 125 defining the first opening portion is positioned to recede from the end portion of the insulating layer 126 defining the second opening portion in the top surface of the first upper electrode 113a1, the insulating layer 126 covers the end portion of the insulating layer 125; thus, division of a common electrode (corresponding to the second upper electrode 113a2 illustrated in FIG. 5 and FIG. 6) can be inhibited. Alternatively, when the end portion of the insulating layer 126 defining the second opening portion is positioned to recede from the end portion of the insulating layer 125 defining the first opening portion, the first upper electrode 113a1 can be inhibited from being in contact with the insulating layer 126.

The insulating layer 125 can cover a side surface of the stack 114a, and deterioration or film separation of the stack 114a can be inhibited.

As illustrated in FIG. 5 and FIG. 6, the insulating layer 126 is preferably provided to fill a depressed portion along a surface of the insulating layer 125. Providing the insulating layer 126 in this manner can reduce an extreme depression and projection of a formation surface of the common electrode (corresponding to the second upper electrode 113a2 illustrated in FIG. 5 and FIG. 6) and make the formation surface flat. Thus, the common electrode can be prevented from being divided.

The top surface of the insulating layer 126 preferably has high planarity but may have a projected portion or a convex surface. Specifically, as illustrated in FIG. 5, FIG. 6, and the like, the top surface of the insulating layer 126 preferably has a convex shape. Furthermore, the top surface of the insulating layer 126 may have a depressed portion or a concave surface as long as the common electrode is prevented from being divided.

Film separation of the stack 114a can be prevented by the insulating layer 125 provided in contact with a side surface of the light-emitting device 102. Accordingly, the reliability of the light-emitting device can be improved. In addition, the manufacturing yield of the light-emitting device can be increased.

The insulating layer 125 provided in contact with the side surface of the light-emitting device 102 can function as a protective layer of the light-emitting device 102. Providing the insulating layer 125 can inhibit entry of impurities (e.g., oxygen and moisture) into the inside of the light-emitting device 102 through its side surface, resulting in a highly reliable display device.

Here, examples of a material and a formation method of the insulating layer 125 are described.

The insulating layer 125 can be an insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferable because it has high selectivity with respect to an EL layer in etching and has a function of protecting the EL layer in formation of the insulating layer 126. An inorganic insulating film such as an aluminum oxide film, a hafnium oxide film, or a silicon oxide film is formed by an ALD method as the insulating layer 125, whereby the insulating layer 125 can have few pinholes and an excellent function of protecting the EL layer. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a protective layer against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

Note that in this specification and the like, a protective layer includes an insulating layer having a barrier property. A barrier property in this specification and the like refers to a function of inhibiting diffusion of a particular substance (also referred to as having low permeability). A barrier property includes a function of capturing or fixing (also referred to as gettering) a particular substance.

When the insulating layer 125 functions as a protective layer, entry of an impurity (typically, at least one of water and oxygen) into the light-emitting device 102 from the outside can be inhibited. With this structure, a highly reliable light-emitting device and a highly reliable display device can be provided.

The concentration of the impurity in the insulating layer 125 is preferably low. For example, the concentration of the impurity in the insulating layer 125 is preferably lower than that in the insulating layer 126. Specifically, it is preferable that one or both of a hydrogen concentration and a carbon concentration in the insulating layer 125 be sufficiently low. Accordingly, deterioration of the light-emitting device, which is caused by entry of the impurity into the light-emitting device from the insulating layer 125, can be inhibited. Furthermore, the insulating layer 125 having a low impurity concentration can function as a protective layer having a high barrier property against at least one of water and oxygen.

Examples of the formation method of the insulating layer 125 include a sputtering method, a chemical vapor deposition (CVD) method, a pulsed laser deposition (PLD) method, and an ALD method. The insulating layer 125 is preferably formed by an ALD method achieving good coverage.

When the substrate temperature in forming the insulating layer 125 is increased, the formed insulating layer 125, even with a small thickness, can have a low impurity concentration and a high barrier property against at least one of water and oxygen. Therefore, the substrate temperature is preferably higher than or equal to 60° C., further preferably higher than or equal to 80° C., still further preferably higher than or equal to 100° C., yet further preferably higher than or equal to 120° C. Meanwhile, the insulating layer 125 is formed after formation of the stack 114a, it is preferable that the insulating layer 125 be formed at a temperature lower than the upper temperature limit of the stack 114a. Therefore, the substrate temperature is preferably lower than or equal to 200° C., further preferably lower than or equal to 180° C., still further preferably lower than or equal to 160° C., yet further preferably lower than or equal to 150° C., yet still further preferably lower than or equal to 140° C.

Examples of temperatures used as indicators of the upper temperature limit include the glass transition point, the softening point, the melting point, the thermal decomposition temperature, and the 5% weight loss temperature. The upper temperature limit of the stack 114a can be any of the above temperatures, preferably the lowest temperature thereof.

The thickness of the insulating layer 125 is preferably greater than or equal to 3 nm, greater than or equal to 5 nm, or greater than or equal to 10 nm and less than or equal to 200 nm, less than or equal to 150 nm, less than or equal to 100 nm, or less than or equal to 50 nm, for example.

The insulating layer 126 provided over the insulating layer 125 has a function of planarizing a depression and a projection on the surface of the insulating layer 125 formed between adjacent light-emitting devices. In other words, the insulating layer 126 can improve the planarity of the formation surface of the common electrode.

For the other components of the display device 300 in FIG. 5, the components described with reference to FIG. 1 can be used. For the other components of the display device 400 in FIG. 6, the components described with reference to FIG. 1 can be used.

### Modification Example 3 of Display Device

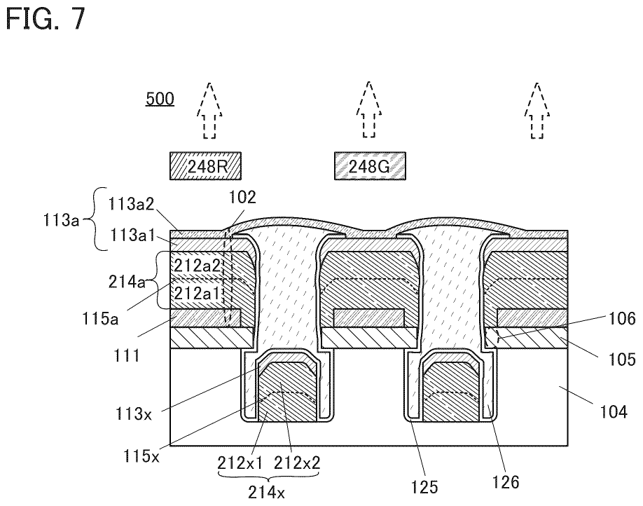

FIG. 7 illustrates a display device 500 including a stack 214a used for a blue light-emitting device instead of the stack 114a of the display device 300 in FIG. 5. The stack 214a can have a tandem structure or a single structure, and a tandem structure is employed in FIG. 7. Specifically, in FIG. 7, the light-emitting device 102 includes the charge-generation layer 115a, and a first light-emitting unit 212a1 on the lower electrode 111 side and a second light-emitting unit 212a2 on the upper electrode 113 side with the charge-generation layer 115a therebetween. The display device 500 in FIG. 7 is different from the display devices in FIG. 1 and FIG. 5 in that blue is exhibited from the light-emitting device 102 including the first light-emitting unit 212a1 and the second light-emitting unit 212a2. Thus, in the display device 500 in FIG. 7, a color conversion layer 248R is provided for a red subpixel, a color conversion layer 248G is provided for a green subpixel, and a color conversion layer for a blue subpixel is omitted.

In the display device 500 in FIG. 7, a stack 214x including a light-emitting unit 212x1 and a light-emitting unit 212x2 is formed in the depressed portion of the insulating layer 104. The charge-generation layer 115x is positioned between the light-emitting unit 212x1 and the light-emitting unit 212x2, and the upper electrode 113x is positioned over the stack 214x.

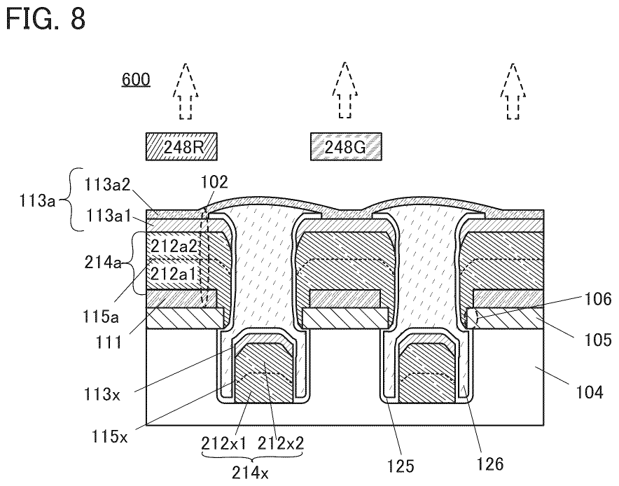

FIG. 8 illustrates a display device 600 including the stack 214a used for a blue light-emitting device instead of the stack 114a of the display device 400 in FIG. 6. The stack 214a can have a tandem structure or a single structure, and a tandem structure is employed in FIG. 7. Specifically, in FIG. 7, the light-emitting device 102 includes the charge-generation layer 115a, and the first light-emitting unit 212a1 on the lower electrode 111 side and the second light-emitting unit 212a2 on the upper electrode 113 side with the charge-generation layer 115a therebetween. The display device 600 in FIG. 8 is different from the display devices in FIG. 3 and FIG. 6 in that blue is exhibited from the light-emitting device 102 including the first light-emitting unit 212a1 and the second light-emitting unit 212a2. Thus, in the display device 600 in FIG. 8, the color conversion layer 248R is provided for a red subpixel, the color conversion layer 248G is provided for a green subpixel, and a color conversion layer for a blue subpixel is omitted.

In the display device 600 in FIG. 8, the stack 214x including the light-emitting unit 212x1 and the light-emitting unit 212x2 is formed in the depressed portion of the insulating layer 104. The charge-generation layer 115x is positioned between the light-emitting unit 212x1 and the light-emitting unit 212x2, and the upper electrode 113x is positioned over the stack 214x.

For the color conversion layer, a phosphor or a quantum dot (QD) is preferably used. A quantum dot has an emission spectrum with a narrow peak, so that emission with high color purity can be obtained. Thus, the display quality of the display device can be improved.

### Specific Example 1 of Display Device

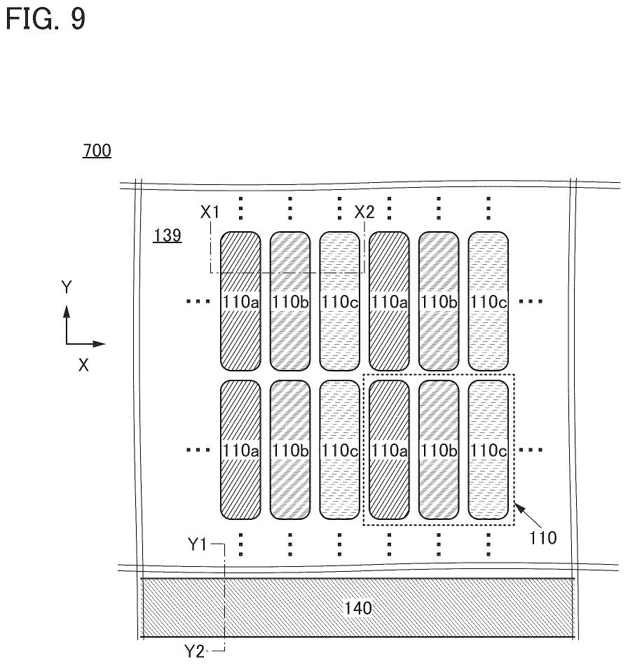

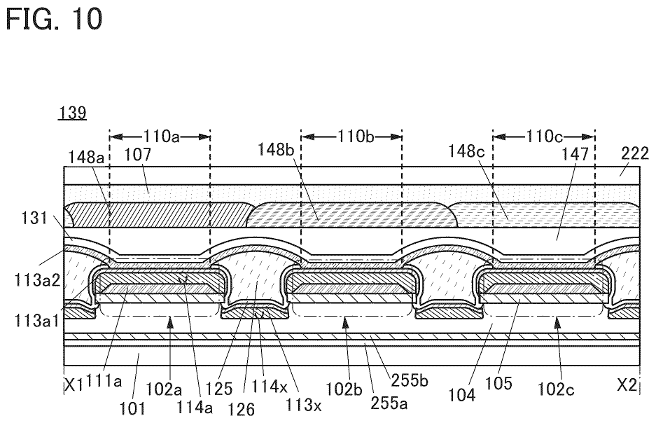

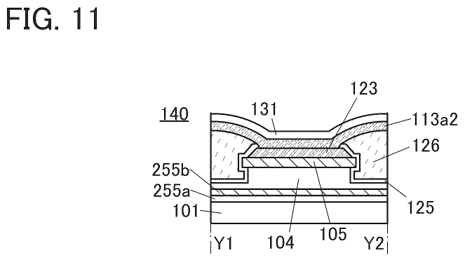

As a specific example, FIG. 9 illustrates a top view of a display device 700, and FIG. 10 and FIG. 11 illustrate cross-sectional views of the display device 700. The cross-sectional view in FIG. 10 illustrates a structure in which the end portion of the lower electrode 111 has a tapered shape as illustrated in FIG. 2D and the like and the insulating layer 125 and the insulating layer 126 are included as illustrated in FIG. 5 and the like.

As illustrated in FIG. 9, the display device 700 includes a pixel region 139 where a plurality of pixels 110 are provided and a connection region 140 positioned outside the pixel region 139. The pixel region is sometimes referred to as a pixel portion or a display region. The connection region 140 is sometimes referred to as a cathode contact region. The pixels 110 illustrated in FIG. 9 each include three subpixels 110a, 110b, and 110c, and FIG. 9 illustrates the pixels in two rows and two columns and the subpixels in two rows and six columns. In FIG. 9, the subpixels are arranged in a matrix, specifically in a stripe pattern.

In FIG. 9, the row direction of the pixel region 139 is referred to as the X direction and the column direction thereof is referred to as the Y direction in some cases, and the X direction and the Y direction can be used for the description of the subpixel and the like. In FIG. 9 in which the subpixels are arranged in the stripe pattern, the subpixels of different colors are arranged along the X direction and the subpixels of the same color are arranged along the Y direction. Note that the X direction and the Y direction can intersect with each other.

Although FIG. 9 illustrates an example in which the connection region 140 is positioned on the lower side of the pixel region 139, one embodiment of the present invention is not limited thereto. The connection region 140 is provided on at least one of the upper side, the right side, the left side, and the lower side of the pixel region 139 in a plan view, and may be provided so as to surround the four sides of the pixel region 139. A top surface of the connection region 140 provided at the one position can have a belt-like shape, an L-like shape, a U-like shape, a frame-like shape, or the like. The connection region 140 may be provided on two or more sides selected from the upper side, the right side, the left side, and the lower side of the pixel region 139.

FIG. 10 illustrates a cross-sectional view along the dashed-dotted line X1-X2 in FIG. 9. FIG. 10 includes regions corresponding to the subpixels 110a. 110b, and 110c, and a state where the subpixels include light-emitting devices 102a. 102b, and 102c is illustrated in the cross-sectional view: The light-emitting device 102a is preferably a white-light-emitting device like the above light-emitting device 102. The light-emitting devices 102b and 102c each have a structure similar to that of the light-emitting device 102a.

As illustrated in FIG. 10, in the subpixels 110a. 110b, and 110c, the color filters 148a. 148c, and 148c are positioned to overlap with the light-emitting devices. Since the color filters 148a, 148c, and 148c transmit light with different wavelengths, the subpixels 110a, 110b, and 110c emit light of different colors. Examples of a combination of different colors include three colors of red (R), green (G), and blue (B) and three colors of yellow (Y), cyan (C), and magenta (M). The combination of different colors is not limited to a combination of three colors, and may be a combination of four or more colors. For example, four colors of R, G, B, and white (W) or four colors of R, G, B, and Y can be given. The emission colors may be made different among the subpixels 110a, 110b, and 110c by using a color conversion layer instead of the color filter 148. When a color conversion layer is used, any of the structures described with reference to FIG. 7, FIG. 8, and the like may be employed. That is, the light-emitting devices 102a, 102b, and 102c may be blue light-emitting devices, and a color conversion layer for a blue subpixel can be omitted.

Adjacent color filters 148 preferably include an overlapping region. Specifically, the adjacent color filters 148 preferably include an overlapping region in a region not overlapping with the light-emitting devices 102a. 102b, and 102c. For example, as illustrated in FIG. 10, part of the color filter 148b overlaps with part of the color filter 148a in a region between the light-emitting device 102a and the light-emitting device 102b, i.e., between the subpixel 110a and the subpixel 110b. Although part of the color filter 148a is positioned over part of the color filter 148b, part of the color filter 148b may be positioned over part of the color filter 148a. In this manner, a region where the color filters 148 transmitting light of different colors overlap with each other can function as a light-blocking region, and a light-blocking layer is not necessarily provided in addition to the color filters 148. The light-blocking region is preferably positioned to overlap with the insulating layer 126. The light-blocking region can inhibit leakage of light emitted from the light-emitting device 102a into the adjacent subpixel 110b, for example. Accordingly, the contrast of images displayed on the display device can be increased, and the display device can have high display quality. Note that although the description is made using the relation between the color filter 148a and the color filter 148b, the same applies to the relation between the color filter 148a and the color filter 148c and the relation between the color filter 148b and the color filter 148c.

The color filter 148 is preferably formed on a flat formation surface. For example, as illustrated in FIG. 10 and the like, the color filter 148 is preferably provided over a resin layer 147 functioning as a planarization film. Accordingly, the color filter 148 can be inhibited from having an uneven shape due to the formation surface, and diffused reflection of light emitted from the light-emitting device 102 due to the unevenness of the color filter 148 is inhibited. Thus, the display quality of the display device can be improved.

As illustrated in FIG. 10, the display device 700 includes a substrate 101, and a layer including a transistor is provided over the substrate 101; however, the layer including a transistor is not illustrated. The insulating layers 255a, 255b, 104, and 105 are provided in this order over the layer including a transistor, and the light-emitting devices 102a, 102b, and 102c are provided over the insulating layer 105.

The insulating layer 125 and the insulating layer 126 are provided in a region between the adjacent light-emitting devices.

Although FIG. 10 and the like illustrate a plurality of cross sections of the insulating layers 125 and the insulating layers 126, when the display device 700 is seen from above, the insulating layers 125 and the insulating layers 126 are each one continuous layer. Note that the display device 700 may include a plurality of the insulating layers 125 which are separated from each other and a plurality of the insulating layers 126 which are separated from each other.

As illustrated in FIG. 10, the side surface of the stack 114a is covered with the insulating layer 125 and the insulating layer 126 in some cases. A side surface of the first upper electrode 113a1 positioned above the stack 114a is covered with the insulating layer 125 and the insulating layer 126 in some cases. That is, the insulating layer 125 and the insulating layer 126 are positioned to cover a side surface of the light-emitting device 102a. Accordingly, the reliability of the light-emitting device can be improved.

Hereinafter, a structure of the insulating layer 126 and the like is described using the structure of the insulating layer 126 between the light-emitting device 102a and the light-emitting device 102b as an example. Note that the same can apply to the insulating layer 126 between the light-emitting device 102b and the light-emitting device 102c, the insulating layer 126 between the light-emitting device 102c and the light-emitting device 102a, and the like.

In the cross-sectional view of the display device, the end portion of the insulating layer 126 preferably has a tapered shape above the first upper electrode 113a1. The taper angle θ of the tapered shape is an angle formed by a side surface of the insulating layer 126 and a substrate surface. In the case where the side surface of the insulating layer 126 has a tapered shape, a side surface of the insulating layer 125 preferably also has a tapered shape.

The taper angle θ of the insulating layer 126 is less than 90°, preferably less than or equal to 60°, further preferably less than or equal to 45°. Such a forward tapered shape of the end portion of the side surface of the insulating layer 126 can prevent division, local thinning, or the like from occurring in the second upper electrode 113a2 which are provided over the end portion of the side surface of the insulating layer 126, leading to formation with good coverage. This can improve the display quality of the display device.

The top surface of the insulating layer 126 preferably has a convex shape in the cross-sectional view of the display device. The convex shape of the top surface of the insulating layer 126 is preferably a shape gently bulged toward the center. The insulating layer 126 preferably has a shape such that the projecting portion at the center portion of the top surface is connected smoothly to the tapered portion of the end portion of the side surface. When the insulating layer 126 has such a shape, the second upper electrode 113a2 can be formed with good coverage over the entire insulating layer 126.

As described above, providing the insulating layer 126 and the like can prevent division and local thinning from occurring in the second upper electrode 113a2. Accordingly, the display quality of the display device of one embodiment of the present invention can be improved.

As illustrated in FIG. 10, a protective layer 131 is preferably provided over the light-emitting devices 102a, 102b, and 102c. Providing the protective layer 131 can improve the reliability of the light-emitting devices. The protective layer 131 may have a single-layer structure, and may have a stacked-layer structure including two or more layers.

There is no limitation on the conductivity of the protective layer 131. As the protective layer 131, at least one kind of an insulating film, a semiconductor film, and a conductive film can be used.

The protective layer 131 including an inorganic film can inhibit deterioration of the light-emitting devices by preventing oxidation of the second upper electrode 113a2 and inhibiting entry of impurities (e.g., moisture and oxygen) into the light-emitting devices, for example: thus, the reliability of the display device can be improved.

As the protective layer 131, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, the protective layer 131 preferably includes a nitride insulating film or a nitride oxide insulating film, and further preferably includes a nitride insulating film.

When light emitted from the light-emitting device is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can employ, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (such as water and oxygen) into the EL layer.

Furthermore, the protective layer 131 may include an organic film. For example, the protective layer 131 may include both an organic film and an inorganic film. Examples of an organic material that can be used for the protective layer 131 include organic insulating materials that can be used for the resin layer 147 described later.

The protective layer 131 may have a stacked structure of two layers that are formed by different film formation methods. Specifically, the first layer of the protective layer 131 may be formed by an atomic layer deposition (ALD) method, and the second layer of the protective layer 131 may be formed by a sputtering method.

In FIG. 10, the resin layer 147 is provided over the protective layer 131, and the color filter 148 is provided over the resin layer 147. By providing the resin layer 147 over the protective layer 131, even the case where a defect such as a pinhole exists in the protective layer 131, for example, the defect can be filled with the resin layer 147 with high step coverage.

As illustrated in FIG. 10, in the display device 700, an adhesive layer 107 and a substrate 222 are provided over the color filter 148. That is, the substrate 222 is bonded to the substrate 101 with the adhesive layer 107 therebetween.

As illustrated in FIG. 10, the display device of one embodiment of the present invention is a top-emission structure in which light is emitted in a direction opposite to the substrate where the light-emitting device is formed. However, this invention is not limited thereto, a bottom-emission structure in which light is emitted toward the substrate where the light-emitting device is formed or a dual-emission structure in which light is emitted toward both surfaces may be employed.

As the light-emitting devices 102a, 102b, and 102c, organic light-emitting diodes (OLEDs), quantum-dot light-emitting diodes (QLEDs), and the like are preferably used.

Examples of a light-emitting material contained in the light-emitting devices 102a, 102b, and 102c include a substance that emits fluorescent light (a fluorescent material), a substance that emits phosphorescent light (a phosphorescent material), and a substance that exhibits thermally activated delayed fluorescence (a thermally activated delayed fluorescent (TADF) material). Note that as a TADF material, a material in which a singlet excited state and a triplet excited state are in a thermal equilibrium state may be used. Since such a TADF material enables a short emission lifetime (excitation lifetime), an efficiency decrease of a light-emitting device in a high-luminance region can be inhibited. As the light-emitting substance contained in the EL element, not only an organic compound but also an inorganic compound (a quantum dot material or the like) can be used.

As each of the insulating layer 255a and the insulating layer 255b, a variety of inorganic insulating films such as an oxide insulating film, a nitride insulating film, an oxynitride insulating film, and a nitride oxide insulating film can be suitably used. As the insulating layer 255a, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. Specifically, it is preferable that a silicon oxide film be used as the insulating layer 255a and a silicon nitride film be used as the insulating layer 255b. With the use of a silicon nitride film as the insulating layer 255b, the progress of etching can be stopped at the insulating layer 255b even when the insulating layer 104 is penetrated in the formation of a depressed portion in the insulating layer 104. That is, the insulating layer 255b preferably has a function of an etching stopper. When the insulating layer 104 is penetrated, the insulating layer 104 has an opening; the opening can function as the above depressed portion together with the insulating layer 255b positioned at a bottom portion.

The stack 114a and the like are divided using the depressed portion of the insulating layer 104. Thus, leakage current between the adjacent light-emitting devices 102a, 102b, and 102c can be inhibited. Accordingly, a higher luminance, a higher contrast, higher display quality, higher power efficiency, lower power consumption, or the like can be achieved in the display device 700.

FIG. 11 is a cross-sectional view along the dashed-dotted line Y1-Y2 in FIG. 9. As illustrated in FIG. 11, the common electrode 113a2 is also provided in the connection region 140. The common electrode 113a2 provided in the connection region 140 is electrically connected to a conductive layer 123. Although a structure above the protective layer 131 is not illustrated in FIG. 11, at least one or more of the resin layer 147, the adhesive layer 107, and the substrate 222 can be provided as appropriate. Alternatively, as the conductive layer 123, a conductive layer formed using the same material in the same step as the lower electrode 111 is preferably used.

### Specific Example 2 of Display Device

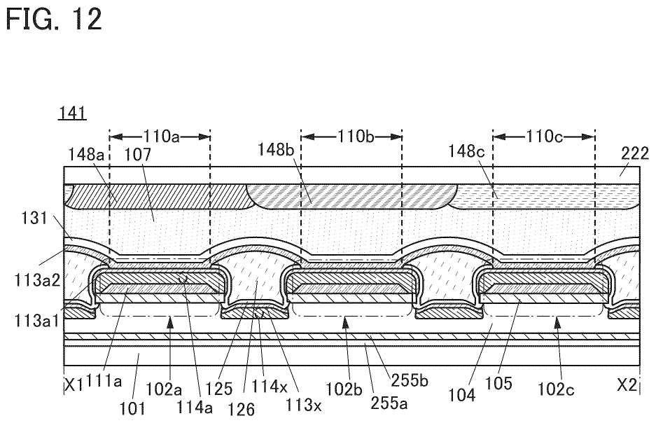

As another specific example, FIG. 12 illustrates a cross-sectional view of a pixel region 141 different from the pixel region in FIG. 10. FIG. 12 illustrating the pixel region 141 corresponds to a cross-sectional view along the dashed-dotted line X1-X2 in FIG. 9 and is different from FIG. 10 in that the color filters 148a, 148b, and 148c are provided on the substrate 222 side. Since the other structures are similar to those in FIG. 10, the descriptions thereof are omitted.

### Specific Example 3 of Display Device

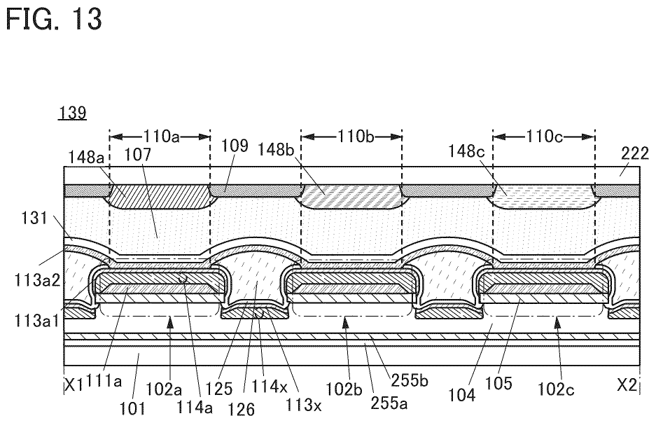

As another specific example, FIG. 13 illustrates a cross-sectional view of the pixel region 139 different from that in FIG. 10. FIG. 13 illustrating the pixel region 139 corresponds to a cross-sectional view along the dashed-dotted line X1-X2 in FIG. 9 and is different from FIG. 10 in that the color filters 148a, 148b, and 148c and a light-blocking layer 109 are provided on the substrate 222 side. The light-blocking layer 109 is a layer having a function of a light-blocking region and is preferably provided at a position overlapping with the insulating layer 126. Since the other structures are similar to those in FIG. 10, the descriptions thereof are omitted.

In any of the display devices of one embodiment of the present invention described in this embodiment, an insulating layer (also referred to as a bank or a partition in some cases) covering an upper end portion of the lower electrode 111 is not provided. Thus, the distance between adjacent light-emitting devices can be extremely shortened. Accordingly, the display device can have high resolution or high definition.

### Fabricating Method Example of Display Device

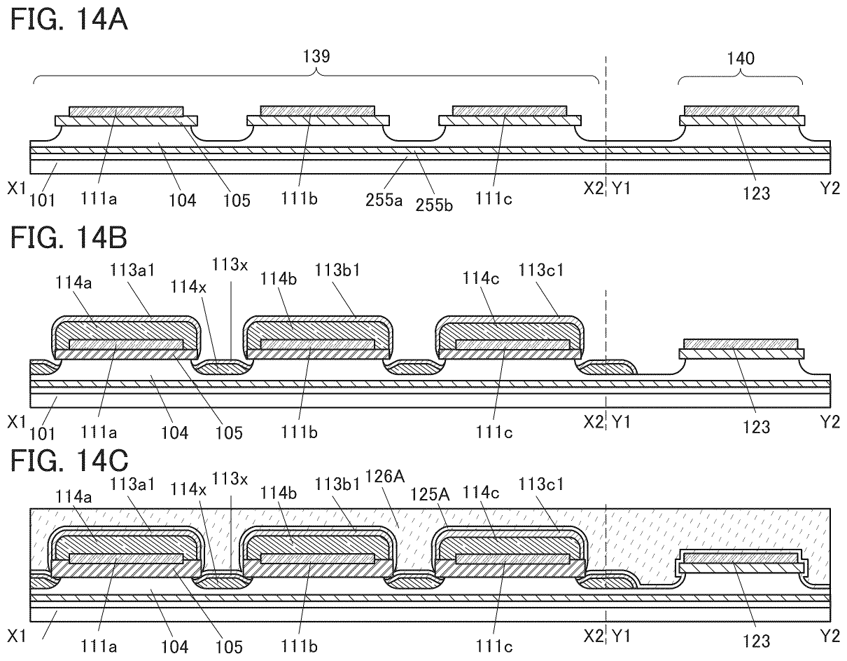

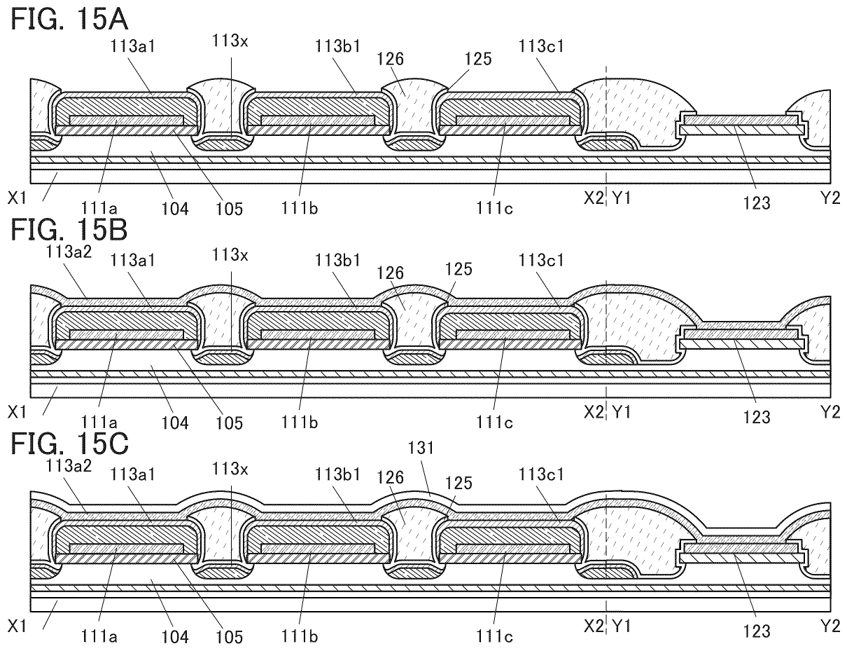

Next, an example of a method for fabricating a display device is described with reference to FIG. 14A to FIG. 15C. Note that FIG. 14A to FIG. 15C each illustrate a cross-sectional view along the dashed-dotted line X1-X2 and a cross-sectional view along the dashed-dotted line Y1-Y2 in FIG. 9 side by side.

Thin films included in the display device (e.g., insulating films, semiconductor films, and conductive films) can be formed by a sputtering method, a chemical vapor deposition (CVD) method, a vacuum evaporation method, a pulsed laser deposition (PLD) method, an ALD method, or the like. Examples of a CVD method include a plasma-enhanced chemical vapor deposition (PECVD: Plasma Enhanced CVD) method and a thermal CVD method. As an example of the thermal CVD method, a metal organic chemical vapor deposition (MOCVD: Metal Organic CVD) method can be given.

Alternatively, thin films included in the display device (e.g., insulating films, semiconductor films, and conductive films) can be formed by a method such as spin coating, dipping, spray coating, ink-jetting, dispensing, screen printing, offset printing, a doctor knife, slit coating, roll coating, curtain coating, or knife coating.

Specifically, for fabrication of the light-emitting device, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a light-emitting layer, an electron-transport layer, and an electron-injection layer) included in the EL layer can be formed by an evaporation method (e.g., a vacuum evaporation method), a coating method (e.g., a dip coating method, a die coating method, a bar coating method, a spin coating method, or a spray coating method), a printing method (e.g., an ink-jet method, a screen printing (stencil) method, an offset printing (planography) method, a flexography (relief printing) method, a gravure printing method, or a micro-contact printing method), or the like.

Thin films included in the display device can be processed by a photolithography method or the like. Alternatively, the thin films may be processed by a nanoimprinting method, a sandblasting method, a lift-off method, or the like. Alternatively, island-shaped thin films may be directly formed by a film formation method using a shielding mask such as a metal mask.

There are the following two typical examples of photolithography methods. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As light used for light exposure in a photolithography method, it is possible to use light with the i-line (wavelength: 365 nm), light with the g-line (wavelength: 436 nm), light with the h-line (wavelength: 405 nm), or combined light of any of them. Alternatively, ultraviolet rays, KrF laser light, ArF laser light, or the like can be used. Light exposure may be performed by liquid immersion light exposure technique. As the light used for the light exposure, extreme ultraviolet (EUV) light or X-rays may be used. Furthermore, instead of the light used for light exposure, an electron beam can be used. It is preferable to use extreme ultraviolet light, X-rays, or an electron beam because extremely minute processing can be performed. Note that in the case of performing light exposure by scanning of a beam such as an electron beam, a photomask is not necessarily used.

For etching of thin films, a dry etching method, a wet etching method, a sandblast method, or the like can be used.

First, as illustrated in FIG. 14A, the insulating layer 255a, the insulating layer 255b, the insulating layer 104, and the insulating layer 105 are formed in this order over the substrate 101. The insulating layer 255a, the insulating layer 255b, the insulating layer 104, and the insulating layer 105 can employ the above structures applicable to the insulating layer 255a, the insulating layer 255b, the insulating layer 104, and the insulating layer 105, respectively.

Although not illustrated in FIG. 14A, a contact hole is provided in the insulating layer 255a, the insulating layer 255b, the insulating layer 104, and the insulating layer 105. A transistor, specifically a source or a drain of the transistor, positioned below the insulating layer 255a can be electrically connected to the lower electrode 111 formed above the insulating layer 105 through the contact hole.

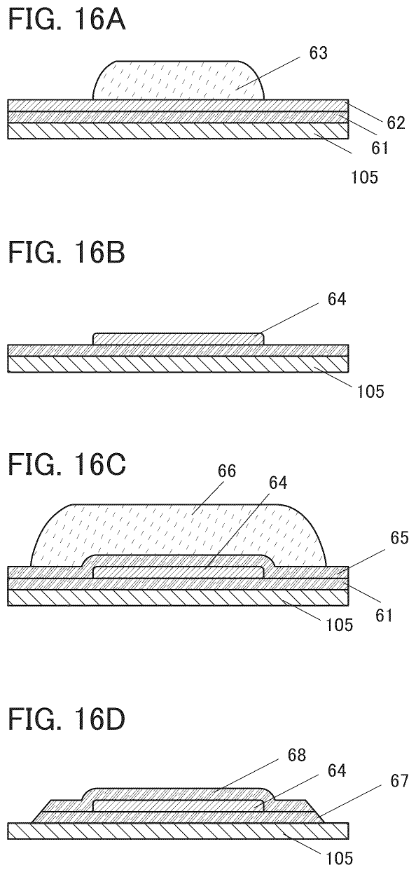

Next, the lower electrode 111 described above is formed over the insulating layer 105. Specifically, as illustrated in FIG. 14A, the lower electrodes 111a, 111b, and 111c and the conductive layer 123 are formed. The lower electrodes 111a, 111b, and 111c and the conductive layer 123 will be described in detail with reference to FIG. 16A to FIG. 16D.

As illustrated in FIG. 16A, a first conductive layer 61 is formed over the insulating layer 105. The first conductive layer 61 can be formed using a material selected from the materials described for the lower electrode. As the first conductive layer 61, for example, ITO, ITSO, or the like is preferably used.

A second conductive layer 62 is formed over the first conductive layer 61. The second conductive layer 62 can be formed using a material selected from the materials described for the lower electrode. As the second conductive layer 62, APC or the like is preferably used, for example. The second conductive layer 62 can give a reflective property to the lower electrode.

In order to process the second conductive layer 62, a resist mask 63 is formed. For the resist mask 63, a resist material containing a photosensitive resin, such as a positive type resist material or a negative type resist material, can be used. The second conductive layer 62 can be processed by a wet etching method or dry etching. In the case where APC is used as the second conductive layer 62, a wet etching method is preferably used.

After that, the resist mask 63 is removed, so that a conductive layer 64 processed as illustrated in FIG. 16B can be obtained.

Next, as illustrated in FIG. 16C, a third conductive layer 65 is formed over the conductive layer 64. The third conductive layer 65 can be formed using a material selected from the materials described for the lower electrode. As the third conductive layer 65, for example, ITO, ITSO, or the like is preferably used, and it is further preferable to use the same material as the first conductive layer 61. When the same material is used for the first conductive layer 61 and the third conductive layer 65, adhesion therebetween is improved; thus, a situation where the conductive layer 64 is exposed to an etchant can be inhibited. In other words, damage to the conductive layer 64 caused by the processing can be inhibited.

In order to process the first conductive layer 61 and the third conductive layer 65, a resist mask 66 is formed. For the resist mask 66, a resist material containing a photosensitive resin, such as a positive type resist material or a negative type resist material, can be used. The first conductive layer 61 and the third conductive layer 65 can be processed by a wet etching method or a dry etching method, and a wet etching method is preferably used. When the first conductive layer 61 and the third conductive layer 65 contain the same material, the first conductive layer 61 and the third conductive layer 65 can be processed without changing conditions of the wet etching method.

After that, the resist mask 66 is removed, so that a conductive layer 67 and conductive layer 68 processed as illustrated in FIG. 16D can be obtained. End portions of each of the conductive layer 67 and the conductive layer 68 preferably have a tapered shape, and it is further preferable that the tapered shape of the conductive layer 67 and the tapered shape of the conductive layer 68 be continuous.

The structure in which the conductive layer 67, the conductive layer 64, and the conductive layer 68 are stacked as illustrated in FIG. 16D is preferably used for the lower electrodes 111a, 111b, and 111c and the conductive layer 123. The conductive layer 64 can give a reflective property to the lower electrodes 111a, 111b, and 111c.

Next, as illustrated in FIG. 14A, an opening portion is formed in a region of the insulating layer 105 not overlapping with the lower electrodes 111a, 111b, and 111c and the conductive layer 123. A resist mask for processing the insulating layer 105 can be formed, and the opening portion can be formed by a dry etching method or a wet etching method.

As the dry etching method, a parallel plate RIE (Reactive Ion Etching) method or an ICP (Inductively Coupled Plasma) etching method can be used. As an etching gas for the dry etching method, for example, a C₄F₆ gas, a C₄F₈ gas, a CF₄ gas, a SF₆ gas, a CHF₃ gas, a Cl₂ gas, a BCl₃ gas, a SiCl₄ gas, or the like can be used alone or two or more of the gases can be mixed and used. Alternatively, an oxygen gas, a helium gas, an argon gas, a hydrogen gas, or the like can be added to any of the above gases as appropriate.

Then, a depressed portion is formed in the insulating layer 104 as illustrated in FIG. 14A. The depressed portion can be formed by a dry etching method or a wet etching method, and is preferably formed by ashing. With the use of ashing, formation of the depressed portion and ashing treatment before removal of the resist mask for forming the opening portion in the insulating layer 105 can be performed at the same time.

A substrate is provided in an apparatus used for ashing (ashing apparatus), and the power density of the bias voltage applied to the substrate side is greater than or equal to 1 W/cm² and less than or equal to 5 W/cm². In the case where oxygen is used as a gas introduced into the ashing apparatus, the substrate temperature is preferably higher than or equal to room temperature and lower than or equal to 300° C., further preferably higher than or equal to 100° C., and lower than or equal to 250° C.

As a result, the depressed portion is formed in the insulating layer 104. In addition, the insulating layer 105 including a protruding portion can be formed. Steps between top surfaces of the lower electrodes 111a, 111b, and 111c and bottom surfaces of the depressed portions of the insulating layer 104 are preferably large enough to divide an organic compound film formed later.

Here, hydrophobic treatment is preferably performed on the lower electrodes 111a, 111b, and 111c. The hydrophobic treatment can change the property of the surface of a processing target from hydrophilic to hydrophobic, or can improve the hydrophobic property of the surface of the processing target. By performing hydrophobization treatment on the lower electrodes, adhesion between the lower electrodes and an organic compound film formed later can be increased, so that film peeling can be inhibited. Note that the hydrophobic treatment is not necessarily performed.

The hydrophobic treatment can be performed by fluorine modification of the lower electrode, for example. The fluorine modification can be performed by, for example, treatment or heat treatment using a fluorine-containing gas, plasma treatment in an atmosphere of a fluorine-containing gas, or the like. As the fluorine-containing gas, a fluorine gas such as a fluorocarbon gas can be used, for example. As the fluorocarbon gas, a low carbon fluoride gas such as a carbon tetrafluoride (CF₄) gas, a C₄F₆ gas, a C₂F₆ gas, a C₄F₈ gas, or C₅F₈ can be used, for example. Alternatively, as the gas containing fluorine, an SF₆ gas, an NF₃ gas, a CHF₃ gas, or the like can be used, for example. Moreover, a helium gas, an argon gas, a hydrogen gas, or the like can be added to any of the above gases as appropriate.

Treatment using a silylating agent is performed on the surface of the lower electrode after plasma treatment is performed in a gas atmosphere containing a Group 18 element such as argon, so that the surface of the lower electrode can have a hydrophobic property. As the silylating agent, hexamethyldisilazane (HMDS), trimethylsilylimidazole (TMSI), or the like can be used. Alternatively, treatment using a silane coupling agent is performed on the surface of the lower electrode after plasma treatment is performed in a gas atmosphere containing a Group 18 element such as argon, so that the surface of the lower electrode can have a hydrophobic property.

Plasma treatment on the surface of the lower electrode in a gas atmosphere containing a Group 18 element such as argon can apply damage to the surface of the lower electrode. Accordingly, a methyl group included in the silylating agent such as HMDS is likely to bond to the surface of the lower electrode. In addition, silane coupling by the silane coupling agent is likely to occur. As described above, treatment using a silylating agent or a silane coupling agent performed on the surface of the lower electrode after plasma treatment in a gas atmosphere containing a Group 18 element such as argon enables the surface of the lower electrode to have a hydrophobic property.

The treatment using a silylating agent, a silane coupling agent, or the like can be performed by application of the silylating agent, the silane coupling agent, or the like by a spin coating method, a dipping method, or the like. Alternatively, the treatment using a silylating agent, a silane coupling agent, or the like can be performed by forming a film containing the silylating agent, a film containing the silane coupling agent, or the like over the lower electrode or the like by a gas phase method, for example. In a gas phase method, first, a material containing a silylating agent, a material containing a silane coupling agent, or the like is evaporated so that the silylating agent, the silane coupling agent, or the like is contained in an atmosphere. Next, a substrate where the lower electrode and the like are formed is put in the atmosphere. Accordingly, a film containing the silylating agent, the silane coupling agent, or the like can be formed over the lower electrode, so that the surface of the lower electrode can have a hydrophobic property.

Next, as illustrated in FIG. 14B, an organic compound film is formed over the lower electrodes 111a, 111b, and 111c. The steps between the top surfaces of the lower electrodes 111a, 111b, and 111c and the bottom surfaces of the depressed portions of the insulating layer 104 are sufficiently large; thus, the organic compound film is spontaneously divided into the stacks 114a, 114b, and 114c. In addition, the stack 114x is formed in the depressed portion of the insulating layer 104 by the division. Furthermore, when the insulating layer 105 includes the protruding portion, the organic compound film is surely divided. This division can also be referred to as self-aligned division.

The organic compound film can be formed by an evaporation method (including a vacuum evaporation method), a transfer method, a printing method, an inkjet method, a coating method, or the like and is preferably formed by an evaporation method. A premix material may be used for an evaporation source in the evaporation method. Note that a premix material is a composite material in which a plurality of materials are combined or mixed in advance.

As illustrated in FIG. 14B, the organic compound film is not formed over the conductive layer 123 in the connection region 140 in the cross section along Y1-Y2. For example, by using a mask for specifying a film formation area (also referred to as an area mask, a rough metal mask, or the like to be distinguished from a fine metal mask), the organic compound film can be formed in different regions. With the combination of the area mask as described above, a light-emitting device can be fabricated in a relatively simple process.

Next, as illustrated in FIG. 14B, a first upper electrode is formed over the stacks 114a. 114b, 114c, and 114x. The first upper electrode is formed at the same position as an organic compound layer, and the first upper electrodes 113a1, 113b1, and 113c1 and the upper electrode 113x are formed. The first upper electrode and the like can be formed by an evaporation method (including a vacuum evaporation method), a transfer method, a printing method, an inkjet method, a coating method, or the like and are preferably formed by the same method as the organic compound layer, i.e., an evaporation method.

The first upper electrodes 113al, 113b1, and 113c1 and the upper electrode 113x are preferably positioned to cover end surfaces of the stacks 114a. 114b, 114c, and 114x, respectively. The first upper electrodes 113al, 113b1, and 113c1 may each be positioned to cover the end surface of the insulating layer 105. The first upper electrodes 113al, 113b1, and 113c1 are divided from the upper electrode 113x. The steps between the top surfaces of the lower electrodes 111a, 111b, and 111c and the bottom surfaces of the depressed portions of the insulating layer 104 are sufficiently large; thus, the first upper electrodes 113al, 113b1, and 113c1 are surely divided from the upper electrodes 113x. Furthermore, when the insulating layer 105 includes the protruding portion, the first upper electrodes 113a1, 113b1, and 113c1 are surely divided from the upper electrodes 113x. This division can also be referred to as self-aligned division.

Next, as illustrated in FIG. 14C, an insulating film 125A is formed to cover the first upper electrodes 113a1, 113b1, and 113c1 and the like. The insulating film 125A is a layer to be the insulating layer 125 later. Thus, the insulating film 125A can be formed using a material that can be used for the insulating layer 125. As the insulating film 125A, an inorganic insulating film can be formed by an ALD method, an evaporation method, a sputtering method, a CVD method, or a PLD method, for example. The thickness of the insulating film 125A is preferably greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

As the insulating film 125A, an aluminum oxide film is preferably formed by an ALD method, for example. The use of an ALD method is preferable because damage due to film formation can be reduced and a film with good coverage can be formed.

As described later, an insulating layer 126A containing a photosensitive organic resin is formed in contact with a top surface of the insulating film 125A. Therefore, the top surface of the insulating film 125A preferably has a high affinity with respect to a photosensitive organic resin used for the insulating layer 126A (e.g., a photosensitive resin composition containing an acrylic resin). To improve the affinity, the top surface of the insulating film 125A is preferably made hydrophobic (or more hydrophobic) by surface treatment. For example, the treatment is preferably performed using a silylating agent such as hexamethyldisilazane (HMDS). By making the top surface of the insulating film 125A hydrophobic in this manner, the insulating layer 126A can be formed with high adhesion. Note that the above-described hydrophobic treatment may be performed as the surface treatment.

Next, as illustrated in FIG. 14C, the insulating layer 126A is applied onto the insulating film 125A.

The insulating layer 126A is a film to be the insulating layer 126 in a later step, and any of the above-described organic materials can be used for the insulating layer 126A. As the organic material, a photosensitive organic resin is preferably used: for example, a photosensitive resin composition containing an acrylic resin is used. The viscosity of the material of the insulating layer 126A is greater than or equal to 1 cP and less than or equal to 1500 cP, and is preferably greater than or equal to 1 cP and less than or equal to 12 cP. By setting the viscosity of the material of the insulating layer 126A in the above range, the insulating layer 126 having a tapered shape can be formed relatively easily.

The insulating layer 126A is preferably formed using a resin composition containing a polymer, an acid-generating agent, and a solvent, for example. The polymer is formed using one or more kinds of monomers and has a structure where one or more kinds of structural units (also referred to as building blocks) are repeated regularly or irregularly. As the acid-generating agent, one or both of a compound that generates an acid by light irradiation and a compound that generates an acid by heating can be used. The resin composition may also include one or more of a photosensitizing agent, a sensitizer, a catalyst, an adhesive aid, a surface-active agent, and an antioxidant.

There is no particular limitation on the method for forming the insulating layer 126A: for example, the insulating layer 126A can be formed by a wet film formation method such as spin coating, dipping, spray coating, ink-jetting, dispensing, screen printing, offset printing, a doctor knife method, slit coating, roll coating, curtain coating, or knife coating. In particular, the organic insulating film to be the insulating layer 126A is preferably formed by spin coating.

Heat treatment is preferably performed after the application of the insulating layer 126A. The heat treatment is performed at a temperature lower than the upper temperature limit of the EL layer. The heat treatment may be performed with a substrate temperature higher than or equal to 50° C., and lower than or equal to 200° C., preferably higher than or equal to 60° C., and lower than or equal to 150° C., further preferably higher than or equal to 70° C., and lower than or equal to 120° C. Accordingly, a solvent contained in the insulating layer 126A can be removed.

Next, light exposure is performed so that part of the insulating layer 126A is irradiated with visible light or ultraviolet rays, whereby the part of the insulating layer 126A is exposed to light. Furthermore, the region of the insulating layer 126A exposed to light is removed by development as illustrated in FIG. 15A, so that the insulating layer 126 is formed.

Here, when a barrier insulating layer against oxygen (e.g., an aluminum oxide film) is provided as the insulating film 125A, diffusion of oxygen into the EL layer can be reduced. In particular, when the EL layer is irradiated with light (visible light or ultraviolet rays), an organic compound contained in the EL layer is brought into an excited state and a reaction with oxygen contained in the atmosphere is promoted in some cases. Specifically, when the EL layer is irradiated with light (visible light rays or ultraviolet rays) in an atmosphere containing oxygen, oxygen might be bonded to the organic compound contained in the EL layer. When the insulating film 125A is provided over the EL layer, bonding of oxygen in the atmosphere to the organic compound contained in the EL layer can be reduced.

In the case where an acrylic resin is used for the insulating layer 126A, an alkaline solution is preferably used as a developer, and for example, a tetramethyl ammonium hydroxide (TMAH) aqueous solution is used. After the development, visible light or ultraviolet rays may be further irradiated. Performing such light exposure can improve the transparency of the insulating layer 126 in some cases.

In addition, heat treatment may be further performed after the development. The heat treatment enables the insulating layer 126 to have a tapered shape on the side surface as illustrated in FIG. 15A. By heat treatment, polymerization of the insulating layer 126 can be started and the insulating layer 126 can be cured. The heat treatment is performed at a temperature lower than the upper temperature limit of the EL layer. The substrate temperature at the time of the heat treatment is higher than or equal to 50° C., and lower than or equal to 200° C., preferably higher than or equal to 60° C., and lower than or equal to 150° C., further preferably higher than or equal to 70° C., and lower than or equal to 130° C. The substrate temperature in the heat treatment of this step is preferably higher than that in the heat treatment after the application of the insulating layer 126. Accordingly, adhesion between the insulating layer 126 and the insulating film 125A can be improved, and corrosion resistance of the insulating layer 126 can also be increased.

Heat treatment may be further performed after the insulating layer 126 is processed into a tapered shape. Etching may be performed so that the surface level of the insulating layer 126 is adjusted. The insulating layer 126 may be processed by ashing using oxygen plasma, for example.

Then, as illustrated in FIG. 15A, the insulating film 125A is removed at least partly to expose the first upper layers 113al, 113b1, and 113c1 and the conductive layer 123. As illustrated in FIG. 15A, a region of the insulating film 125A that overlaps with the insulating layer 126 remains as the insulating layer 125.

The insulating film 125A can be processed by a wet etching method or a dry etching method.

In processing of the insulating film 125A, damage to the EL layer can be less in the case of using a wet etching method than in the case of using a dry etching method. In the case of using a wet etching method, it is preferable to use a developer, a tetramethylammonium hydroxide (TMAH) aqueous solution, dilute hydrofluoric acid, oxalic acid, phosphoric acid, acetic acid, nitric acid, or a chemical solution containing a mixed solution of any of these acids, for example. In the case of employing a wet etching method, a mixed acid chemical solution containing water, phosphoric acid, diluted hydrofluoric acid, and nitric acid may be used. A chemical solution used for the wet etching treatment may be alkaline or acid.

In the case of using a dry etching method, deterioration of the EL layer can be inhibited by not using a gas containing oxygen as the etching gas. In the case of using a dry etching method, it is preferable to use a gas containing CF₄, C₄F₈, SF₆, CHF₃, Cl₂, H₂O, or BCl₃ or a noble gas (also referred to as a rare gas) such as He as the etching gas, for example.

For example, when an aluminum oxide film formed by an ALD method is used as the insulating film 125A, the insulating film 125A can be processed by a dry etching method using CHF₃ and He.

Next, the second upper electrode 113a2 is formed as illustrated in FIG. 15B. The second upper electrode 113a2 functions as a common electrode and is also formed over the conductive layer 123. In the connection region 140, the conductive layer 123 and the second upper electrode 113a2 are in direct contact with each other and thus electrically connected to each other.

Next, as illustrated in FIG. 15C, the protective layer 131 is formed over the second upper electrode 113a2. Then, although not illustrated, the resin layer 147 is formed over the protective layer 131, and the color filter 148 is formed over the resin layer 147. Furthermore, the substrate 222 is bonded onto the color filter 148 using the adhesive layer 107, whereby the display device can be fabricated.

This embodiment can be combined with the other embodiments as appropriate. In the case where a plurality of structure examples are described in one embodiment in this specification, the structure examples can be combined as appropriate.

### Embodiment 2

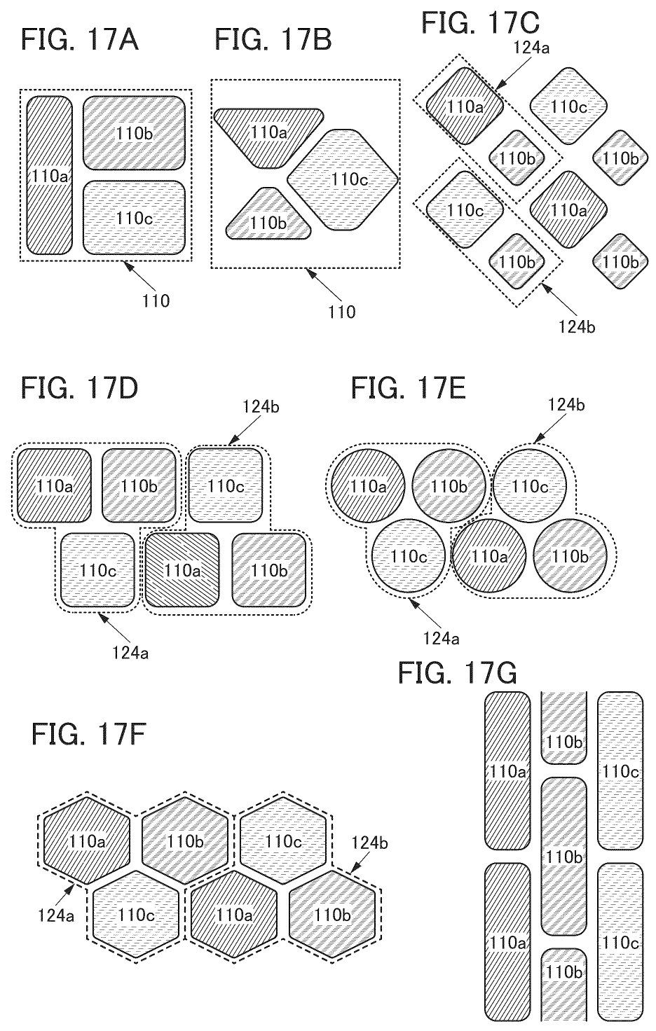

In this embodiment, the display device of one embodiment of the present invention is described with reference to FIG. 17 to FIG. 19.

### [Subpixel Layouts]

Subpixel layouts different from the layout in FIG. 9 will be mainly described in this embodiment. There is no particular limitation on the arrangement of subpixels, and a variety of methods can be employed. Examples of the arrangement of the subpixels include stripe arrangement, S-stripe arrangement, matrix arrangement, delta arrangement, Bayer arrangement, or PenTile arrangement.

Examples of a top surface shape of the subpixel include polygons such as a triangle, a tetragon (including a rectangle and a square), and a pentagon: polygons with rounded corners; an ellipse: or a circle. Here, the top surface shape of the subpixel corresponds to the top surface shape of a light-emitting region of a light-emitting device.

The range of the circuit layout for forming the subpixels is not limited to the range of the subpixels illustrated in a diagram and may be placed outside the range of the subpixels.

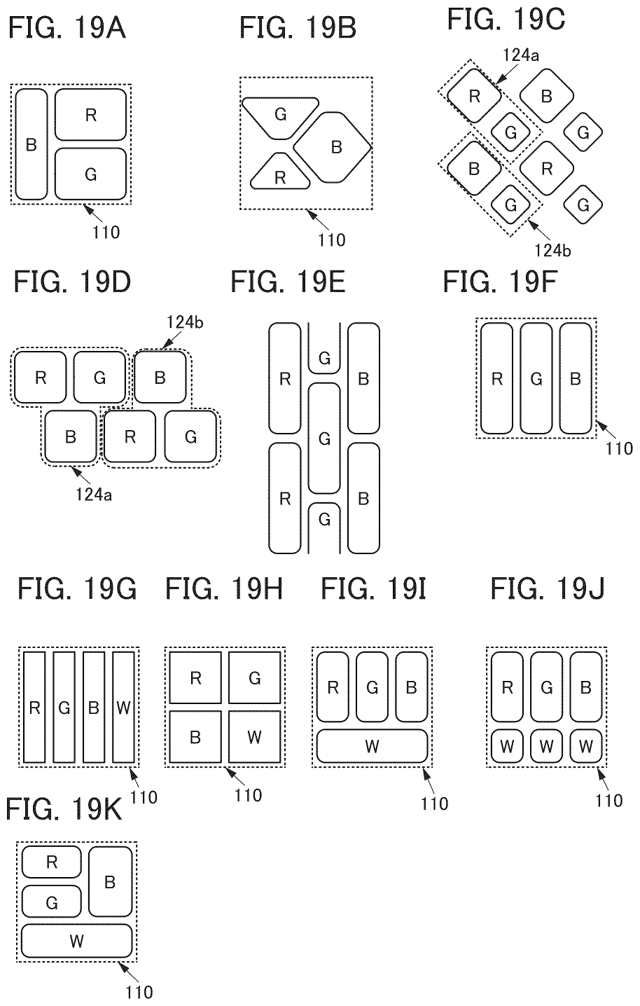

The pixel 110 illustrated in FIG. 17A employs S-stripe arrangement. The pixel 110 illustrated in FIG. 17A is composed of three subpixels; the subpixels 110a, 110b, and 110c. For example, as illustrated in FIG. 19A, the subpixel 110a may be a blue subpixel B, the subpixel 110b may be a red subpixel R, and the subpixel 110c may be a green subpixel G.

The pixel 110 illustrated in FIG. 17B includes the subpixel 110a whose top surface has a rough trapezoidal shape with rounded corners, the subpixel 110b whose top surface has a rough triangle shape with rounded corners, and the subpixel 110c whose top surface has a rough tetragonal or rough hexagonal shape with rounded corners. The subpixel 110a has a larger light-emitting area than the subpixel 110b. In this manner, the shapes and sizes of the subpixels can be determined independently. For example, the size of a subpixel including a light-emitting device with higher reliability can be smaller. For example, as illustrated in FIG. 19B, the subpixel 110a may be the green subpixel G, the subpixel 110b may be the red subpixel R, and the subpixel 110c may be the blue subpixel B.

Pixels 124a and 124b illustrated in FIG. 17C employ PenTile arrangement. FIG. 17C illustrates an example where the pixels 124a including the subpixel 110a and the subpixel 110b and the pixels 124b including the subpixel 110b and the subpixel 110c are alternately arranged. For example, as illustrated in FIG. 19C, the subpixel 110a may be the red subpixel R, the subpixel 110b may be the green subpixel G, and the subpixel 110c may be the blue subpixel B.

The pixels 124a and 124b illustrated in FIG. 17D to FIG. 17F employ delta arrangement. The pixel 124a includes two subpixels (the subpixels 110a and 110b) in the upper row (first row) and one subpixel (the subpixel 110c) in the lower row (second row). The pixel 124b includes one subpixel (the subpixel 110c) in the upper row (first row) and two subpixels (the subpixels 110a and 110b) in the lower row (second row). For example, as illustrated in FIG. 19D, the subpixel 110a may be the red subpixel R, the subpixel 110b may be the green subpixel G, and the subpixel 110c may be the blue subpixel B.

FIG. 17D is an example where the top surface of each subpixel has a rough tetragonal shape with rounded corners, FIG. 17E is an example where the top surface of each subpixel is circular, and FIG. 17F is an example where the top surface of each subpixel has a rough hexagonal shape with rounded corners.

In FIG. 17F, subpixels are placed inside respective hexagonal regions that are arranged densely. Focusing on one of the subpixels, the subpixel is placed so as to be surrounded by six subpixels. The subpixels are arranged such that subpixels exhibiting light of the same color are not adjacent to each other. For example, focusing on the subpixel 110a, the subpixel 110a is surrounded by three subpixels 110b and three subpixels 110c that are alternately arranged.

FIG. 17G illustrates an example where subpixels of different colors are arranged in a zigzag manner. Specifically, the positions of the top sides of two subpixels arranged in the column direction (e.g., the subpixel 110a and the subpixel 110b or the subpixel 110b and the subpixel 110c) are not aligned in the plan view. For example, as illustrated in FIG. 19E, the subpixel 110a may be the red subpixel R, the subpixel 110b may be the green subpixel G, and the subpixel 110c may be the blue subpixel B.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface shape of the pixel electrode may be a polygon with rounded corners, an ellipse, a circle, or the like. In the display device of one embodiment of the present invention, the top surface shape of the EL layer and the top surface shape of the light-emitting device may each be a polygon with rounded corners, an ellipse, a circle, or the like due to the influence of the top surface shape of the pixel electrode.

Note that to obtain a desired top surface shape of the pixel electrode, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

Also in the pixel 110 illustrated in FIG. 17, which employs stripe arrangement, for example, the subpixel 110a can be the red subpixel R, the subpixel 110b can be the green subpixel G, and the subpixel 110c can be the blue subpixel B as illustrated in FIG. 19F.

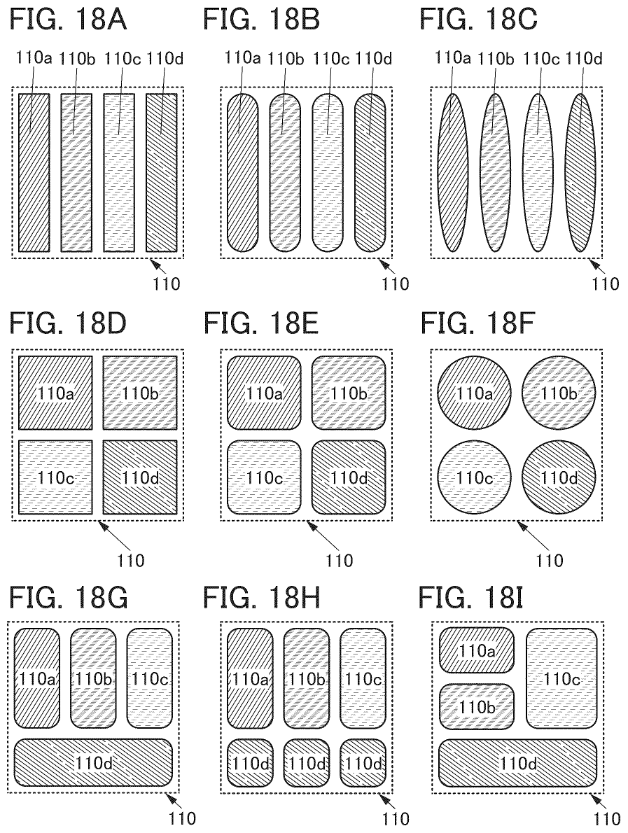

As illustrated in FIG. 18A to FIG. 18I, the pixel can include four types of subpixels.

The pixels 110 illustrated in FIG. 18A to FIG. 18C employ stripe arrangement.

FIG. 18A illustrates an example where each subpixel has a rectangular top surface shape, FIG. 18B illustrates an example where each subpixel has a top surface shape formed by combining two half circles and a rectangle, and FIG. 18C illustrates an example where each subpixel has an elliptical top surface shape.

The pixels 110 illustrated in FIG. 18D to FIG. 18F employ matrix arrangement.

FIG. 18D illustrates an example where each subpixel has a square top surface shape, FIG. 18E illustrates an example where each subpixel has a rough square top surface shape with rounded corners, and FIG. 18F illustrates an example where each subpixel has a circular top surface shape.

FIG. 18G and FIG. 18H each illustrate an example where one pixel 110 is composed of two rows and three columns.

The pixel 110 illustrated in FIG. 18G includes three subpixels (the subpixels 110a, 110b, and 110c) in the upper row (first row) and one subpixel (a subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 illustrated in FIG. 18H includes three subpixels (the subpixels 110a, 110b, and 110c) in the upper row (first row) and three subpixels 110d in the lower row (second row). In other words, the pixel 110 includes the subpixel 110a and the subpixel 110d in the left column (first column), the subpixel 110b and the subpixel 110d in the center column (second column), and the subpixel 110c and the subpixel 110d in the right column (third column). Matching the positions of the subpixels in the upper row and the lower row as illustrated in FIG. 18H enables efficient removal of dust and the like that would be produced in the manufacturing process. Thus, a display device with high display quality can be provided.

FIG. 18I illustrates an example where one pixel 110 is composed of three rows and two columns.

The pixel 110 illustrated in FIG. 18I includes the subpixel 110a in the upper row (first row), the subpixel 110b in the center row (second row), the subpixel 110c across the first and second rows, and one subpixel (the subpixel 110d) in the lower row (third row). In other words, the pixel 110 includes the subpixels 110a and 110b in the left column (first column), the subpixel 110c in the right column (second column), and the subpixel 110d across these two columns.

The pixels 110 illustrated in FIG. 18A to FIG. 18I are each composed of four subpixels: the subpixels 110a, 110b, 110c, and 110d. The subpixels 110a, 110b, 110c, and 110d are subpixels that emit light of different colors. As the subpixels 110a, 110b, 110c, and 110d, subpixels of four colors of R, G, B, and white (W), subpixels of four colors of R, G, B, and Y, subpixels of R, G, B, and infrared light (IR), and the like can be given.

For example, as illustrated in FIG. 19G to FIG. 19K, the subpixel 110a can be the subpixel R emitting red light, the subpixel 110b can be the subpixel G emitting green light, the subpixel 110c can be the subpixel B emitting blue light, and the subpixel 110d can be a subpixel W emitting white light. In this case, the subpixels 110a, 110b, and 110c are provided with the light-emitting device 102 and the color filter 148. Meanwhile, in the subpixel 110d, although the light-emitting device 102 is provided in a similar manner, the color filter 148 is not provided. Thus, white light of the light-emitting device 102 is directly emitted from the subpixel 110d. Alternatively, the subpixel 110d can be a subpixel Y emitting yellow light or a subpixel IR emitting near-infrared light. In the above-described structure, stripe arrangement is employed as the layout of R, G, and B in the pixels 110 illustrated in FIG. 191 and FIG. 19J, leading to higher display quality. In addition, what is called S-stripe arrangement is employed as the layout of R, G, and B in the pixel 110 illustrated in FIG. 19K, leading to higher display quality. Note that the number of types of subpixels is not limited to four, and five or more types of subpixels may be used.

As described above, the pixel composed of the subpixels each including the light-emitting device can employ any of a variety of layouts in the display device of one embodiment of the present invention.

This embodiment can be combined with the other embodiments as appropriate. In the case where a plurality of structure examples are described in one embodiment in this specification, the structure examples can be combined as appropriate.

### Embodiment 3

In this embodiment, a light-emitting device that can be used for the display device of one embodiment of the present invention will be described.

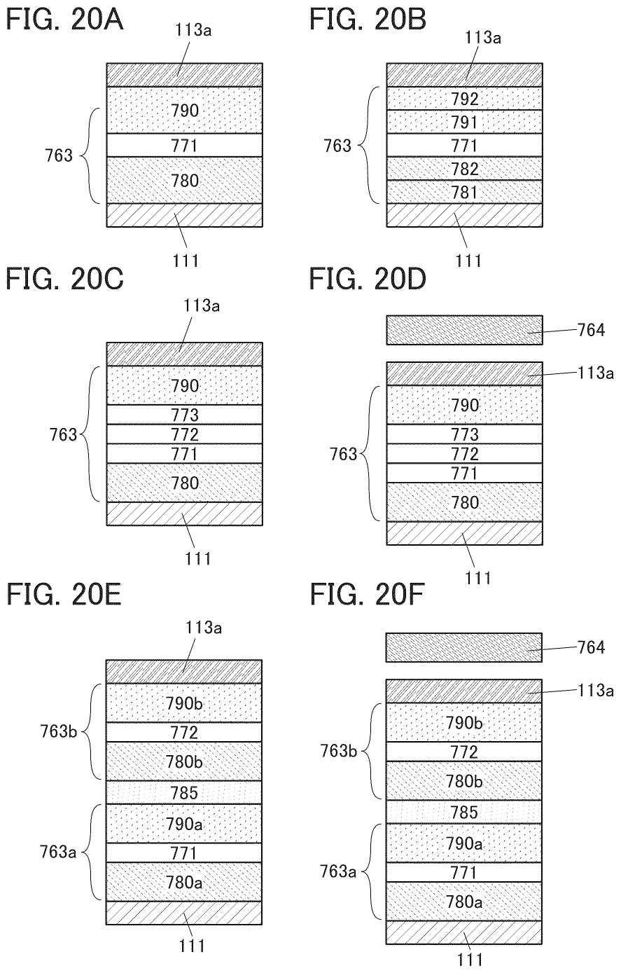

As illustrated in FIG. 20A, the light-emitting device includes a stack 763 between a pair of electrodes (the lower electrode 111 and the upper electrode 113a). The stack 763 can be formed of a plurality of layers such as a layer 780, a light-emitting layer 771, and a layer 790.

The light-emitting layer 771 contains at least a light-emitting material.

In the case where the lower electrode 111 is an anode and the upper electrode 113a is a cathode, the layer 780 includes one or more of a hole-injection layer, a hole-transport layer, and an electron-blocking layer. In the case where the layer 780 includes two or more of the layers, the hole-injection layer, the hole-transport layer, and the electron-blocking layer are preferably provided in this order from the upper electrode 113a side. The layer 790 includes one or more of an electron-injection layer, an electron-transport layer, and a hole-blocking layer. In the case where the layer 790 includes two or more of the layers, the electron-injection layer, the electron-transport layer, and the hole-blocking layer are preferably provided in this order from the lower electrode 111 side. In the case where the lower electrode 111 is a cathode and the upper electrode 113a is an anode, the layer 780 has the structure described for the layer 790 and the layer 790 has the structure described for the layer 780.

The structure including the layer 780, the light-emitting layer 771, and the layer 790 that are provided between a pair of electrodes can function as one light-emitting unit.

FIG. 20B is a specific example of the stack 763 illustrated in FIG. 20A. FIG. 20B illustrates a light-emitting device including a layer 781 over the lower electrode 111, a layer 782 over the layer 781, the light-emitting layer 771 over the layer 782, a layer 791 over the light-emitting layer 771, a layer 792 over the layer 791, and the upper electrode 113a over the layer 792.

In the case where the lower electrode 111 is an anode and the upper electrode 113a is a cathode, the layer 781 can be a hole-injection layer, the layer 782 can be a hole-transport layer, the layer 791 can be an electron-transport layer, and the layer 792 can be an electron-injection layer, for example. In the case where the lower electrode 111 is a cathode and the upper electrode 113a is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected to the light-emitting layer 771, and the efficiency of the recombination of carriers in the light-emitting layer 771 can be increased.

As illustrated in FIG. 20C, in the light-emitting device, a plurality of light-emitting layers (the light-emitting layers 771, 772, and 773) may be provided between the layer 780 and the layer 790. Although FIG. 20C illustrates an example where the three light-emitting layers are included, two or four or more light-emitting layers may be included.

As illustrated in FIG. 20D, a color filter or a color conversion layer may be provided as a layer 764 at a position overlapping with the light-emitting device. As the layer 764, both a color conversion layer and a color filter are preferably used. Part of light emitted from the light-emitting layer is transmitted without being converted by the color conversion layer in some cases; thus, the light is extracted through the color filter to increase the color purity of the light emitted from the subpixel.

Note that the above structure with the layer 764 may be applied to the light-emitting device illustrated in FIG. 20A and FIG. 20B.

As illustrated in FIG. 20E, the light-emitting device may have a structure in which a plurality of light-emitting units (a light-emitting unit 763a and a light-emitting unit 763b) are stacked with a charge-generation layer 785 therebetween. This structure is a tandem structure and may be referred to as a stack structure. The tandem structure enables the light-emitting device to perform high luminance light emission, and can offer higher reliability than a single structure.

As illustrated in FIG. 20F, a color filter or a color conversion layer may be provided as the layer 764 at a position overlapping with the light-emitting device. As the layer 764, both a color conversion layer and a color filter are preferably used. Part of light emitted from the light-emitting layer is transmitted without being converted by the color conversion layer in some cases; thus, the light is extracted through the color filter to increase the color purity of the light emitted from the subpixel.

In FIG. 20D and FIG. 20F, light is extracted from the layer 764 side; thus, a transparent electrode is preferably used as the upper electrode 113a.

In FIG. 20C and FIG. 20D, the light-emitting layer 771, the light-emitting layer 772, and the light-emitting layer 773 may contain light-emitting materials that emit light of the same color. As the light-emitting materials that emit light of the same color, the same light-emitting material may be used. For example, the same light-emitting material that emits blue light can be used. In a subpixel that emits blue light, blue light emitted from the light-emitting device can be extracted not through the layer 764. That is, the layer 764 can be omitted in the subpixel that emits blue light. In a subpixel that emits red light and a subpixel that emits green light, by providing a color conversion layer as the layer 764 illustrated in FIG. 20D, blue light emitted from the light-emitting device can be converted into light with a longer wavelength and red light or green light can be extracted. In the case where the color conversion layer is provided, the addition of the color filter described above can increase the color purity of light emitted from the subpixel can be increased.

A light-emitting material that emits blue light can be used for the light-emitting layer 771 of the light-emitting device illustrated in FIG. 20A and FIG. 20B: also in that case, in a subpixel that emits blue light, blue light emitted from the light-emitting device can be extracted not through a color conversion layer or the like, and in a subpixel that emits red light and a subpixel that emits green light, red light or green light can be extracted by providing a color conversion layer. In the case where the color conversion layer is provided, the addition of the color filter described above can increase the color purity of light emitted from the subpixel can be increased.

In FIG. 20C and FIG. 20D, light-emitting materials that emit light of different colors may be used for the light-emitting layer 771, the light-emitting layer 772, and the light-emitting layer 773. White light emission can be obtained when the light-emitting layer 771, the light-emitting layer 772, and the light-emitting layer 773 emit light of complementary colors. To emit light of complementary colors, a light-emitting layer containing a light-emitting material that emits blue light and a light-emitting layer containing a light-emitting material that emits visible light having a longer wavelength than blue light are included, for example. Since three light-emitting layers are included, two light-emitting layers each containing a light-emitting material that emits blue light are preferably included, for example.

The light-emitting layer 771, the light-emitting layer 772, and the light-emitting layer 773 may be a light-emitting layer containing a light-emitting material that emits red (R) light, a light-emitting layer containing a light-emitting material that emits green (G) light, and a light-emitting layer containing a light-emitting material that emits blue (B) light. In this case, the stacking order of the light-emitting layers can be R, G, and B from the lower electrode 111 side or R. B, and G from the upper electrode 113a side.

In the case where the light-emitting layer 773 is omitted and the two light-emitting layers are included in FIG. 20C and FIG. 20D, a structure is preferable in which a light-emitting layer containing a light-emitting material that emits blue (B) light and a light-emitting layer containing a light-emitting material that emits yellow (Y) light are included. Since the light-emitting layers emit light of the complementary colors, white light emission can be obtained.

Also in FIG. 20C and FIG. 20D, the layer 780 and the layer 790 may each independently have a stacked-layer structure of two or more layers as illustrated in FIG. 20B.

In FIG. 20E and FIG. 20F, light-emitting materials that emit light of the same color, or moreover, the same light-emitting material may be used for the light-emitting layer 771 and the light-emitting layer 772. For example, in light-emitting devices included in subpixels emitting light of different colors, a light-emitting material that emits blue light may be used for each of the light-emitting layer 771 and the light-emitting layer 772. In a subpixel that emits blue light, blue light emitted from the light-emitting device can be extracted. In a subpixel that emits red light and a subpixel that emits green light, by providing a color conversion layer as the layer 764 illustrated in FIG. 20F, blue light emitted from the light-emitting device can be converted into light with a longer wavelength and red light or green light can be extracted. As the layer 764, both a color conversion layer and a color filter are preferably used.

Alternatively, in FIG. 20E and FIG. 20F, light-emitting materials that emit light of different colors may be used for the light-emitting layer 771 and the light-emitting layer 772. White light emission can be obtained when the light-emitting layer 771 and the light-emitting layer 772 emit light of complementary colors. A color filter may be provided as the layer 764 illustrated in FIG. 20F. When white light passes through the color filter, light of a desired color can be obtained.

Although FIG. 20E and FIG. 20F illustrate examples where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

In addition, although FIG. 20E and FIG. 20F each illustrate the light-emitting device including two light-emitting units as an example, one embodiment of the present invention is not limited thereto. The light-emitting device may include three or more light-emitting units. Note that a structure including two light-emitting units and a structure including three light-emitting units may be referred to as a two-unit tandem structure and a three-unit tandem structure, respectively.

In FIG. 20E and FIG. 20F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 111 is an anode and the upper electrode 113a is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 111 is a cathode and the upper electrode 113a is an anode, the structures of the layer 780a and the layer 790a are replaced with each other, and the structures of the layer 780b and the layer 790b are also replaced with each other.

In the case where the lower electrode 111 is an anode and the upper electrode 113a is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 111 is a cathode and the upper electrode 113a is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In FIG. 20E and FIG. 20F, the two light-emitting units are stacked with the charge-generation layer 785 therebetween. The charge-generation layer 785 includes at least a charge-generation region.

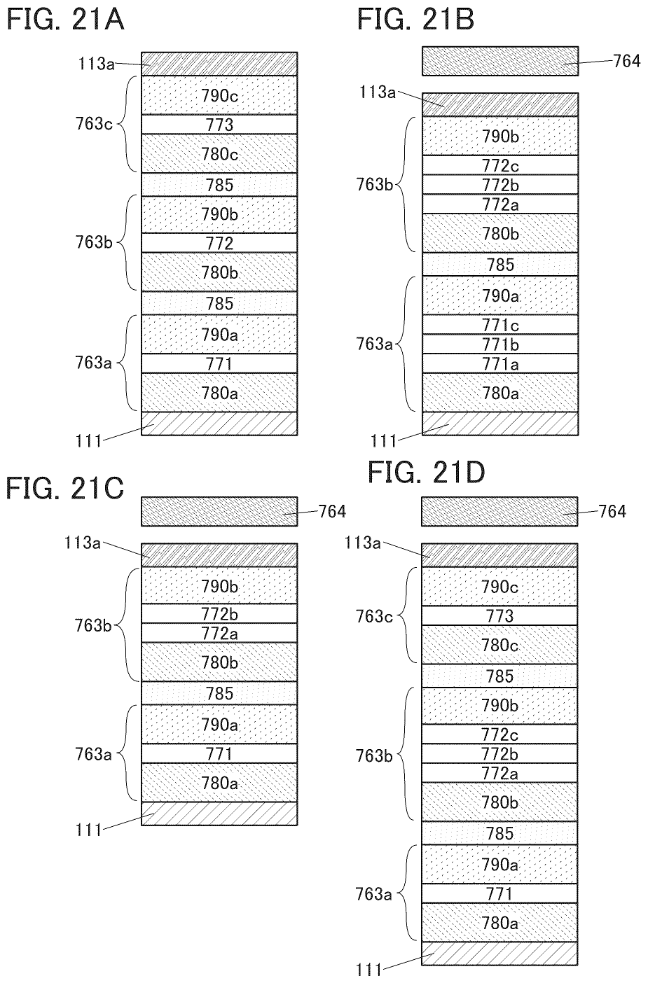

The structures illustrated in FIG. 21A to FIG. 21D can be given as examples of the light-emitting device having a tandem structure.

FIG. 21A illustrates a structure including three light-emitting units. In FIG. 21A, a plurality of light-emitting units (the light-emitting unit 763a, the light-emitting unit 763b, and a light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 21A, the light-emitting layer 771, the light-emitting layer 772, and the light-emitting layer 773 preferably contain light-emitting materials that emit light of the same color. Specifically, the light-emitting layer 771, the light-emitting layer 772, and the light-emitting layer 773 can each have a structure containing a blue (B) light-emitting material (i.e., a three-unit tandem structure of B\B\B). Alternatively, the layer 764 may be provided as in the light-emitting device illustrated in FIG. 20D and FIG. 20F. As the layer 764, a color conversion layer, a color filter, or a combination of a color conversion layer and a color filter is used.

In FIG. 21A, light-emitting materials that emit light of different colors may be used for some or all of the light-emitting layer 771, the light-emitting layer 772, and the light-emitting layer 773. Examples of a combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other. Alternatively, the layer 764 may be provided as in the light-emitting device illustrated in FIG. 20D and FIG. 20F. As the layer 764, a color filter is used.

Note that the structure containing the light-emitting materials that emit light of the same color is not limited to the above structure. For example, a light-emitting device with a tandem structure may be employed in which light-emitting units each including a plurality of light-emitting layers are stacked as illustrated in FIG. 21B. FIG. 21B illustrates a structure in which two light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 21B, the light-emitting unit 763a is configured to emit white (W) light by selecting light-emitting materials for the light-emitting layer 771a, the light-emitting layer 771b, and the light-emitting layer 771c so that their emission colors are complementary colors. Furthermore, the light-emitting unit 763b is configured to emit white (W) light by selecting light-emitting materials for the light-emitting layer 772a, the light-emitting layer 772b, and the light-emitting layer 772c so that their emission colors are complementary colors. That is, the structure illustrated in FIG. 21B is a two-unit tandem structure of W\W. Note that there is no particular limitation on the stacking order of the light-emitting materials that emit light of complementary colors. The practitioner can select the optimal stacking order as appropriate. Although not illustrated, a three-unit tandem structure of W\W\W or a tandem structure with four or more units may be employed.

In the case where the light-emitting device with a tandem structure is used, the following structure can be given: a B\Y or Y\B two-unit tandem structure including a light-emitting unit that emits yellow (Y) light and a light-emitting unit that emits blue (B) light: an R·G\B or B\R·G two-unit tandem structure including a light-emitting unit that emits red (R) light and green (G) light and a light-emitting unit that emits blue (B) light: a B\Y\B three-unit tandem structure including a light-emitting unit that emits blue (B) light, a light-emitting unit that emits yellow (Y) light, and a light-emitting unit that emits blue (B) light in this order: a B\YG\B three-unit tandem structure including a light-emitting unit that emits blue (B) light, a light-emitting unit that emits yellow green (YG) light, and a light-emitting unit that emits blue (B) light in this order; and a B\G\B three-unit tandem structure including a light-emitting unit that emits blue (B) light, a light-emitting unit that emits green (G) light, and a light-emitting unit that emits blue (B) light in this order, for example. Note that “a·b” means that one light-emitting unit contains a light-emitting material that emits light of a and a light-emitting material that emits light of b.

As illustrated in FIG. 21C, a light-emitting unit including one light-emitting layer and a light-emitting unit including a plurality of light-emitting layers may be used in combination.

Specifically, in the structure illustrated in FIG. 21C, two light-emitting units (the light-emitting unit 763a and the light-emitting unit 763b) are connected in series through the charge-generation layers 785. Unlike in FIG. 21B, the light-emitting unit 763a includes the layer 780a, the light-emitting layer 771, and the layer 790a, and the light-emitting unit 763b includes the layer 780b, the light-emitting layer 772a, the light-emitting layer 772b, and the layer 790b in FIG. 21C.

In FIG. 21C, white (W) light emission is obtained by selecting light-emitting materials for the light-emitting layer 771, the light-emitting layer 771b, and the light-emitting layer 771c so that their emission colors are complementary colors. Specifically, in FIG. 21C, a two-unit tandem structure of B\R·G or B\G·R, which includes the light-emitting unit 763a that emits blue (B) light and the light-emitting unit 763b that emits red (R) and green (G) light, can be employed. The green (G) light-emitting layer may be in contact with the red (R) light-emitting layer, and the red (R) light-emitting layer is preferably positioned closer to the upper electrode 113a than the green (G) light-emitting layer is.

As illustrated in FIG. 21D, a light-emitting unit including one light-emitting layer and a light-emitting unit including a plurality of light-emitting layers may be used in combination.

Specifically, in the structure illustrated in FIG. 21D, a plurality of light-emitting units (the light-emitting unit 763a, the light-emitting unit 763b, and the light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 21D, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow green (YG) light, and the light-emitting unit 763c is a light-emitting unit that emits blue (B) light can be employed.

Examples of the number of stacked light-emitting units and the order of colors from the anode side include a two-unit structure of B and Y, a two-unit structure of B and a light-emitting unit X, a three-unit structure of B, Y, and B, and a three-unit structure of B, X, and B. Examples of the number of light-emitting layers stacked in the light-emitting unit X and the order of colors from the anode side include a two-layer structure of R and Y, a two-layer structure of R and G, a two-layer structure of G and R, a three-layer structure of G, R, and G, and a three-layer structure of R. G, and R. Another layer may be provided between two light-emitting layers.

Next, materials that can be used for the light-emitting device will be described.

Either a low molecular compound or a high molecular compound can be used in the light-emitting device, and an inorganic compound may be included. Each layer included in the light-emitting device can be formed by any of the following methods: an evaporation method (including a vacuum evaporation method), a transfer method, a printing method, an ink-jet method, a coating method, and the like.

The light-emitting layer contains one or more kinds of light-emitting materials. As the light-emitting material, a material whose emission color is blue, violet, bluish violet, green, yellowish green, yellow, orange, red, or the like is appropriately used. Alternatively, as the light-emitting material, a material that emits near-infrared light can be used.

Examples of the light-emitting material include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton: an organometallic complex (particularly an iridium complex) having a phenylpyridine derivative including an electron-withdrawing group as a ligand: a platinum complex; and a rare earth metal complex.

The light-emitting layer may contain one or more kinds of organic compounds (e.g., a host material and an assist material) in addition to the light-emitting material (a guest material). As one or more kinds of organic compounds, one or both of a substance with a high hole-transport property (a hole-transport material) and a substance with a high electron-transport property (an electron-transport material) can be used. As the hole-transport material, it is possible to use a material having a high hole-transport property which can be used for the hole-transport layer and will be described later. As the electron-transport material, it is possible to use a material having a high electron-transport property which can be used for the electron-transport layer and will be described later. Alternatively, as one or more kinds of organic compounds, a bipolar material or a TADF material may be used.

The light-emitting layer preferably contains a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting material (phosphorescent material). When a combination of materials is selected so as to form an exciplex that exhibits light emission whose wavelength overlaps with the wavelength on a lowest-energy-side absorption band of the light-emitting material, energy can be transferred smoothly and light emission can be obtained efficiently. With the above structure, high efficiency, low-voltage driving, and a long lifetime of a light-emitting device can be achieved at the same time.

The hole-injection layer is a layer injecting holes from the anode to the hole-transport layer, and is a layer containing a material with a high hole-injection property. Examples of the material with a high hole-injection property include an aromatic amine compound. Other examples of the material with a high hole-injection property include an acceptor material (an electron-accepting material) and a composite material containing an acceptor material and a hole-transport material. The composite material is obtained by, for example, co-evaporation of an acceptor material and a hole-transport material.

As the acceptor material, an oxide of a metal belonging to Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable since it is stable in the air, has a low hygroscopic property, and is easy to handle. An organic acceptor material containing fluorine can be used. An organic acceptor material such as a quinodimethane derivative, a chloranil derivative, or a hexaazatriphenylene derivative can be used.

As the hole-transport material, it is possible to use a material having a high hole-transport property which can be used for the hole-transport layer and will be described later.

As the material having a high hole-injection property, a material that contains a hole-transport material and the above-described oxide of a metal belonging to any of Group 4 to Group 8 of the periodic table (typically, molybdenum oxide) may be used, for example.

The hole-transport layer is a layer transporting holes injected from the anode by the hole-injection layer, to the light-emitting layer. The hole-transport layer is a layer containing a hole-transport material. As the hole-transport material, a substance having a hole mobility higher than or equal to 1×10⁻⁶ cm²/Vs is preferable. Note that other substances can also be used as long as the substances have a hole-transport property higher than an electron-transport property.

The hole-transport material further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of amine through an arylene group is preferably used. Note that the material having a hole-transport property preferably has an N,N-bis(4-biphenyl)amino group because a light-emitting device having a long lifetime can be fabricated.

The electron-blocking layer has a hole-transport property and contains a material capable of blocking electrons. Any of the materials having an electron-blocking property among the above hole-transport materials can be used for the electron-blocking layer. Such an electron-blocking layer may be referred to as a hole-transport layer.

The electron-transport layer is a layer transporting electrons injected from the cathode by the electron-injection layer, to the light-emitting layer. The electron-transport layer is a layer containing an electron-transport material. As the electron-transport material, a substance having an electron mobility higher than or equal to 1×10⁻⁶ cm²/Vs is preferable. Note that other substances can also be used as long as the substances have an electron-transport property higher than a hole-transport property.

As the electron-transport material, it is possible to use a metal complex having a quinoline skeleton, a metal complex having a benzoquinoline skeleton, a metal complex having an oxazole skeleton, and a metal complex having a thiazole skeleton. Other examples of the electron-transport material include an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, and a pyrimidine derivative. As the other electron-transport material, a material having a high electron-transport property, such as a π-electron deficient heteroaromatic compound including the other nitrogen-containing heteroaromatic compound, can be used.

The hole-blocking layer is a layer having an electron-transport property and containing a material that can block holes. Any of the materials having a hole-blocking property among the above electron-transport materials can be used for the hole-blocking layer. Such a hole-blocking layer may be referred to as an electron-transport layer.

The electron-injection layer is a layer injecting electrons from the cathode to the electron-transport layer, and is a layer containing a material with a high electron-injection property. Examples of the material with a high electron-injection property include an alkali metal, an alkaline earth metal, a compound of an alkali metal, and a compound of an alkaline earth metal. As the material with a high electron-injection property, a composite material containing an electron-transport material and a donor material (electron-donating material) can also be used.

The difference between the LUMO level of the material with a high electron-injection property and the work function value of the material used for the cathode is preferably small (specifically, smaller than or equal to 0.5 eV).

The electron-injection layer can be formed using, for example, an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato) lithium (abbreviation: Liq), 2-(2-pyridyl) phenolatolithium (abbreviation: LiPP), 2-(2-pyridyl)-3-pyridinolatolithium (abbreviation: LiPPy), 4-phenyl-2-(2-pyridyl) phenolatolithium (abbreviation: LiPPP), lithium oxide (LiOₓ), or cesium carbonate. The electron-injection layer may have a stacked-layer structure of two or more layers. The stacked-layer structure can be, for example, a structure in which lithium fluoride is used for the first layer and ytterbium is used for the second layer.

The electron-injection layer may contain an electron-transport material. For example, a compound having an unshared electron pair and an electron deficient heteroaromatic ring can be used as the electron-transport material. Specifically, a compound having one or more selected from a pyridine ring, a diazine ring (a pyrimidine ring, a pyrazine ring, or a pyridazine ring), and a triazine ring can be used.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2-(1,3-phenylene)bis [9-phenyl-1,10-phenanthroline] (abbreviation: mPPhen2P), diquinoxalino [2,3-a: 2′,3′-c]phenazine (abbreviation: HATNA), 2,4,6-tris [3′-(pyridin-3-yl) biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

The charge-generation layer includes at least a charge-generation region. The charge-generation region preferably contains an acceptor material, which may be the same as the acceptor material contained in the hole-injection layer.

The charge-generation region preferably contains a composite material or the like containing an acceptor material and a hole-transport material, which may be the same as the hole-transport material contained in the hole-injection layer or the hole-transport layer. As the composite material containing an acceptor material and a hole-transport material, a stacked-layer structure of a layer containing an acceptor material and a layer containing a hole-transport material may be used or a layer in which an acceptor material and a hole-transport material are mixed may be used. The layer in which materials are mixed is obtained by, for example, co-evaporation of an acceptor material and a hole-transport material.

Note that the charge-generation layer may contain a donor material instead of an acceptor material, and a layer containing an electron-transport material and a donor material is used.

The charge-generation layer preferably includes a layer containing a material having a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (e.g., lithium oxide (Li₂O)). Alternatively, a material that can be used for the electron-injection layer can be suitably used for the electron-injection buffer layer.

A boundary between the charge-generation region and the electron-injection buffer layer is sometimes unclear. For example, both an element contained in the charge-generation region and an element contained in the electron-injection buffer layer might be detected by time-of-flight secondary ion mass spectrometry (referred to as TOF-SIMS) analysis of a very thin charge-generation layer. In the case of using lithium oxide for the electron-injection buffer layer, lithium may be detected not only in the electron-injection buffer layer but also in the whole charge-generation layer because an alkali metal such as lithium has high diffusibility. Thus, a region where lithium is detected by TOF-SIMS can be regarded as the charge-generation layer.

The charge-generation layer preferably includes a layer containing a material having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

For the electron-relay layer, an electron-transport material can be suitably used. For the electron-relay layer, a phthalocyanine-based material such as copper (II) phthalocyanine (abbreviation: CuPc) can be suitably used. For the electron-relay layer, a metal complex having a metal-oxygen bond and an aromatic ligand can be suitably used.

Note that the charge-generation region, the electron-injection buffer layer, and the electron-relay layer cannot be clearly distinguished from one another in some cases on the basis of the cross-sectional shapes, properties, or the like.

Note that the charge-generation layer may contain a donor material instead of an acceptor material. For example, the charge-generation layer may include a layer containing an electron-transport material and a donor material, which can be used for the electron-injection layer. When the light-emitting units are stacked, provision of a charge-generation layer between two light-emitting units can suppress an increase in driving voltage.

This embodiment can be combined with the other embodiments as appropriate. In the case where a plurality of structure examples are described in one embodiment in this specification, the structure examples can be combined as appropriate.

### Embodiment 4

In this embodiment, a display device will be described.

### Structure Example of Display Device

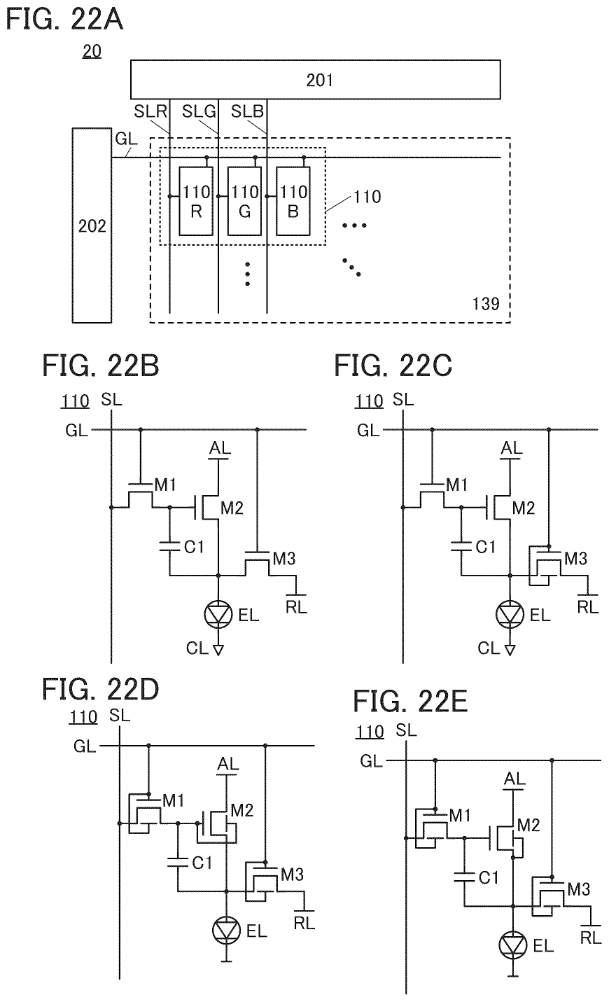

FIG. 22A illustrates a block diagram of a display device 20. The display device 20 includes the pixel region 139, a driver circuit portion 201, a driver circuit portion 202, and the like.

The pixel region 139 includes the plurality of pixels 110 laid out in a matrix. Each of the pixels 110 includes a subpixel 110R, a subpixel 110G, and a subpixel 110B.

The pixel 110 is electrically connected to a wiring GL, a wiring SLR, a wiring SLG, and a wiring SLB. The wiring SLR, the wiring SLG, and the wiring SLB are electrically connected to the driver circuit portion 201. The wiring GL is electrically connected to the driver circuit portion 202. The driver circuit portion 201 functions as a source line driver circuit (also referred to as a source driver), and the driver circuit portion 202 functions as a gate line driver circuit (also referred to as a gate driver). The wiring GL functions as a gate line, and the wiring SLR, the wiring SLG, and the wiring SLB each function as a source line.

The subpixel 110R emits red light. The subpixel 110G emits green light. The subpixel 110B emits blue light. Thus, the display device 20 can perform full-color display. Note that the pixel 110 may include a subpixel that emits light of another color. For example, the pixel 110 may include, in addition to the three subpixels, a subpixel that emits white light, a subpixel that emits yellow light, or the like.

The wiring GL is electrically connected to the subpixel 110R, the subpixel 110G, and the subpixel 110B arranged in the row direction (an extending direction of the wiring GL). The wiring SLR, the wiring SLG, and the wiring SLB are electrically connected to the subpixels 110R, the subpixels 110G, and the subpixels 110B (not illustrated), respectively, arranged in the column direction (an extending direction of the wiring SLR and the like).

### Structure Example of Pixel Circuit

FIG. 22B illustrates an example of a circuit diagram of the pixel 110 that can be used as the subpixel 110R, the subpixel 110G, and the subpixel 110B. The pixel 110 includes a transistor M1, a transistor M2, a transistor M3, a capacitor C1, and a light-emitting device. In the pixel circuit, the light-emitting device is denoted by EL. The wiring GL and a wiring SL are electrically connected to the pixel 110. The wiring SL corresponds to any of the wiring SLR, the wiring SLG, and the wiring SLB illustrated in FIG. 22A.

A gate of the transistor M1 is electrically connected to the wiring GL, one of a source and a drain of the transistor M1 is electrically connected to the wiring SL, and the other of the source and the drain of the transistor M1 is electrically connected to one electrode of the capacitor C1 and a gate of the transistor M2. One of a source and a drain of the transistor M2 is electrically connected to a wiring AL, and the other of the source and the drain of the transistor M2 is electrically connected to one electrode of the light-emitting device EL, the other electrode of the capacitor C1, and one of a source and a drain of the transistor M3. A gate of the transistor M3 is electrically connected to the wiring GL, and the other of the source and the drain of the transistor M3 is electrically connected to a wiring RL. The other electrode of the light-emitting device EL is electrically connected to a wiring CL.

A data potential D is supplied to the wiring SL. A selection signal is supplied to the wiring GL. The selection signal includes a potential for bringing a transistor into a conducting state and a potential for bringing a transistor into a non-conducting state.

A reset potential is supplied to the wiring RL. An anode potential is supplied to the wiring AL. A cathode potential is supplied to the wiring CL. In the pixel 110, the anode potential is a potential higher than the cathode potential. The reset potential supplied to the wiring RL can be set such that a potential difference between the reset potential and the cathode potential is lower than the threshold voltage of the light-emitting device EL. The reset potential can be a potential higher than the cathode potential, a potential equal to the cathode potential, or a potential lower than the cathode potential.

The transistor M1 and the transistor M3 each function as a switch. The transistor M2 functions as a transistor for controlling current flowing through the light-emitting device EL. For example, it can be said that the transistor M1 functions as a selection transistor and the transistor M2 functions as a driving transistor.

Here, it is preferable to use LTPS transistors as all of the transistor M1 to the transistor M3. Alternatively, it is preferable to use OS transistors as the transistor M1 and the transistor M3 and to use an LTPS transistor as the transistor M2.

Alternatively, OS transistors may be used as all of the transistor M1 to the transistor M3. In that case, an LTPS transistor can be used as at least one of a plurality of transistors included in the driver circuit portion 201 and a plurality of transistors included in the driver circuit portion 202, and OS transistors can be used as the other transistors. For example, OS transistors can be used as the transistors provided in the pixel region 139, and LTPS transistors can be used as the transistors provided in the driver circuit portion 201 and the driver circuit portion 202.

As the OS transistor, a transistor containing an oxide semiconductor in a semiconductor layer where a channel is formed can be used. The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. In particular, M is preferably one or more kinds selected from aluminum, gallium, yttrium, and tin. It is particularly preferable to use an oxide containing indium, gallium, and zinc (also referred to as IGZO) for the semiconductor layer of the OS transistor. Alternatively, it is preferable to use an oxide containing indium, tin, and zinc. Further alternatively, it is preferable to use an oxide containing indium, gallium, tin, and zinc.

A transistor containing an oxide semiconductor having a wider band gap and a lower carrier concentration than silicon can achieve an extremely low off-state current. Accordingly, such a low off-state current enables long-term retention of charge accumulated in a capacitor that is connected to the transistor in series. Thus, it is particularly preferable to use a transistor containing an oxide semiconductor as the transistor M1 and the transistor M3 each of which is connected to the capacitor C1 in series. The use of the transistor containing an oxide semiconductor as each of the transistor M1 and the transistor M3 can prevent leakage of charge retained in the capacitor C1 through the transistor M1 or the transistor M3. Furthermore, since charge retained in the capacitor C1 can be retained for a long time, a still image can be displayed for a long time without rewriting data in the pixel 110.

Although the transistors are illustrated as n-channel transistors in FIG. 22B, a p-channel transistor can also be used.

The transistors included in the pixel 110 are preferably formed to be arranged over the same substrate.

Transistors each including a pair of gates overlapping with each other with a semiconductor layer therebetween can be used as the transistors included in the pixel 110.

In the transistor including a pair of gates, the same potential is supplied to the pair of gates electrically connected to each other, which brings advantage that the transistor can have a higher on-state current and improved saturation characteristics. A potential for controlling the threshold voltage of the transistor may be supplied to one of the pair of gates. Furthermore, when a constant potential is supplied to one of the pair of gates, the stability of the electrical characteristics of the transistor can be improved. For example, one of the gates of the transistor may be electrically connected to a wiring to which a constant potential is supplied or may be electrically connected to a source or a drain of the transistor.

The pixel 110 illustrated in FIG. 22C is an example of the case where a transistor including a pair of gates is used as the transistor M3. The gates of the transistor M3 are electrically connected to each other. Such a structure can shorten the period in which data is written to the pixel 110.

The pixel 110 illustrated in FIG. 22D is an example in which a transistor including a pair of gates is used also as each of the transistor M1 and the transistor M2 in addition to the transistor M3. In each of the transistors, the pair of gates are electrically connected to each other. When such a transistor is used at least as the transistor M2, the saturation characteristics are improved, so that the emission luminance of the light-emitting device EL can be controlled easily and the display quality can be improved.

The pixel 110 illustrated in FIG. 22E is an example of the case where one of the pair of gates of the transistor M2 in the pixel 110 illustrated in FIG. 22D is electrically connected to the source of the transistor M2.

### Structure Example of Transistor

Cross-sectional structure examples of the transistor will be described below.

### Structure Example 1

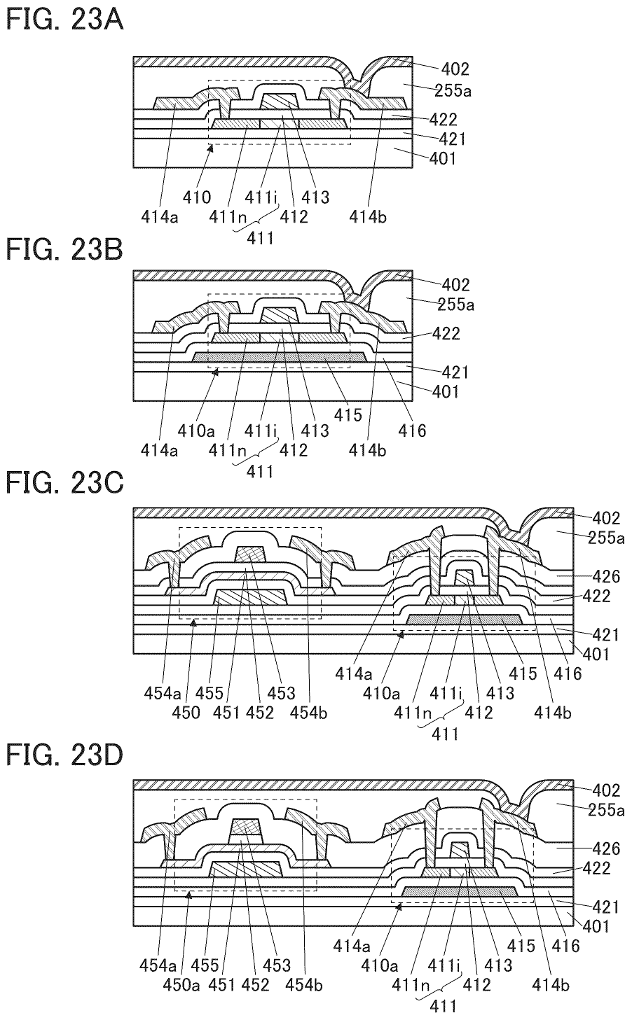

FIG. 23A is a cross-sectional view including a transistor 410.

The transistor 410 is provided over a substrate 401 and contains polycrystalline silicon in its semiconductor layer. The transistor 410 corresponds to the transistor M2 in the pixel 110, for example. That is, one of a source and a drain of the transistor 410 can be electrically connected to the lower electrode 111 of the light-emitting device, and FIG. 23A illustrates a conductive layer 402 positioned between the lower electrode 111 and the one of the source and the drain.

The transistor 410 includes a semiconductor layer 411, an insulating layer 412, a conductive layer 413, and the like. The semiconductor layer 411 includes a channel formation region 411i and low-resistance regions 411n. The semiconductor layer 411 contains silicon. The semiconductor layer 411 preferably contains polycrystalline silicon. Part of the insulating layer 412 functions as a gate insulating layer. Part of the conductive layer 413 functions as a gate electrode.

Note that the semiconductor layer 411 can include a metal oxide exhibiting semiconductor characteristics (also referred to as an oxide semiconductor). In that case, the transistor 410 can be referred to as an OS transistor.

The low-resistance regions 411n are each a region containing an impurity element. For example, in the case where the transistor 410 is an n-channel transistor, phosphorus, arsenic, or the like is added to the low-resistance regions 411n. Meanwhile, in the case where the transistor 410 is a p-channel transistor, boron, aluminum, or the like is added to the low-resistance regions 411n. In addition, in order to control the threshold voltage of the transistor 410, the above-described impurity may be added to the channel formation region 411i.

An insulating layer 421 is provided over the substrate 401. The semiconductor layer 411 is provided over the insulating layer 421. The insulating layer 412 is provided to cover the semiconductor layer 411 and the insulating layer 421. The conductive layer 413 is provided in a position that is over the insulating layer 412 and overlaps with the semiconductor layer 411.

An insulating layer 422 is provided to cover the conductive layer 413 and the insulating layer 412. A conductive layer 414a and a conductive layer 414b are provided over the insulating layer 422. The conductive layer 414a and the conductive layer 414b are electrically connected to the low-resistance regions 411n in opening portions provided in the insulating layer 422 and the insulating layer 412. Part of the conductive layer 414a functions as one of a source electrode and a drain electrode, and part of the conductive layer 414b functions as the other of the source electrode and the drain electrode. The insulating layer 255a is provided to cover the conductive layer 414a, the conductive layer 414b, and the insulating layer 422.

The conductive layer 402 is provided over the insulating layer 255a.

### Structure Example 2

FIG. 23B illustrates a transistor 410a including a pair of gate electrodes. The transistor 410a illustrated in FIG. 23B is different from the transistor in FIG. 23A mainly in including a conductive layer 415 and an insulating layer 416.

The conductive layer 415 is provided over the insulating layer 421. The insulating layer 416 is provided to cover the conductive layer 415 and the insulating layer 421. The semiconductor layer 411 is provided such that at least the channel formation region 411i overlaps with the conductive layer 415 with the insulating layer 416 therebetween.

In the transistor 410a illustrated in FIG. 23B, part of the conductive layer 413 functions as a first gate electrode, and part of the conductive layer 415 functions as a second gate electrode. At this time, part of the insulating layer 412 functions as a first gate insulating layer, and part of the insulating layer 416 functions as a second gate insulating layer.

Here, to electrically connect the first gate electrode to the second gate electrode, the conductive layer 413 is electrically connected to the conductive layer 415 through an opening portion provided in the insulating layer 412 and the insulating layer 416 in a region not illustrated. To electrically connect the second gate electrode to a source or a drain, the conductive layer 415 is electrically connected to the conductive layer 414a or the conductive layer 414b through an opening portion provided in the insulating layer 422, the insulating layer 412, and the insulating layer 416 in a region not illustrated.

In the case of using LTPS transistors as all of the transistors included in the pixels 110, the transistor 410 exemplified in FIG. 23A or the transistor 410a exemplified in FIG. 23B can be used. In that case, the transistors 410a may be used as all of the transistors included in the pixels 110, the transistors 410 may be used as all of the transistors, or the transistors 410a and the transistors 410 may be used in combination.

### Structure Example 3

Described below is an example of a structure including both a transistor containing silicon in its semiconductor layer and a transistor containing a metal oxide in its semiconductor layer.

FIG. 23C is a cross-sectional view including the transistor 410a and a transistor 450.

Structure example 1 described above can be referred to for the transistor 410a. Although an example of using the transistor 410a is illustrated here, a structure including the transistor 410 and the transistor 450 or a structure including all the transistor 410, the transistor 410a, and the transistor 450 may alternatively be employed.

The transistor 450 is a transistor containing a metal oxide in its semiconductor layer. The structure illustrated in FIG. 23C is an example in which the transistor 450 and the transistor 410a respectively correspond to the transistor M1 and the transistor M2 in the pixel 110. That is, one of a source and a drain of the transistor 410 can be electrically connected to the lower electrode 111 of the light-emitting device, and FIG. 23C illustrates the conductive layer 402 positioned between the lower electrode 111 and the one of the source and the drain.

Moreover, FIG. 23C illustrates an example in which the transistor 450 includes a pair of gates.

The transistor 450 includes a conductive layer 455, the insulating layer 422, a semiconductor layer 451, an insulating layer 452, a conductive layer 453, and the like. Part of the conductive layer 453 functions as a first gate of the transistor 450, and part of the conductive layer 455 functions as a second gate of the transistor 450. In that case, part of the insulating layer 452 functions as a first gate insulating layer of the transistor 450, and part of the insulating layer 422 functions as a second gate insulating layer of the transistor 450.

The conductive layer 455 is provided over the insulating layer 412. The insulating layer 422 is provided to cover the conductive layer 455. The semiconductor layer 451 is provided over the insulating layer 422. The insulating layer 452 is provided to cover the semiconductor layer 451 and the insulating layer 422. The conductive layer 453 is provided over the insulating layer 452 and includes a region overlapping with the semiconductor layer 451 and the conductive layer 455.

An insulating layer 426 is provided to cover the insulating layer 452 and the conductive layer 453. A conductive layer 454a and a conductive layer 454b are provided over the insulating layer 426. The conductive layer 454a and the conductive layer 454b are electrically connected to the semiconductor layer 451 in opening portions provided in the insulating layer 426 and the insulating layer 452. Part of the conductive layer 454a functions as one of a source electrode and a drain electrode, and part of the conductive layer 454b functions as the other of the source electrode and the drain electrode. The insulating layer 104 is provided to cover the conductive layer 454a, the conductive layer 454b, and the insulating layer 426.

Here, the conductive layer 414a and the conductive layer 414b electrically connected to the transistor 410a are preferably formed by processing the same conductive film as the conductive layer 454a and the conductive layer 454b. In FIG. 23C, the conductive layer 414a, the conductive layer 414b, the conductive layer 454a, and the conductive layer 454b are formed on the same plane (i.e., in contact with the top surface of the insulating layer 426) and contain the same metal element. In that case, the conductive layer 414a and the conductive layer 414b are electrically connected to the low-resistance regions 411n through openings provided in the insulating layer 426, the insulating layer 452, the insulating layer 422, and the insulating layer 412. This is preferable because the fabrication process can be simplified.

Moreover, the conductive layer 413 functioning as the first gate electrode of the transistor 410a and the conductive layer 455 functioning as the second gate electrode of the transistor 450 are preferably formed by processing the same conductive film. FIG. 23C illustrates a structure in which the conductive layer 413 and the conductive layer 455 are formed on the same plane (i.e., in contact with the top surface of the insulating layer 412) and contain the same metal element. This is preferable because the fabrication process can be simplified.

In the structure in FIG. 23C, the insulating layer 452 functioning as the first gate insulating layer of the transistor 450 covers the end portion of the semiconductor layer 451; however, the insulating layer 452 may be processed to have the same or substantially the same top surface shape as the conductive layer 453 as in the transistor 450a illustrated in FIG. 23D.

Note that in this specification and the like, the expression “top surface shapes are substantially the same” means that at least outlines of stacked layers partly overlap with each other. For example, the case of processing an upper layer and a lower layer with the use of the same mask pattern or mask patterns that are partly the same is included. However, in some cases, the outlines do not completely overlap with each other and the upper layer is positioned inward from the lower layer or the upper layer is positioned outward from the lower layer: such cases are also represented by the expression “top surface shapes are substantially the same”.

Although the example in which the transistor 410a corresponds to the transistor M2 and is electrically connected to the pixel electrode is illustrated here, one embodiment of the present invention is not limited thereto. For example, a structure in which the transistor 450 or the transistor 450a corresponds to the transistor M2 may be employed. In that case, the transistor 410a corresponds to the transistor M1, the transistor M3, or another transistor.

By including the above pixel circuit and having the structure of the light-emitting device described in the above embodiment, the display device can display an image with any one or more of image crispness, image sharpness, high chroma, and a high contrast ratio. The display device is preferable; leakage current that might flow through the transistors in the pixel circuit is extremely low and leakage current between the light-emitting devices in the above embodiment is extremely low, leading to little leakage of light or the like at the time of black display.

This embodiment can be combined with any of the other embodiments as appropriate. In the case where a plurality of structure examples are described in one embodiment in this specification, the structure examples can be combined as appropriate.

### Embodiment 5

In this embodiment, a metal oxide (also referred to as an oxide semiconductor) that can be used in the OS transistor described in the above embodiment will be described.

The metal oxide preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

The metal oxide can be formed by a sputtering method, a CVD method such as an MOCVD method, an ALD method, or the like.

### <Classification of Crystal Structure>

Amorphous (including completely amorphous), CAAC (c-axis-aligned crystalline), nc (nanocrystalline), CAC (cloud-aligned composite), single crystal, and polycrystalline (poly crystal) structures can be given as examples of a crystal structure of an oxide semiconductor.

Note that a crystal structure of a film or a substrate can be evaluated with an X-ray diffraction (XRD) spectrum. For example, evaluation is possible using an XRD spectrum which is obtained by GIXD (Grazing-Incidence XRD) measurement. Note that a GIXD method is also referred to as a thin film method or a Seemann-Bohlin method.

For example, the XRD spectrum of a quartz glass substrate shows a peak with a substantially bilaterally symmetrical shape. On the other hand, the peak of the XRD spectrum of an IGZO film having a crystal structure has a bilaterally asymmetrical shape. The bilaterally asymmetrical peak of the XRD spectrum clearly shows the existence of crystals in the film or the substrate. In other words, the crystal structure of the film or the substrate cannot be regarded as an amorphous state unless it has a bilaterally symmetrical peak in the XRD spectrum.

A crystal structure of a film or a substrate can also be evaluated with a diffraction pattern obtained by a nanobeam electron diffraction method (NBED) (such a pattern is also referred to as a nanobeam electron diffraction pattern). For example, a halo pattern is observed in the diffraction pattern of the quartz glass substrate, which indicates that the quartz glass is in an amorphous state. Furthermore, not a halo pattern but a spot-like pattern is observed in the diffraction pattern of the IGZO film formed at room temperature. Thus, it is suggested that the IGZO film formed at room temperature is in an intermediate state, which is neither a crystal state nor an amorphous state, and it cannot be concluded that the IGZO film is in an amorphous state.

### <<Structure of Oxide Semiconductor>>

Oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a plurality of fine crystals, the size of the crystal region may be approximately several tens of nanometers.

In the case of an In-M-Zn oxide (an element M is one or more kinds selected from aluminum, gallium, yttrium, tin, titanium, and the like), the CAAC-OS tends to have a layered crystal structure (also referred to as a layered structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Thus, indium may be contained in the (M,Zn) layer. In addition, the element M may be contained in the In layer. Note that Zn may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (grain boundary) cannot be observed even in the vicinity of the distortion in the CAAC-OS. That is, formation of a crystal grain boundary is inhibited by the distortion of a lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure in which a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable. Hence, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., larger than or equal to 1 nm and smaller than or equal to 30 nm).

[a-like OS]

The a-like OS is an oxide semiconductor having a structure between those of the nc-OS and the amorphous oxide semiconductor. The a-like OS has a void or a low-density region.

That is, the a-like OS has lower crystallinity than the nc-OS and the CAAC-OS. Moreover, the a-like OS has a higher hydrogen concentration in the film than the nc-OS and the CAAC-OS.

### <<Structure of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Note that the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide has [In] higher than [In] in the composition of the CAC-OS film. Moreover, the second region has [Ga] higher than [Ga] in the composition of the CAC-OS film. For example, the first region has higher [In] and lower [Ga] than the second region. Moreover, the second region has higher [Ga] and lower [In] than the first region.

Specifically, the first region contains an indium oxide, an indium zinc oxide, or the like as its main component. The second region contains a gallium oxide, a gallium zinc oxide, or the like as its main component. That is, the first region can be rephrased as a region containing In as its main component. The second region can be rephrased as a region containing Ga as its main component.

Note that a clear boundary between the first region and the second region cannot be observed in some cases.

In a material composition of a CAC-OS in an In—Ga—Zn oxide that contains In, Ga, Zn, and O, regions containing Ga as a main component are observed in part of the CAC-OS and regions containing In as a main component are observed in part thereof. These regions are randomly present to form a mosaic pattern. Thus, it is suggested that the CAC-OS has a structure in which metal elements are unevenly distributed.

The CAC-OS can be formed by a sputtering method under a condition where a substrate is not heated, for example. Moreover, in the case of forming the CAC-OS by a sputtering method, any one or more selected from an inert gas (typically, argon), an oxygen gas, and a nitrogen gas are used as a deposition gas. The ratio of the flow rate of an oxygen gas to the total flow rate of the deposition gas at the time of deposition is preferably as low as possible, and for example, the ratio of the flow rate of an oxygen gas to the total flow rate of the deposition gas at the time of deposition is preferably higher than or equal to 0% and lower than 30%, further preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has higher conductivity than the second region. That is, when carriers flow through the first region, the conductivity of a metal oxide is exhibited. Accordingly, when the first regions are distributed in a metal oxide like a cloud, high field-effect mobility (u) can be achieved.

The second region has a higher insulating property than the first region. That is, when the second regions are distributed in a metal oxide, leakage current can be inhibited.

Thus, in the case where a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material: as a whole, the CAC-OS has a function of a semiconductor. Separation of the conducting function and the insulating function can maximize each function. Accordingly, when the CAC-OS is used for a transistor, high on-state current (Ion), high field-effect mobility (u), and excellent switching operation can be achieved.

A transistor using the CAC-OS has high reliability. Thus, the CAC-OS is most suitable for a variety of semiconductor devices such as display devices.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor having a low carrier concentration is preferably used for a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### <Impurity>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, trap states are sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

This embodiment can be combined with any of the other embodiments as appropriate. In the case where a plurality of structure examples are described in one embodiment in this specification, the structure examples can be combined as appropriate.

### Embodiment 6

In this embodiment, the display device of one embodiment of the present invention will be described with reference to drawings.

### Specific Example of Display Device

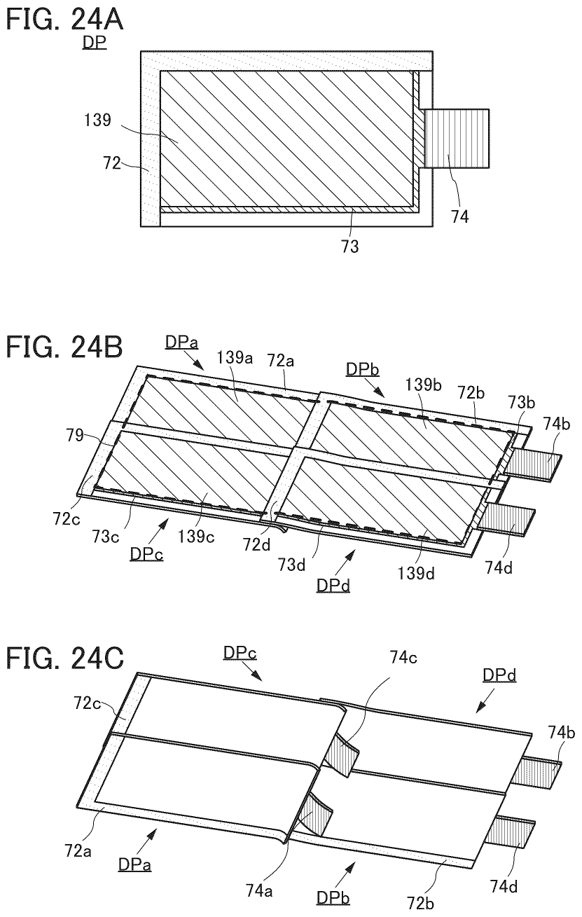

One embodiment of the display device described in the above embodiment is a display module DP provided with an FPC 74. A large display device using a plurality of the display modules DP will be described with reference to FIG. 24.

FIG. 24A is a top view of the display module DP. The display module DP includes a visible-light-transmitting region 72 and a visible-light-blocking region 73 that are adjacent to the pixel region 139.

FIG. 24B and FIG. 24C are perspective views of a display device including four display modules DP. When a plurality of display modules DP are arranged in one or more directions (e.g., in one column or in a matrix), a large display device with a large display region can be fabricated.

Note that in this embodiment, to distinguish the display modules from each other, components included in the display modules from each other, or components relating to the display modules from each other, an explanation is made with alphabetical letters added to reference numerals in some cases. Unless otherwise explained, “a” is added to a display module and components placed on the lowest side (the side opposite to the display surface side), and to one or more display modules and components placed thereover, “b”, “c”, and the like are added in alphabetical order from the lower side. Furthermore, unless otherwise explained, in describing a structure in which a plurality of display modules are included, an explanation is made without alphabetical letters when a common part of the display modules or the components is described.

In the case where a large display device is fabricated using the plurality of display modules DP, each of the display modules DP is not required to be large. Thus, a manufacturing apparatus for fabricating the display modules DP does not need to be increased in size, whereby space-saving can be achieved. Furthermore, since a manufacturing apparatus for small- and medium-sized display panels can be used and a novel manufacturing apparatus does not need to be utilized for a larger display device, manufacturing cost can be reduced. In addition, a decrease in yield caused by an increase in the size of the display modules DP can be inhibited.

A non-display region where wirings and the like are led is positioned in the periphery of the pixel region 139. The non-display region corresponds to the visible-light-blocking region 73. When the plurality of display modules DP overlap with one another, one image is sometimes perceived as images separated by the non-display region or the like.

Thus, in one embodiment of the present invention, the visible-light-transmitting region 72 is provided in the display module DP, and in two display modules overlapping with each other, the pixel region 139 of the display module DP placed on the lower side and the visible-light-transmitting region 72 of the display module DP placed on the upper side overlap with each other.

The visible-light-transmitting region 72 provided in this manner eliminates the need for actively downsizing the non-display region in the display module DP. Note that two display modules DP overlapping with each other are preferable because of the downsized non-display region. As a result, a large display device in which a seam between the display modules DP is hardly seen by a user can be obtained.

In the display module DP positioned on the upper side, the visible-light-transmitting region 72 may be provided in at least part of the non-display region. The visible-light-transmitting region 72 can overlap with the pixel region 139 of the display module DP positioned on the lower side.

Furthermore, at least part of the non-display region of the display module DP positioned on the lower side overlaps with the pixel region 139 or the visible-light-blocking region 73 of the display module DP positioned on the upper side.

The non-display region of the display module DP is preferably large because an increase in the distance between the end portion of the display module DP and an element in the display module DP can inhibit the deterioration of the element due to impurities entering from the outside of the display module DP.

In the case where the plurality of display modules DP are provided in the display device as described above, the pixel region 139 is continuous between the adjacent display modules DP; thus, a display region with a large area can be provided.

The pixel region 139 includes a plurality of pixels.

In the visible-light-transmitting region 72, a pair of substrates that constitute the display module DP, a resin material for sealing a display element sandwiched between the pair of substrates, and the like may be provided. In that case, for members provided in the visible-light-transmitting region 72, materials having a visible-light-transmitting property are used.

In the visible-light-blocking region 73, a wiring electrically connected to the pixels included in the pixel region 139 may be provided, for example. Moreover, one or both of a scan line driver circuit and a signal line driver circuit may be provided in the visible-light-blocking region 73. Furthermore, a terminal connected to the FPC 74, a wiring connected to the terminal, and the like may be provided in the visible-light-blocking region 73.

FIG. 24B and FIG. 24C illustrate an example in which the display modules DP each of which is illustrated in FIG. 24A are arranged in a 2×2 matrix (two display modules DP are arranged in the longitudinal direction and the lateral direction). FIG. 24B is a perspective view of the display surface side of the display modules DP, and FIG. 24C is a perspective view of the side opposite to the display surface side of the display modules DP. A first display module DPa includes a pixel region 139a, a visible-light-transmitting region 72a, and a visible-light-blocking region; however, in FIG. 24B, since another display module overlaps with the first display module DPa, the visible-light-blocking region cannot be observed. FIG. 24C illustrates an FPC 74a included in the first display module DPa. A second display module DPb includes a pixel region 139b, a visible-light-transmitting region 72b, and a visible-light-blocking region 73b. FIG. 24B and FIG. 24C illustrate an FPC 74b included in the second display module DPb. A third display module DPc includes a pixel region 139c, a visible-light-transmitting region 72c, and a visible-light-blocking region 73c. FIG. 24C illustrates an FPC 74c included in the third display module DPc. A fourth display module DPd includes a pixel region 139d, a visible-light-transmitting region 72d, and a visible-light-blocking region 73d. FIG. 24B and FIG. 24C illustrate an FPC 74d included in the fourth display module DPd.

The four display modules DP are arranged so as to overlap with each other. Specifically, the first display module DPa, the second display module DPb, the third display module DPc, and the fourth display module DPd are arranged such that the region 72 transmitting visible light that is included in one display module DP has a region overlapping with and located over the pixel region 139 (on the display surface side) of another display module DP. In addition, the first display module DPa, the second display module DPb, the third display module DPc, and the fourth display module DPd are arranged such that the region 73 blocking visible light of one display module DP does not overlap with the pixel region 139 of another display module DP. In a portion where the four display modules DP overlap with one another, the second display module DPb is stacked over the first display module DPa, the third display module DPc is stacked over the second display module DPb, and the fourth display module DPd is stacked over the third display module DPc.

The short sides of the first display module DPa and the second display module DPb overlap with each other, and part of the pixel region 139a and part of the visible-light-transmitting region 72b overlap with each other. Furthermore, the long sides of the first display module DPa and the third display module DPc overlap with each other, and part of the pixel region 139a and part of the visible-light-transmitting region 72c overlap with each other.

Part of the pixel region 139b overlaps with part of the visible-light-transmitting region 72c and part of the visible-light-transmitting region 72d. In addition, part of the pixel region 139c overlaps with part of the visible-light-transmitting region 72d.

Thus, a region where the pixel region 139a to the pixel region 139d are placed almost seamlessly can be a display region 79.

Here, the first display module DPa, the second display module DPb, the third display module DPc, and the fourth display module DPd preferably have flexibility. For example, a pair of substrates included in each of the first display module DPa, the second display module DPb, the third display module DPc, and the fourth display module DPd preferably have flexibility.

Thus, as illustrated in FIG. 24B and FIG. 24C, the vicinity of an FPC 74a of the first display module DPa can be bent such that part of the first display module DPa and part of the FPC 74a are placed under the pixel region 139b of the second display module DPb adjacent to the FPC 74a, for example. As a result, the FPC 74a can be placed without physical interference with the rear surface of the second display module DPb. Furthermore, when the first display module DPa and the second display module DPb overlap with and are fixed to each other, it is not necessary to consider the thickness of the FPC 74a; thus, the level difference between the top surface of the visible-light-transmitting region 72b and the top surface of the first display module DPa can be reduced. This can make the end portion of the second display module DPb positioned over the pixel region 139a less noticeable.

Moreover, when each of the display modules has flexibility, the second display module DPb can be curved gently such that the top surface of the pixel region 139b of the second display module DPb is level with the top surface of the pixel region 139a of the first display module DPa.

Thus, the display regions can be level with each other except in the vicinity of a region where the first display module DPa and the second display module DPb overlap with each other, and the display quality of a video displayed on the display region 79 can be improved.

Although the relation between the first display module DPa and the second display module DPb is taken as an example in the above description, the same can apply to the relation between any other two adjacent display modules DP.

Note that to reduce a step between two display modules DP having an overlapping region, the thicknesses of the display modules are preferably small. For example, the thicknesses of the display modules are preferably less than or equal to 1 mm, further preferably less than or equal to 300 μm, still further preferably less than or equal to 100 μm.

Each of the display modules preferably incorporates both a scan line driver circuit and a signal line driver circuit. In the case where a driver circuit is provided separately from the display panel, a printed circuit board including a driver circuit and a large number of wirings, terminals, and the like are provided on the back side (the side opposite to the display surface side) of the display panel. Thus, the number of components of the whole display device becomes enormous, which leads to an increase in weight of the display device in some cases. When each of the display modules incorporates both a scan line driver circuit and a signal line driver circuit, the number of components of the display device can be reduced and the weight of the display device can be reduced. This leads to higher portability of the display device.

Here, the scan line driver circuit and the signal line driver circuit are required to operate at a high driving frequency in accordance with the frame frequency of an image to be displayed. In particular, the signal line driver circuit is required to operate at a higher driving frequency than the scan line driver circuit. Thus, some transistors used for the signal line driver circuit require the capability of supplying a large amount of current in some cases. Meanwhile, some transistors provided in the pixel region require adequate withstand voltage for driving a display element in some cases.

In view of the above, the transistor included in the driver circuit and the transistor included in the pixel region are preferably formed to have different structures. For example, a transistor with high withstand voltage is used as one or more of the transistors provided in the pixel region, and a transistor with a high driving frequency is used as one or more of the transistors provided in the driver circuit.

Specifically, one or more of the transistors used for the signal line driver circuit include a gate insulating layer thinner than that of the transistor used for the pixel region. By forming two kinds of transistors separately as described above, the signal line driver circuit can be formed over the substrate where the pixel region is provided.

In each transistor used for the scan line driver circuit, the signal line driver circuit, and the pixel region, a metal oxide is preferably used for a semiconductor where a channel is formed.

Alternatively, in each transistor used for the scan line driver circuit, the signal line driver circuit, and the pixel region, silicon is preferably used for a semiconductor where a channel is formed.

As transistors used for the scan line driver circuit, the signal line driver circuit, and the pixel region, a transistor in which a metal oxide is used for a semiconductor where a channel is formed and a transistor in which silicon is used for a semiconductor where a channel is formed are preferably used in combination.

This embodiment can be combined with the other embodiments as appropriate. In the case where a plurality of structure examples are described in one embodiment in this specification, the structure examples can be combined as appropriate.

### Embodiment 7

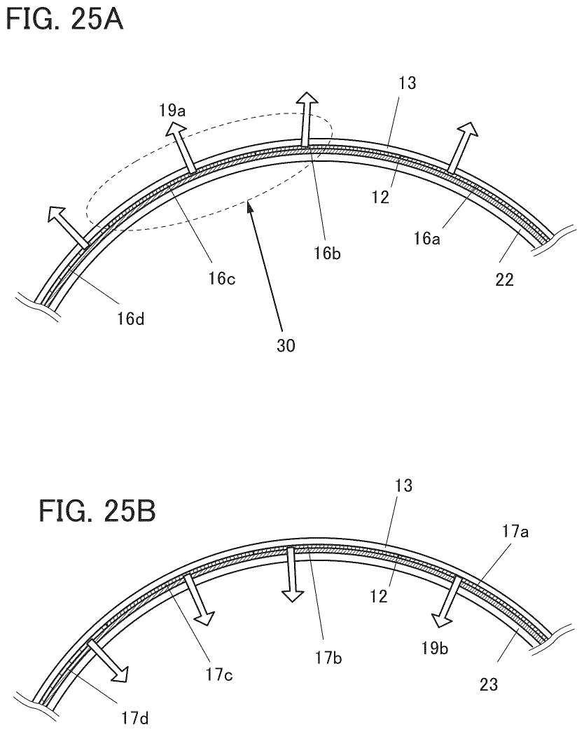

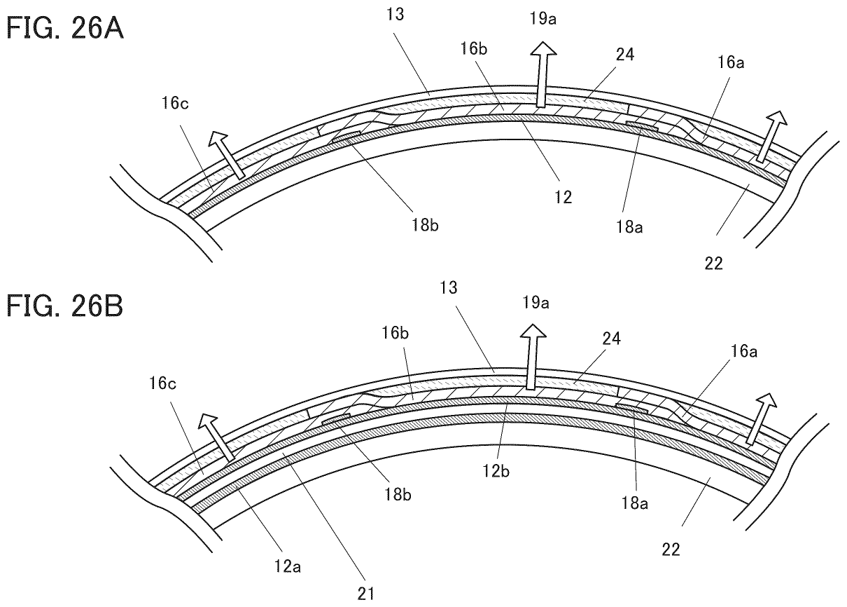

In this embodiment, a large display device using the plurality of flexible display modules will be described with reference to FIG. 25, FIG. 26, and the like. The large display device using the plurality of display modules DP has a curved display surface. When such a large display device is seen, a sense of immersion can be obtained.

FIG. 25A is a cross-sectional view of a display device in which a pixel portion is provided in a support 22 having a curved surface. Although an FPC is not illustrated in FIG. 25A, the FPC can be provided in a manner similar to that in the above embodiment. FIG. 26A is an enlarged view of a region 30 surrounded by a dotted line in FIG. 25A.

The support 22 can also be referred to as a housing or a support member and is formed using a component that can partly have a curved surface. In the case where the display device is provided inside a motor vehicle, for example, plastic, a metal, glass, rubber, or the like can be used for the support 22. Although the support 22 having a plate-like shape is illustrated in FIG. 25A, the shape of the support 22 is not limited to a plate-like shape and the support 22 has a shape partly having a curved surface.

In FIG. 25A, four display modules of a first display module 16a, a second display module 16b, a third display module 16c, and a fourth display module 16d are arranged side by side. Pixel portions of the display modules are arranged side by side, whereby one display surface can be formed. Although FIG. 25A illustrates an example in which the four display modules form one display surface in the display device, there is no particular limitation and two or more display modules can form one display surface. Arrows in FIG. 25A indicate light-emitting directions 19a of the second display module 16b.

A wiring layer 12 is provided over the support 22. The wiring layer 12 includes a plurality of wirings. At least one of the plurality of wirings is electrically connected to an electrode included in the second display module 16b. The wiring layer 12 includes, in addition to the wirings, an insulating film covering the wirings. A contact hole is provided in the insulating film, and the wirings of the wiring layer 12 can be electrically connected to electrodes included in the display modules through the contact hole. The wirings of the wiring layer 12 can each function as a connection wiring, a power supply line, a signal line, a fixed potential line, or the like.

The wirings of the wiring layer 12 can be formed over the support 22 by a method in which a silver paste is selectively formed, a transposition method, or a transfer method.

In the display device illustrated in FIG. 25A, the wirings of the wiring layer 12 can function as common wirings. The common wirings refer to wirings that can be shared by at least the first display module 16a and the second display module 16b. For example, the wirings of the wiring layer 12 can be electrically connected to the electrode of the first display module 16a and can be electrically connected also to the electrode of the second display module 16b. Note that the common wirings may be shared also by the third display module 16c. Such common wirings preferably function as power supply lines.

The viewing surfaces of the first display module 16a, the second display module 16b, and the third display module 16c are preferably covered with a cover member 13. As illustrated in FIG. 26A, the cover member 13 is bonded to the display modules with the use of a resin 24 or the like. For example, by adjusting the refractive index of the resin 24, lines (vertical stripes or horizontal stripes) that might be generated around the boundaries between the first display module 16a, the second display module 16b, and the third display module 16c can be less noticeable. The structure in which the cover member 13 is bonded to the display modules with the use of the resin 24 allows the first display module 16a, the second display module 16b, and the third display module 16c to be fixed firmly.

For the cover member 13, for example, polyimide (PI), aramid, polyethylene terephthalate (PET), polyethersulfone (PES), polyethylene naphthalate (PEN), polycarbonate (PC), nylon, polyetheretherketone (PEEK), polysulfone (PSF), polyetherimide (PEI), polyarylate (PAR), polybutylene terephthalate (PBT), or a silicone resin can be used. A substrate containing any of these materials can be referred to as a plastic substrate. The plastic substrate has a light-transmitting property and has a film-like shape.

The cover member 13 may be formed using an optical film (a polarizing film, a circularly polarizing film, or a light-scattering film). Alternatively, a stacked-layer film in which a plurality of optical films are stacked may be used as the cover member 13.

In FIG. 26A, the end portion of the second display module 16b and the end portion of the third display module 16c overlap with each other. An electrode 18b of the second display module 16b is provided in the region where the end portions overlap with each other, and the electrode 18b is electrically connected to the wirings of the wiring layer 12. When the vicinity of the electrode 18b overlaps with the end of the pixel region of the third display module 16c, a line (a vertical stripe or a horizontal stripe) that might be generated around the boundary between the third display module 16c and the second display module 16b can be less noticeable.

Also when a light-blocking layer such as a black matrix is placed to overlap with the vicinity of the boundary, a line (a vertical stripe or a horizontal stripe) that might be generated around the boundary between the third display module 16c and the second display module 16b can be less noticeable.

When the vicinity of an electrode 18a of the second display module 16b overlaps with the end of the pixel region of the first display module 16a, a line (a vertical stripe or a horizontal stripe) that might be generated around the boundary between the first display module 16a and the second display module 16b can be less noticeable.

Also when a light-blocking layer such as a black matrix is placed to overlap with the vicinity of the boundary, a line (a vertical stripe or a horizontal stripe) that might be generated around the boundary between the first display module 16a and the second display module 16b can be less noticeable.

The wiring layer 12 can have a multilayer structure and an example of such a case is illustrated in FIG. 26B.

In FIG. 26B, the support 22 having a curved surface is provided with a stack including a wiring layer 12a, an insulating film 21 over the wiring layer 12a, and a wiring layer 12b over the insulating film 21. The wirings of the wiring layer 12a and the wiring layer 12b may be arranged to intersect with each other. Like the wiring layer 12 in FIG. 26A, the wiring layer 12b can be electrically connected to the electrodes of the display modules. The wiring layer 12a can be electrically connected to the electrodes of the display modules through a contact hole provided in the insulating film 21.

The wirings of the wiring layer 12 can function as some lead wirings of the first display module 16a, the second display module 16b, and the third display module 16c. The wiring density in each of the display modules can be reduced to decrease the parasitic capacitance, for example.

FIG. 25B illustrates a modification example of the structure in FIG. 25A. Light-emitting directions 19b indicated by arrows in FIG. 25B are different from the light-emitting directions 19a indicated by the arrows in FIG. 25A. In other words, FIG. 25A illustrates a structure in which the display surface has a convex surface, whereas FIG. 25B illustrates a structure in which the display surface has a concave surface.

In FIG. 25B, a fourth display module 17a, a fifth display module 17b, a sixth display module 17c, and a seventh display module 17d are arranged side by side and fixed to a support 23 having a light-transmitting property. Note that the fourth display module 17a and the like can have structures similar to those of the first display module 16a and the like.

The material of the cover member 13 in the display device illustrated in FIG. 25B does not necessarily have a light-transmitting property, and a ceiling of a motor vehicle can be used for the cover member 13. Furthermore, a glass roof of the motor vehicle can be used for the cover member 13. The support 23 having a light-transmitting property is placed on the viewing surface, and the support 23 has a curved surface.

Although FIG. 25B illustrates an example in which the four display modules form one display surface in the display device, there is no particular limitation and two or more display modules can form one display surface.

The entire surface of the support illustrated in each of FIG. 25A to FIG. 26B is not necessarily a curved surface, and part of the surface may be a flat surface. The flat surface can be provided in accordance with, for example, a component inside a motor vehicle (e.g., a dashboard, a ceiling, a pillar, window glass, a steering wheel, a seat, or an inner portion of a door).

Furthermore, the display surface, i.e., the viewing surface, of the display device can be provided with a touch sensor. With the touch sensor, the display surface that can be operated by touch of a hand or a finger of a driver of a motor vehicle can be provided.

The flexible substrate included in the support is more fragile than a glass substrate. Thus, in the case where the touch sensor is provided, a surface protective film is preferably provided to prevent a scratch from being caused by touch of a hand or a finger. As the surface protective film, a silicon oxide film having optically good characteristics (a high visible light transmittance or a high infrared light transmittance) is preferably used. The surface protective film may be formed using DLC (diamond-like carbon), aluminum oxide (AlOx), a polyester-based material, a polycarbonate-based material, or the like. Note that a material having high hardness is suitable for the surface protective film. Providing the surface protective film can prevent dirt from attaching to the support.

In the case where the surface protective film is formed by a coating method, the surface protective film can be formed before the display device is fixed to the support having a curved surface or can be formed after the display device is fixed to the support having a curved surface.

In this manner, a large display device having a curved surface can be provided. When a large display device having a curved surface is seen, a sense of immersion can be obtained.

This embodiment can be implemented in combination with any of the other embodiments described in this specification and the like as appropriate. For example, part of the structure described in this embodiment may be implemented in combination with any of the other embodiments described in this specification and the like as appropriate.

### Embodiment 8

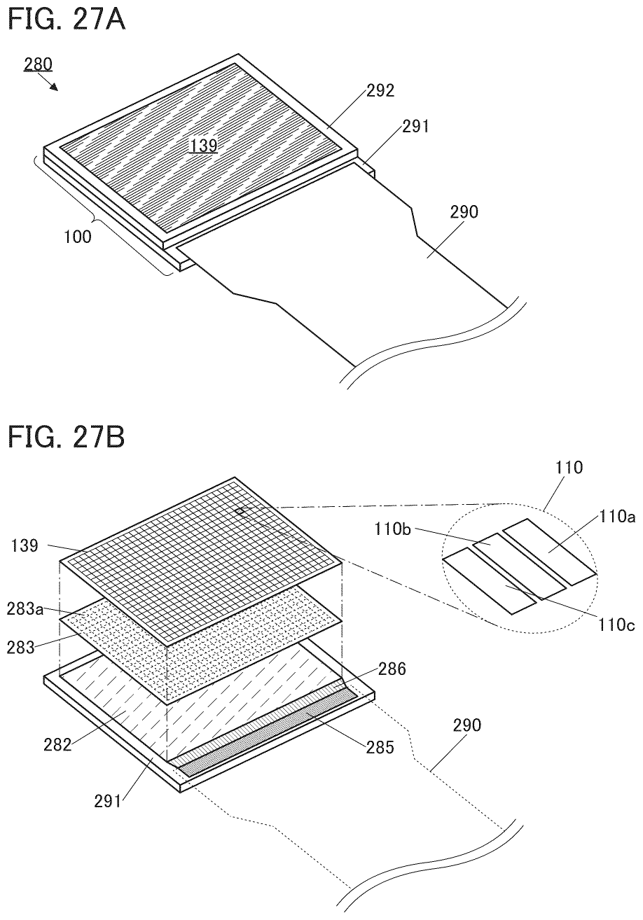

In this embodiment, the display device of one embodiment of the present invention will be described with reference to FIG. 27.

The display device in this embodiment can be a high-resolution display device. Accordingly, the display device in this embodiment can be used for display portions of information terminals (wearable devices) such as watch-type and bracelet-type information terminals and display portions of wearable devices that can be worn on a head, such as a VR device like a head-mounted display and a glasses-type AR device.

### [Display Module]

FIG. 27A is a perspective view of a display module 280. The display module 280 includes the display device 100 and an FPC 290.

The display module 280 includes a substrate 291 and a substrate 292. The display module 280 includes the pixel region 139. The pixel region 139 is a region of the display module 280 where an image is displayed, and is a region where light from pixels provided in the pixel region 139 described later can be seen.

FIG. 27B is a perspective view schematically illustrating a structure on the substrate 291 side. Over the substrate 291, a circuit portion 282, a pixel circuit portion 283 over the circuit portion 282, and the pixel region 139 over the pixel circuit portion 283 are stacked. A terminal portion 285 (sometimes referred to as an FPC terminal portion) to be connected to the FPC 290 is provided in a portion that is over the substrate 291 and does not overlap with the pixel region 139. The terminal portion 285 and the circuit portion 282 are electrically connected to each other through a wiring portion 286 formed of a plurality of wirings.

The pixel region 139 includes the plurality of pixels 110 arranged periodically. An enlarged view of one pixel 110 is shown on the right side of FIG. 27B. The pixel 110 includes the subpixels 110a, 110b, and 110c that emit light of different colors. The plurality of light-emitting devices can be laid out in stripe arrangement as illustrated in FIG. 27B. Alternatively, a variety of arrangement methods of light-emitting devices, such as delta arrangement and PenTile arrangement, can be employed.

The pixel circuit portion 283 includes pixel circuits 283a including a plurality of transistors and the like arranged periodically.

One pixel circuit 283a is a circuit that controls light emission from light-emitting devices included in one pixel 110. One pixel circuit 283a may be provided with three circuits each of which controls light emission from one light-emitting device. For example, the pixel circuit 283a can include at least one selection transistor, one current control transistor (driving transistor), and a capacitor for one light-emitting device. In that case, a gate signal is input to a gate of the selection transistor, and a source signal is input to one of a source and a drain of the selection transistor. Thus, an active-matrix display device is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel region 139; hence, the aperture ratio (effective display area ratio) of the pixel region 139 can be significantly high. For example, an aperture ratio of the pixel region 139 can be higher than or equal to 40% and lower than 100%, preferably higher than or equal to 50% and lower than or equal to 95%, further preferably higher than or equal to 60% and lower than or equal to 95%. Furthermore, the pixels 110 can be laid out extremely densely, and thus the resolution of the pixel region 139 can be extremely high. For example, the pixels 110 are preferably laid out in the pixel region 139 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution and thus can be suitably used for a VR device such as a head-mounted display or a glasses-type AR device. For example, even with a structure in which the display portion of the display module 280 is seen through a lens, pixels of the extremely-high-density pixel region 139 included in the display module 280 are prevented from being perceived when the display portion is enlarged by the lens, so that display providing a high sense of immersion can be performed. Without being limited thereto, the display module 280 can be suitably used for electronic devices including relatively small display portions. For example, the display module 280 can be suitably used in a display portion of a wearable electronic device such as a watch.

This embodiment can be combined with any of the other embodiments as appropriate. In the case where a plurality of structure examples are described in one embodiment in this specification, the structure examples can be combined as appropriate.

### Embodiment 9

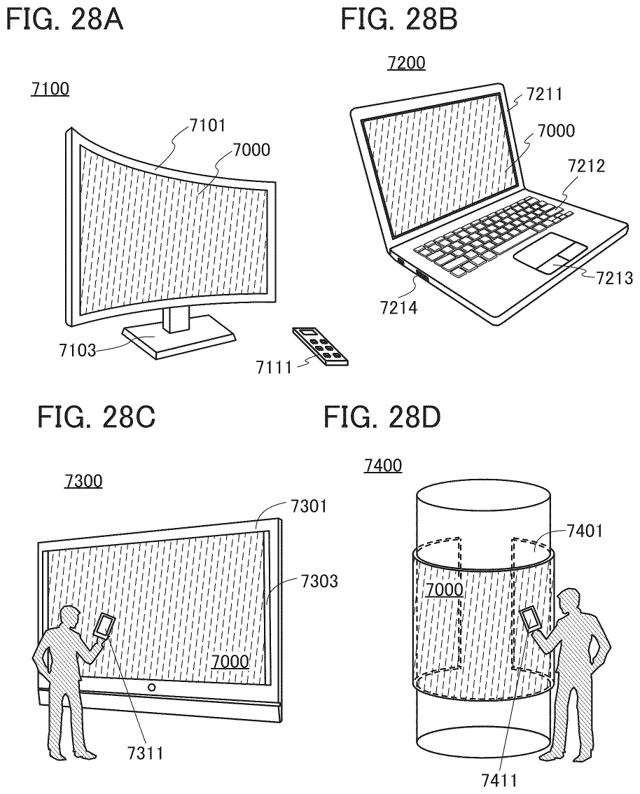

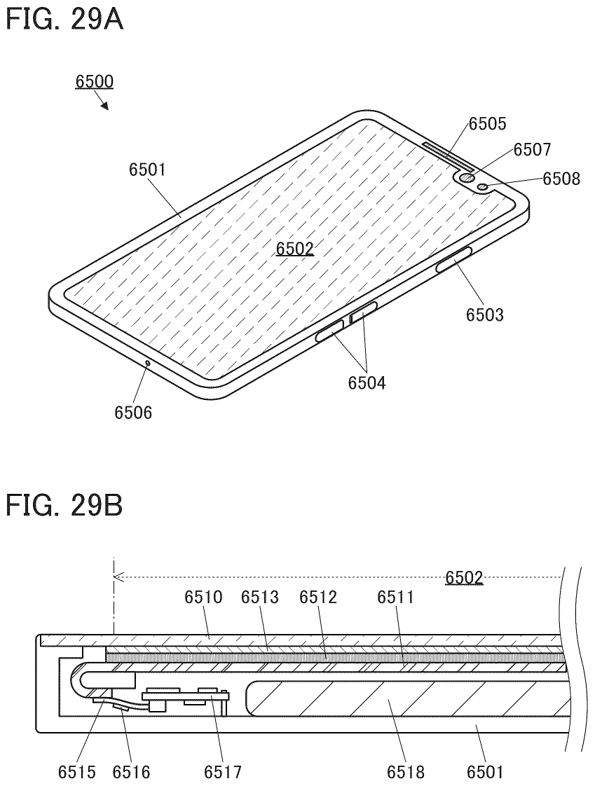

In this embodiment, electronic devices of one embodiment of the present invention will be described with reference to FIG. 28 and FIG. 29.

Electronic devices of this embodiment are each provided with the display device of one embodiment of the present invention in a display portion. The display device of one embodiment of the present invention can be easily increased in resolution and definition. Thus, the display device of one embodiment of the present invention can be used for display portions of a variety of electronic devices.

Examples of electronic devices include a digital camera, a digital video camera, a digital photo frame, a mobile phone, a portable game machine, a portable information terminal, and an audio reproducing device in addition to electronic devices with a relatively large screen, such as a television device, a desktop or laptop personal computer, a monitor of a computer or the like, digital signage, and a large game machine like a pachinko machine.

In particular, the display device of one embodiment of the present invention can have a high resolution, and thus can be suitably used for an electronic device having a relatively small display portion. Examples of such an electronic device include watch-type and bracelet-type information terminals (wearable devices) and wearable devices that can be worn on a head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. Furthermore, the pixel density (resolution) of the display device of one embodiment of the present invention is preferably higher than or equal to 100 ppi, preferably higher than or equal to 300 ppi, further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. The use of such a display device having one or both of high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, electric power, radiation, a flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

FIG. 28A illustrates an example of a television device. In a television device 7100, a pixel portion 7000 is incorporated in a housing 7101. Here, the housing 7101 is supported by a stand 7103.

The pixel region 139 of one embodiment of the present invention can be used as the display portion 7000.

Operation of the television device 7100 illustrated in FIG. 28A can be performed with an operation switch provided in the housing 7101 and a separate remote control 7111. Alternatively, the pixel portion 7000 may include a touch sensor, and the television device 7100 may be operated by touch on the pixel portion 7000 with a finger or the like. The remote control 7111 may be provided with a display portion for displaying information output from the remote control 7111. With operation keys or a touch panel provided in the remote control 7111, channels and volume can be operated and videos displayed on the pixel portion 7000 can be operated.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) information communication can be performed.

FIG. 28B illustrates an example of a laptop personal computer. A laptop personal computer 7200 includes a housing 7211, a keyboard 7212, a pointing device 7213, an external connection port 7214, and the like. In the housing 7211, the pixel portion 7000 is incorporated.

The pixel region 139 of one embodiment of the present invention can be used as the pixel portion 7000.

FIG. 28C and FIG. 28D illustrate examples of digital signage.

Digital signage 7300 illustrated in FIG. 28C includes a housing 7301, the pixel portion 7000, a speaker 7303, and the like. The digital signage 7300 can also include an LED lamp, an operation key (including a power switch or an operation switch), a connection terminal, a variety of sensors, a microphone, and the like.

FIG. 28D is digital signage 7400 attached to a cylindrical pillar 7401. The digital signage 7400 includes the pixel portion 7000 provided along a curved surface of the pillar 7401.

The pixel region 139 of one embodiment of the present invention can be used as the pixel portion 7000 in FIG. 28C and FIG. 28D.

A larger area of the pixel portion 7000 can increase the amount of information that can be provided at a time. The larger pixel portion 7000 attracts more attention, so that the effectiveness of the advertisement can be increased, for example.

The use of a touch panel in the pixel portion 7000 is preferable because in addition to display of a still image or a moving image on the pixel portion 7000, intuitive operation by a user is possible. Moreover, for an application for providing information such as route information or traffic information, usability can be enhanced by intuitive operation.

As illustrated in FIG. 28C and FIG. 28D, it is preferable that the digital signage 7300 or the digital signage 7400 be capable of working with an information terminal 7311 or an information terminal 7411 such as a smartphone a user has through wireless communication. For example, information of an advertisement displayed on the pixel portion 7000 can be displayed on a screen of the information terminal 7311 or the information terminal 7411. By operation of the information terminal 7311 or the information terminal 7411, display on the pixel portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

An electronic device 6500 illustrated in FIG. 29A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The pixel region 139 of one embodiment of the present invention can be used in the display portion 6502.

FIG. 29B is a cross-sectional view including the end portion of the housing 6501 on the microphone 6506 side.

A protection member 6510 having a light-transmitting property is provided on the display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display can be used as the display panel 6511. Thus, an extremely lightweight electronic device can be achieved. Since the display panel 6511 is extremely thin, the battery 6518 with high capacity can be mounted while the thickness of the electronic device is reduced. Moreover, part of the display panel 6511 is folded back such that a connection portion with the FPC 6515 is provided on the back side of the pixel portion, whereby an electronic device with a narrow bezel can be achieved.

This embodiment can be combined with any of the other embodiments as appropriate. In the case where a plurality of structure examples are described in one embodiment in this specification, the structure examples can be combined as appropriate.

### Example

In this example, a sample in which the light-emitting device 102 was divided using the insulating layer 104 including a depressed portion and the insulating layer 105 including a protruding portion was fabricated, and the results of observation with a scanning transmission electron microscopy (STEM) are described.

First, the fabrication conditions of the sample are described. The insulating layer 104 was formed using an acrylic resin over a substrate, and the insulating layer 105 was formed over the insulating layer 104 using a stacked-layer structure of a silicon nitride film and a silicon oxynitride film positioned thereover. The acrylic resin was formed by a spin coating method. The silicon nitride film was formed by a CVD method using a mixed gas of SiH₄ and N₂ to have a thickness smaller than that of the silicon oxynitride film, specifically a thickness of 10 nm. The silicon oxynitride film was formed by a CVD method using a mixed gas of SiH₄ and N₂O to have a thickness larger than that of the silicon nitride film, specifically a thickness of 200 nm. When N₂O is used in the gas for forming the silicon oxynitride film, damage to the acrylic resin in contact with the N₂O occurs in some cases. Thus, it is preferable to use the insulating layer 105 having the stacked-layer structure in which the silicon nitride film formed without an N₂O gas is formed over the acrylic resin and the silicon oxynitride film is formed over the silicon nitride film.

Over the insulating layer 105, a lower electrode having a stacked-layer structure was formed. As the lower electrode, a conductive layer containing ITSO was formed as a first conductive layer, a conductive layer containing APC was formed as a second conductive layer, and the conductive layer containing APC was processed by a wet etching method as illustrated in FIG. 16 and the like. Furthermore, a conductive layer containing ITSO was formed as a third conductive layer, and the two conductive layers each containing ITSO were processed by a wet etching method at the same time, so that the lower electrode 111 having a tapered shape in an end portion was formed.

Then, the insulating layer 105 was processed by a dry etching method. Specifically, an opening portion was formed in the insulating layer 105 under the conditions where 100 sccm of a SF₆ gas was used as an etching gas, the pressure was 0.67 Pa, the ICP power was 6000 W, the bias power was 500 W, and the treatment time was 180 seconds.

Next, the insulating layer 104 was subjected to ashing to form a depressed portion. The depressed portion was formed in the insulating layer 104 under the conditions where the bias power was 700 W, the pressure was 40 Pa, 1800 sccm of an oxygen gas was used, and the treatment time was 300 seconds. This ashing treatment was performed with a resist mask formed for formation of the opening portion in the insulating layer 105 remaining. In that case, the ashing treatment can also serve as ashing treatment as pretreatment for removal of the resist mask.

After that, the stack 114a was formed over the lower electrode 111 by a vacuum evaporation method. To obtain a white-light-emitting device, the stack 114a was formed to have a tandem structure including the charge-generation layer 115a, and the first upper electrode 113a1 was formed by a vacuum evaporation method. For the first upper electrode 113a1, a stacked-layer structure was employed in which MgAg was formed by a vacuum evaporation method as a lower layer, and IGZO was formed by a sputtering method as an upper layer.

As a result, the stack 114x including the charge-generation layer 115x and the upper electrode 113x, which were divided from the stack 114a and the first upper electrode 113a1, were formed in the depressed portion. Note that the charge-generation layer 115x includes the same layer as the charge-generation layer 115a. The stack 114x contains the same material as the stack 114a. The upper electrode 113x contains the same material as the first upper electrode 113a1. Thus, in the upper electrode 113x, the lower layer contains MgAg, and the upper layer contains IGZO.

In this sample, the insulating layer 105 included a protruding portion, and part of the stack 114a was attached to an end surface of the insulating layer 105 but the stack 114a did not exist on a bottom surface of the insulating layer 105. With such a protruding portion, the stack and the upper electrode can each be surely divided.

Next, the insulating layer 125 was formed using an aluminum oxide film. The aluminum oxide film was formed by an ALD method. The insulating layer 125 can be attached on the bottom surface side of the insulating layer 105. The adhesion between layers covered with the aluminum oxide film of the insulating layer 125 and the silicon oxynitride film of the insulating layer 105 can be increased. Specifically, peeling of the stack 114a from the lower electrode 111 can be inhibited. Furthermore, peeling of the stack 114a from the first upper electrode 113a1 can be inhibited.

A resist material was formed by a spin coating method to fill the depressed portion formed by a surface of the insulating layer 125, and light exposure and development were performed to form the insulating layer 126. Then, wet etching was performed using the insulating layer 126 as a mask to form the opening portion in the insulating layer 125.

Lastly, the second upper electrode 113a2 was formed using ITSO. It is found that the second upper electrode 113a2 is positioned to overlap with a top surface of the insulating layer 126 and can function as a common electrode. In this manner, the light-emitting device of this sample was fabricated.

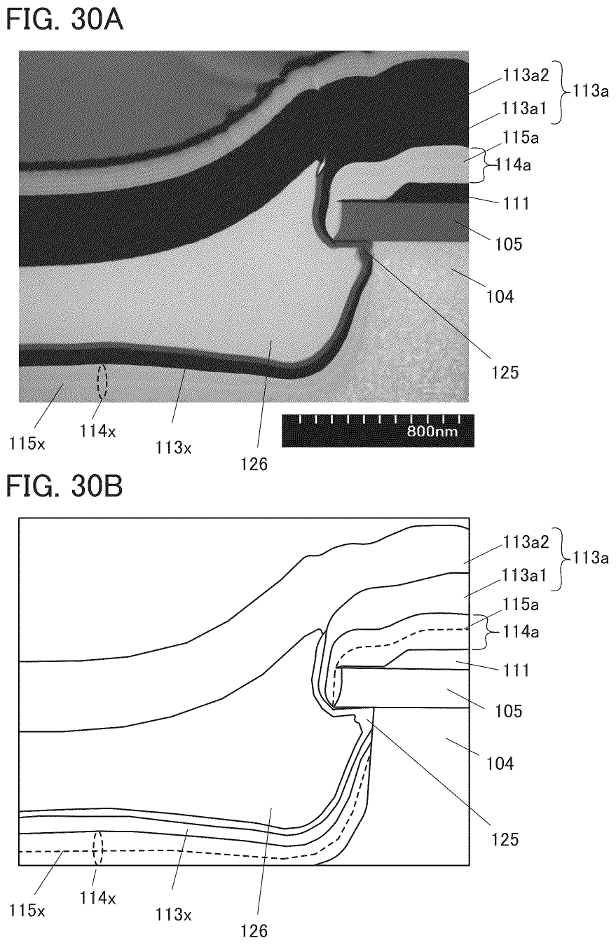

FIG. 30A shows a cross-sectional STEM image of the light-emitting device. The cross-sectional STEM image was captured at an acceleration voltage of 200 kV with “HD-2300” produced by Hitachi High-Technologies Corporation. The thickness or the like of each layer can be grasped on the basis of the scale bar shown in FIG. 30A. FIG. 30B shows a drawing in which the layers in FIG. 30A are indicated with lines.

In FIG. 30A and FIG. 30B, a projected portion and the depressed portion can be observed in the insulating layer 104, the protruding portion included in the insulating layer 105 can be observed, and the protruding portion is positioned to overlap with the depressed portion. It can be confirmed that the stack 114a to be the light-emitting device is positioned to overlap with the projected portion of the insulating layer 104. It can be confirmed that the stack 114a and the stack 114x in the depressed portion are isolated from each other.

The charge-generation layer 115a can be observed in the stack 114a, and the charge-generation layer 115x can be observed in the stack 114x positioned in the depressed portion. It can be confirmed that the charge-generation layer 115a of the light-emitting device exists around the end surface of the insulating layer 105 but does not exist on the bottom surface of the insulating layer 105. Such a charge-generation layer 115a can be regarded as being isolated from the charge-generation layer 115x in the depressed portion.

It can be confirmed that the upper electrode 113a to be the light-emitting device, specifically the first upper electrode 113a1, and the upper electrode 113x in the depressed portion are isolated from each other.

The insulating layer 125 is positioned in a region where the isolation can be observed. It can be confirmed that the insulating layer 125 is attached also below the insulating layer 105. Furthermore, it can be confirmed that the insulating layer 125 is attached to cover a side surface of the upper electrode 113a1. The insulating layer 125 can inhibit peeling of the stack 114a from the lower electrode 111.

This example shows that a light-emitting device can be divided using a depressed portion. Accordingly, crosstalk in the display device can be inhibited or sufficiently reduced.

### REFERENCE NUMERALS

100: display device, 102: light-emitting device, 104: insulating layer, 105: insulating layer, 106: protruding portion, 111: lower electrode, 113a: upper electrode, 113a1: first upper electrode, 113a2: second upper electrode, 113x: upper electrode, 114a: stack, 114x: stack, 115a: charge-generation layer, 115x: charge-generation layer, 125: insulating layer, 126: insulating layer, 148a: color filter, 148b: color filter, 148c: color filter

1. A display device comprising:
a first insulating layer comprising a first region and a second region having a lower top surface level than the first region;
a second insulating layer comprising a region overlapping with the first region;
a light-emitting device comprising a region overlapping with the first region with the second insulating layer therebetween;
a stack comprising a region overlapping with the second region; and
a third insulating layer comprising a region overlapping with the stack,
wherein the second insulating layer comprises a protruding portion overlapping with the second region,
wherein the light-emitting device comprises at least a light-emitting layer, a first upper electrode over the light-emitting layer, and a second upper electrode over the first upper electrode,
wherein the second upper electrode comprises a region overlapping with the third insulating layer, and
wherein the stack comprises a material identical to a material of the light-emitting layer.

2. A display device comprising:
a substrate;
a first insulating layer that is positioned over the substrate and comprises a first region and a second region at a lower level from the substrate than the first region;
a second insulating layer that is positioned over the first insulating layer and comprises a region overlapping with the first region;
a light-emitting device that is positioned over the second insulating layer and comprises a region overlapping with the first region;
a stack that is positioned over the first insulating layer and comprises a region overlapping with the second region; and
a third insulating layer that is positioned over the first insulating layer and comprises a region overlapping with the stack,
wherein the second insulating layer comprises a protruding portion in a position overlapping with the second region,
wherein the light-emitting device comprises at least a light-emitting layer, a first upper electrode over the light-emitting layer, and a second upper electrode over the first upper electrode,
wherein the second upper electrode comprises a region positioned over the third insulating layer, and
wherein the stack comprises a material identical to a material of the light-emitting layer.

3. The display device according to claim 1,
wherein the material identical to a material of the light-emitting layer is a light-emitting material.

4-6. (canceled)

7. The display device according to claim 1,
wherein the second upper electrode is configured to serve as a common electrode.

8. The display device according to claim 1, further comprising a color filter in a position overlapping with the light-emitting device.

9. The display device according to claim 1, further comprising a fourth insulating layer comprising a region positioned between the light-emitting device and the third insulating layer.

10. The display device according to claim 9,
wherein the fourth insulating layer comprises a region in contact with a bottom surface of the second insulating layer.

11. The display device according to claim 1,
wherein the first insulating layer comprises an organic material, and
wherein the second insulating layer comprises an inorganic material.

12. The display device according to claim 1,
wherein an end portion of a lower electrode in the light-emitting device has a tapered shape.

13. The display device according to claim 2,
wherein the material identical to a material of the light-emitting layer is a light-emitting material.

14. The display device according to claim 2,
wherein the second upper electrode is configured to serve as a common electrode.

15. The display device according to claim 2, further comprising a color filter in a position overlapping with the light-emitting device.

16. The display device according to claim 2, further comprising a fourth insulating layer comprising a region positioned between the light-emitting device and the third insulating layer.

17. The display device according to claim 16,
wherein the fourth insulating layer comprises a region in contact with a bottom surface of the second insulating layer.

18. The display device according to claim 2,
wherein the first insulating layer comprises an organic material, and
wherein the second insulating layer comprises an inorganic material.

19. The display device according to claim 2,
wherein an end portion of a lower electrode in the light-emitting device has a tapered shape.

20. The display device according to claim 1, further comprising a charge-generation layer.

21. The display device according to claim 20,
wherein the charge-generation layer is a layer comprising lithium.

22. The display device according to claim 2, further comprising a charge-generation layer.

23. The display device according to claim 22,
wherein the charge-generation layer is a layer comprising lithium.

24. The display device according to claim 1, wherein the light-emitting layer comprises a first light-emitting layer and a second light-emitting layer.

25. The display device according to claim 2, wherein the light-emitting layer comprises a first light-emitting layer and a second light-emitting layer.
